(19) United States
(12) Patent Application Publication
(10) Pub. No.: US 2020/0135445 A1
(43) Pub. Date: Apr. 30, 2020

(54) SEMICONDUCTOR DEVICE AND METHOD FOR FABRICATING SEMICONDUCTOR DEVICE

(71) Applicant: SEMICONDUCTOR ENERGY LABORATORY CO., LTD., ATSUGI-SHI, KANAGAWA-KEN (JP)

(72) Inventors: Shunpei YAMAZAKI, Setagaya, Tokyo (JP); Sachiaki TEZUKA, Atsugi, Kanagawa (JP); Hiroki KOMAGATA, Atsugi, Kanagawa (JP); Yuji EGI, Atsugi, Kanagawa (JP); Naoki OKUNO, Yamato, Kanagawa (JP)

(73) Assignee: SEMICONDUCTOR ENERGY LABORATORY CO., LTD., ATSUGI-SHI, KANAGAWA-KEN (JP)

(21) Appl. No.: 16/607,803

(22) PCT Filed: Apr. 16, 2018
(86) PCT No.: PCT/IB2018/052617

§ 371 Date: Oct. 24, 2019

(30) Foreign Application Priority Data
Apr. 28, 2017 (JP) 2017-090756
Feb. 22, 2018 (JP) 2018-029397

(51) Int. Cl. H01L 21/02; H01L 21/28; H01L 29/51; C23C 16/455; C23C 16/40

(52) U.S. Cl. CPC H01L 21/0228; H01L 21/02178; H01L 21/02181; H01L 21/02194; H01L 21/022; H01L 29/7869; H01L 29/513; H01L 29/517; C23C 16/45525; C23C 16/403; H01L 29/40117

(57) ABSTRACT

A semiconductor device having favorable electrical characteristics is provided.

A first insulator is formed over an oxide, a second insulator is formed over the first insulator, a conductor is formed over the second insulator, and a third insulator that is in contact with a top surface of the oxide, a side surface of the first insulator, a side surface of the second insulator, and a side surface of the conductor is formed. The first insulator and the second insulator are successively formed in a reduced-pressure atmosphere.

### TECHNICAL FIELD

One embodiment of the present invention relates to a semiconductor device, a method for fabricating the semiconductor device, and a method for forming an insulator. Alternatively, one embodiment of the present invention relates to a semiconductor wafer, a module, and an electronic device.

In particular, a feature of the method for forming an insulator described in one embodiment of the present invention is using an ALD (Atomic Layer Deposition) method.

Note that in this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. It can be sometimes said that a display device (a liquid crystal display device, a light-emitting display device, and the like), a projection device, a lighting device, an electro-optical device, a power storage device, a memory device, a semiconductor circuit, an imaging device, an electronic device, and the like include a semiconductor device.

Note that one embodiment of the present invention is not limited to the above technical field. One embodiment of the invention disclosed in this specification and the like relates to an object, a method, or a manufacturing method. Alternatively, one embodiment of the present invention relates to a process, a machine, manufacture, or a composition of matter.

### BACKGROUND ART

Integrated circuits (IC) using semiconductor elements have been developed. A CPU and a memory have been developed and manufactured with technology for an LSI including a highly integrated IC or an ultra LSI. Such an IC is mounted on a circuit board, for example, a printed wiring board, to be used as one of components of a variety of electronic devices included in a computer, an information terminal, a display device, an automobile, and the like. Moreover, utilization of these ICs for an artificial intelligence (AI) system has been studied.

As computers and information terminals, desktop computers, laptop computers, tablet computers, smartphones, cell phones, and the like are known.

A silicon-based semiconductor material is widely known as a semiconductor material used for a semiconductor element; in addition, an oxide semiconductor has attracted attention as another material.

It is known that a transistor using an oxide semiconductor has an extremely low leakage current in a non-conduction state. For example, a low-power consumption CPU utilizing a characteristic of low leakage current of the transistor using an oxide semiconductor has been disclosed (see Patent Document 1).

Furthermore, in recent years, demand for an integrated circuit with higher density has risen with reductions in the size and weight of electronic devices. Furthermore, the productivity of a semiconductor device including an integrated circuit is required to be improved.

Furthermore, miniaturization of a semiconductor element has been required with higher density of an integrated circuit, and demand for a technique for forming a thin film with excellent coverage and few defects such as a pinhole has been increasing. As such a technique for forming a thin film, an ALD (Atomic Layer Deposition) method is known.

### PRIOR ART DOCUMENT

### Patent Document

[Patent Document 1] Japanese Published Patent Application No. 2012-257187

### SUMMARY OF THE INVENTION

### Problems to be Solved by the Invention

An object of one embodiment of the present invention is to provide a semiconductor device having favorable electrical characteristics. Another object of one embodiment of the present invention is to provide a semiconductor device that has small variation in electrical characteristics, stable electrical characteristics, and improved reliability. Another object of one embodiment of the present invention is to provide a semiconductor device capable of retaining data for a long time. Another object of one embodiment of the present invention is to provide a semiconductor device capable of high-speed data writing. Another object of one embodiment of the present invention is to provide a novel semiconductor device.

An object of one embodiment of the present invention is to provide a semiconductor device that can be miniaturized or highly integrated. Another object of one embodiment of the present invention is to provide a semiconductor device with high productivity. Another object of one embodiment of the present invention is to provide a semiconductor device with high design flexibility. Another object of one embodiment of the present invention is to provide a semiconductor device with reduced power consumption.

One object of one embodiment of the present invention is to provide a semiconductor device whose fabricating process is simplified and a fabricating method thereof. Another object of one embodiment of the present invention is to provide a semiconductor device with reduced area and a fabricating method thereof.

Note that the descriptions of these objects do not disturb the existence of other objects. One embodiment of the present invention does not need to achieve all the objects. Other objects will be apparent from and can be derived from the descriptions of the specification, the drawings, the claims, and the like.

### Means for Solving the Problems

One embodiment of the present invention is a method for fabricating a semiconductor device in which a substrate over which an oxide is provided is set in a deposition chamber, an oxidizer is introduced into the deposition chamber in a pulsed form a plurality of times, an insulating film is formed over the oxide after the introduction of the oxidizer, and one or both of addition of oxygen to the oxide and release of hydrogen or water from the oxide is performed by the introduction of the oxidizer.

In the above, the insulating film is preferably formed by an ALD method.

In the above, the insulating film is preferably an oxide containing one or both of aluminum and hafnium.

One embodiment of the present invention is a method for fabricating a semiconductor device in which a first insulator is formed over an oxide, a second insulator is formed over the first insulator, a conductor is formed over the second insulator, and a third insulator in contact with a top surface of the oxide, a top surface of the first insulator, a side surface of the second insulator, and a side surface of the conductor is formed; the first insulator and the second insulator are successively formed in a reduced-pressure atmosphere.

In the above, the first insulator and the second insulator are preferably formed by an ALD method.

In the above, the third insulator is preferably formed by an ALD method.

In the above, the second insulator is preferably an oxide containing one or both of aluminum and hafnium.

In the above, the third insulator is preferably an oxide containing one or both of aluminum and hafnium.

One embodiment of the present invention is a method for fabricating a semiconductor device in which a first insulator is formed over a first conductor, a second insulator is formed over the first insulator, a third insulator is formed over the second insulator, a fourth insulator is formed over the third insulator, a fifth insulator is formed over the fourth insulator, and an oxide is formed over the fifth insulator; the second insulator, the third insulator, and the fourth insulator are successively formed in a reduced-pressure atmosphere.

In the above, the second insulator, the third insulator, and the fourth insulator are preferably formed by an ALD method.

In the above, it is preferable that the second insulator and the fourth insulator be each an oxide containing one of hafnium and aluminum, and the third insulator be an oxide containing the other of hafnium and aluminum.

### Effect of the Invention

According to one embodiment of the present invention, a semiconductor device having favorable electrical characteristics can be provided. Alternatively, according to one embodiment of the present invention, a semiconductor device that has small variation in electrical characteristics, stable electrical characteristics, and improved reliability can be provided. Alternatively, a semiconductor device capable of retaining data for a long time can be provided. Alternatively, a semiconductor device capable of high-speed data writing can be provided. Alternatively, a novel semiconductor device can be provided.

According to one embodiment of the present invention, a semiconductor device that can be miniaturized or highly integrated can be provided. According to one embodiment of the present invention, a semiconductor device with high productivity can be provided. Alternatively, a semiconductor device with high design flexibility can be provided. Alternatively, a semiconductor device with reduced power consumption can be provided.

According to one embodiment of the present invention, a semiconductor device whose fabricating process is simplified and a fabricating method thereof can be provided. Alternatively, according to one embodiment of the present invention, a semiconductor device with reduced area and a fabricating method thereof can be provided.

Note that the descriptions of the effects do not disturb the existence of other effects. One embodiment of the present invention does not necessarily have all the effects. Other effects will be apparent from and can be derived from the descriptions of the specification, the drawings, the claims, and the like.

### BRIEF DESCRIPTION OF DRAWINGS

FIG. 1 A top view and cross-sectional views of a semiconductor device of one embodiment of the present invention.

FIG. 2 A cross-sectional view of a semiconductor device of one embodiment of the present invention.

FIG. 3 A top view and cross-sectional views of a semiconductor device of one embodiment of the present invention.

FIG. 4 A top view and a cross-sectional view of a deposition apparatus of one embodiment of the present invention.

FIG. 5 Diagrams showing a deposition method of one embodiment of the present invention.

FIG. 6 A circuit diagram of a semiconductor device of one embodiment of the present invention.

FIG. 7 A circuit diagram and a cross-sectional view of a semiconductor device of one embodiment of the present invention.

FIG. 8 A circuit diagram of a semiconductor device of one embodiment of the present invention.

FIG. 9 A circuit diagram and a cross-sectional view of a semiconductor device of one embodiment of the present invention.

FIG. 10 A cross-sectional view of a semiconductor device of one embodiment of the present invention.

FIG. 11 A top view and cross-sectional views illustrating a method for fabricating a semiconductor device of one embodiment of the present invention.

FIG. 12 A top view and cross-sectional views illustrating a method for fabricating a semiconductor device of one embodiment of the present invention.

FIG. 13 A top view and cross-sectional views illustrating a method for fabricating a semiconductor device of one embodiment of the present invention.

FIG. 14 A top view and cross-sectional views illustrating a method for fabricating a semiconductor device of one embodiment of the present invention.

FIG. 15 A top view and cross-sectional views illustrating a method for fabricating a semiconductor device of one embodiment of the present invention.

FIG. 16 A top view and cross-sectional views illustrating a method for fabricating a semiconductor device of one embodiment of the present invention.

FIG. 17 A top view and cross-sectional views illustrating a method for fabricating a semiconductor device of one embodiment of the present invention.

FIG. 18 A top view and cross-sectional views illustrating a method for fabricating a semiconductor device of one embodiment of the present invention.

FIG. 19 A top view and cross-sectional views illustrating a method for fabricating a semiconductor device of one embodiment of the present invention.

FIG. 20 A top view and cross-sectional views illustrating a method for fabricating a semiconductor device of one embodiment of the present invention.

FIG. 21 A top view and cross-sectional views illustrating a method for fabricating a semiconductor device of one embodiment of the present invention.

FIG. 22 A top view and cross-sectional views illustrating a method for fabricating a semiconductor device of one embodiment of the present invention.

FIG. 23 A top view and cross-sectional views illustrating a method for fabricating a semiconductor device of one embodiment of the present invention.

FIG. 24 A top view and cross-sectional views illustrating a method for fabricating a semiconductor device of one embodiment of the present invention.

FIG. 25 A top view and cross-sectional views illustrating a method for fabricating a semiconductor device of one embodiment of the present invention.

FIG. 26 Cross-sectional views illustrating a structure of a memory device of one embodiment of the present invention.

FIG. 27 A cross-sectional view illustrating a structure of a memory device of one embodiment of the present invention.

FIG. 28 A cross-sectional view illustrating a structure of a memory device of one embodiment of the present invention.

FIG. 29 A circuit diagram illustrating a structure of a memory device of one embodiment of the present invention.

FIG. 30 A block diagram illustrating a structure example of a memory device of one embodiment of the present invention.

FIG. 31 Circuit diagrams illustrating structure examples of a memory device of one embodiment of the present invention.

FIG. 32 A circuit diagram illustrating a structure example of a memory device of one embodiment of the present invention.

FIG. 33 A cross-sectional view illustrating a structure of a memory device of one embodiment of the present invention.

FIG. 34 A block diagram illustrating a structure example of a memory device of one embodiment of the present invention.

FIG. 35 A block diagram and a circuit diagram illustrating a structure example of a memory device of one embodiment of the present invention.

FIG. 36 Block diagrams illustrating a structure example of a semiconductor device of one embodiment of the present invention.

FIG. 37 A block diagram and a circuit diagram illustrating a structure example of a semiconductor device of one embodiment of the present invention and a timing chart showing an operation example of the semiconductor device.

FIG. 38 A block diagram illustrating a structure example of a semiconductor device of one embodiment of the present invention.

FIG. 39 A circuit diagram illustrating a structure example of a semiconductor device of one embodiment of the present invention and a timing chart showing an operation example of the semiconductor device.

FIG. 40 A block diagram illustrating a configuration example of an AI system of one embodiment of the present invention.

FIG. 41 Block diagrams illustrating application examples of an AI system of one embodiment of the present invention.

FIG. 42 A schematic perspective view illustrating a configuration example of an IC into which an AI system of one embodiment of the present invention is incorporated.

FIG. 43 Diagrams each illustrating an electronic device of one embodiment of the present invention.

FIG. 44 Diagrams showing a sheet resistance value of an oxide in Example of the present invention.

FIG. 45 A diagram showing an oxygen barrier property of an insulator in Example of the present invention.

FIG. 46 A diagram showing electric characteristics of a transistor in Example of the present invention.

### MODE FOR CARRYING OUT THE INVENTION

Hereinafter, embodiments will be described with reference to drawings. However, the embodiments can be implemented with many different modes, and it will be readily appreciated by those skilled in the art that modes and details thereof can be changed in various ways without departing from the spirit and scope thereof. Thus, the present invention should not be interpreted as being limited to the following description of the embodiments.

In the drawings, the size, the layer thickness, or the region is exaggerated for clarity in some cases. Therefore, the size, the layer thickness, or the region is not limited to the illustrated scale. Note that the drawings are schematic views showing ideal examples, and embodiments of the present invention are not limited to shapes or values shown in the drawings. For example, in the actual manufacturing process, a layer, a resist mask, or the like might be unintentionally reduced in size by treatment such as etching, which is not illustrated in some cases for easy understanding. In the drawings, the same portions or portions having similar functions are denoted by the same reference numerals in different drawings and repeated description thereof is omitted, in some cases. Furthermore, the same hatch pattern is used for the portions having similar functions, and the portions are not especially denoted by reference numerals in some cases.

Especially in a top view (also referred to as a “plan view”), a perspective view, or the like, some components might not be illustrated for easy understanding of the invention. Furthermore, the description of some hidden lines and the like might be omitted.

The ordinal numbers such as first and second in this specification and the like are used for convenience and do not denote the order of steps or the stacking order of layers. Thus, for example, description can be made even when “first” is replaced with “second,” “third,” or the like, as appropriate. In addition, the ordinal numbers in this specification and the like do not correspond to the ordinal numbers which are used to specify one embodiment of the present invention in some cases.

In this specification, terms for describing arrangement, such as “over” and “under”, are used for convenience in describing a positional relationship between components with reference to drawings. Furthermore, the positional relationship between components is changed as appropriate in accordance with a direction in which each component is described. Thus, description can be rephrased appropriately according to the situation, without being limited by the terms used in the specification.

In the case where there is an explicit description, X and Y are connected, in this specification and the like, for example, the case where X and Y are electrically connected, X and Y are functionally connected, and X and Y are directly connected are disclosed in this specification and the like. Accordingly, without being limited to a predetermined connection relationship, for example, a connection relation shown in drawings or texts, a connection relationship other than one shown in drawings or texts is included in the drawings or the texts.

Here, X and Y each denote an object (e.g., a device, an element, a circuit, a wiring, an electrode, a terminal, a conductive film, or a layer).

Examples of the case where X and Y are directly connected include the case where an element that allows an electrical connection between X and Y (e.g., a switch, a transistor, a capacitor, an inductor, a resistor, a diode, a display element, a light-emitting element, and a load) is not connected between X and Y, and the case where X and Y are connected without the element that allows the electrical connection between X and Y (e.g., a switch, a transistor, a capacitor, an inductor, a resistor, a diode, a display element, a light-emitting element, and a load) provided therebetween.

For example, in the case where X and Y are electrically connected, one or more elements that enable an electrical connection between X and Y (e.g., a switch, a transistor, a capacitor, an inductor, a resistor, a diode, a display element, a light-emitting element, or a load) can be connected between X and Y. Note that the switch is controlled to be turned on or off. That is, a switch has a function of being in a conduction state (on state) or non-conduction state (off state) to control whether or not current flows. Alternatively, the switch has a function of selecting and changing a current path. Note that the case where X and Y are electrically connected includes the case where X and Y are directly connected.

An example of the case where X and Y are functionally connected is the case where one or more circuits that allow functional connection between X and Y (for example, a logic circuit (an inverter, a NAND circuit, a NOR circuit, or the like), a signal converter circuit (a DA converter circuit, an AD converter circuit, a gamma correction circuit, or the like), a potential level converter circuit (a power supply circuit (for example, a step-up circuit, a step-down circuit, or the like), a level shifter circuit for changing the potential level of a signal, or the like), a voltage source, a current source, a switching circuit, an amplifier circuit (a circuit capable of increasing signal amplitude, the amount of current, or the like, an operational amplifier, a differential amplifier circuit, a source follower circuit, a buffer circuit, or the like), a signal generator circuit, a memory circuit, a control circuit, or the like) can be connected between X and Y. For example, even when another circuit is interposed between X and Y, X and Y are functionally connected when a signal output from X is transmitted to Y. Note that the case where X and Y are functionally connected includes the case where X and Y are directly connected and the case where X and Y are electrically connected.

In this specification and the like, a transistor is an element having at least three terminals of a gate, a drain, and a source. The transistor includes a channel formation region between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which current mainly flows.

Furthermore, functions of a source and a drain might be switched when a transistor of opposite polarity is employed or a direction of current flow is changed in circuit operation, for example. Therefore, the terms “source” and “drain” is used interchangeably in this specification and the like in some cases.

Note that a channel length refers to, for example, a distance between a source (a source region or a source electrode) and a drain (a drain region or a drain electrode) in a region where a semiconductor (or a portion where current flows in a semiconductor when a transistor is in an on state) and a gate electrode overlap with each other or a region where a channel is formed in a top view of the transistor. Note that in one transistor, channel lengths in all regions are not necessarily the same. In other words, the channel length of one transistor is not fixed to one value in some cases. Thus, in this specification, the channel length is any one of values, the maximum value, the minimum value, or the average value in a region where a channel is formed.

The channel width refers to, for example, the length of a portion where a source and a drain face each other in a region where a semiconductor (or a portion where current flows in a semiconductor when a transistor is on) and a gate electrode overlap with each other, or a region where a channel is formed in a top view of the transistor. Note that in one transistor, channel widths in all regions are not necessarily the same. In other words, the channel width of one transistor is not fixed to one value in some cases. Thus, in this specification, the channel width is any one of values, the maximum value, the minimum value, or the average value in a region where a channel is formed.

Note that depending on transistor structures, a channel width in a region where a channel is actually formed (hereinafter also referred to as an “effective channel width”) is different from a channel width shown in a top view of a transistor (hereinafter also referred to as an “apparent channel width”) in some cases. For example, when a gate electrode covers a side surface of a semiconductor, an effective channel width is greater than an apparent channel width, and its influence cannot be ignored in some cases. For example, in a miniaturized transistor having a gate electrode covering a side surface of a semiconductor, the proportion of a channel formation region formed in the side surface of the semiconductor is increased in some cases. In that case, an effective channel width is greater than an apparent channel width.

In such a case, an effective channel width is difficult to estimate by actual measurement in some cases. For example, estimation of an effective channel width from a design value requires an assumption that the shape of a semiconductor is known. Accordingly, in the case where the shape of a semiconductor is not known accurately, it is difficult to measure an effective channel width accurately.

Thus, in this specification, an apparent channel width is referred to as a “surrounded channel width (SCW)” in some cases. Furthermore, in this specification, the simple term “channel width” refers to a surrounded channel width or an apparent channel width in some cases. Alternatively, in this specification, the simple term “channel width” refers to an effective channel width in some cases. Note that values of a channel length, a channel width, an effective channel width, an apparent channel width, a surrounded channel width, and the like can be determined, for example, by analyzing a cross-sectional TEM image and the like.

Note that an impurity in a semiconductor refers to, for example, elements other than the main components of a semiconductor. For example, an element with a concentration of lower than 0.1 atomic % can be regarded as an impurity. When an impurity is contained, for example, DOS (Density of States) in a semiconductor may be increased or the crystallinity may be decreased. In the case where the semiconductor is an oxide semiconductor, examples of an impurity which changes characteristics of the semiconductor include Group 1 elements, Group 2 elements, Group 13 elements, Group 14 elements, Group 15 elements, and transition metals other than the main components of the oxide semiconductor; hydrogen, lithium, sodium, silicon, boron, phosphorus, carbon, and nitrogen are given as examples. In the case of an oxide semiconductor, water also functions as an impurity in some cases. In addition, in the case of an oxide semiconductor, oxygen vacancies are formed by entry of impurities, for example. Furthermore, in the case where the semiconductor is silicon, examples of an impurity which changes the characteristics of the semiconductor include oxygen, Group 1 elements except hydrogen, Group 2 elements, Group 13 elements, and Group 15 elements.

Note that in this specification and the like, “silicon oxynitride film” is a film in which oxygen content is higher than nitrogen content in its composition. A silicon oxynitride film preferably contains, for example, oxygen, nitrogen, silicon, and hydrogen at concentrations ranging from 55 atomic % to 65 atomic %, 1 atomic % to 20 atomic %, 25 atomic % to 35 atomic %, and 0.1 atomic % to 10 atomic %, respectively. Moreover, “silicon nitride oxide film” is a film in which nitrogen content is higher than oxygen content in its composition. A silicon nitride oxide film preferably contains nitrogen, oxygen, silicon, and hydrogen at concentrations ranging from 55 atomic % to 65 atomic %, 1 atomic % to 20 atomic %, 25 atomic % to 35 atomic %, and 0.1 atomic % to 10 atomic %, respectively.

Moreover, in this specification and the like, the term “film” and the term “layer” can be interchanged with each other. For example, the term “conductive layer” can be changed into the term “conductive film” in some cases. another example, the term “insulating film” can be changed into the term “insulating layer” in some cases.

In addition, in this specification and the like, the term “insulator” can be replaced with an insulating film or an insulating layer. Moreover, the term “conductor” can be replaced with a conductive film or a conductive layer. Furthermore, the term “semiconductor” can be replaced with a semiconductor film or a semiconductor layer.

Furthermore, unless otherwise specified, transistors described in this specification and the like are field-effect transistors. Furthermore, unless otherwise specified, transistors described in this specification and the like are n-channel transistors. Thus, unless otherwise specified, the threshold voltage (also referred to as “Vₜₕ”) is larger than 0 V.

In this specification and the like, “parallel” indicates a state where two straight lines are placed such that the angle formed therebetween is greater than or equal to −10° and less than or equal to 10°. Thus, the case where the angle is greater than or equal to −5° and less than or equal to 5° is also included. The term “substantially parallel” indicates a state where two straight lines are placed such that the angle formed therebetween is greater than or equal to −30° and less than or equal to 30°. Moreover, “perpendicular” indicates a state where two straight lines are placed such that the angle formed therebetween is greater than or equal to 80° and less than or equal to 100°. Thus, the case where the angle is greater than or equal to 85° and less than or equal to 95° is also included. The term “substantially perpendicular” indicates a state where two straight lines are placed such that the angle formed therebetween is greater than or equal to 60° and less than or equal to 120°.

Furthermore, in this specification, in the case where a crystal is a trigonal crystal or a rhombohedral crystal, the crystal is regarded as a hexagonal crystal system.

Note that in this specification, a barrier film means a film having a function of inhibiting the passage of oxygen and impurities such as hydrogen, and the barrier film having conductivity is referred to as a conductive barrier film in some cases.

In this specification and the like, a metal oxide means an oxide of a metal in a broad expression. Metal oxides are classified into an oxide insulator, an oxide conductor (including a transparent oxide conductor), an oxide semiconductor (also simply referred to as an OS), and the like. For example, in the case where a metal oxide is used in an active layer of a transistor, the metal oxide is referred to as an oxide semiconductor in some cases. That is, in the case where an OS FET is stated, it can also be referred to as a transistor including an oxide or an oxide semiconductor.

### Embodiment 1

An example of a semiconductor device including a transistor 200 of one embodiment of the present invention is described below.

### Structure Example 1 of Semiconductor Device

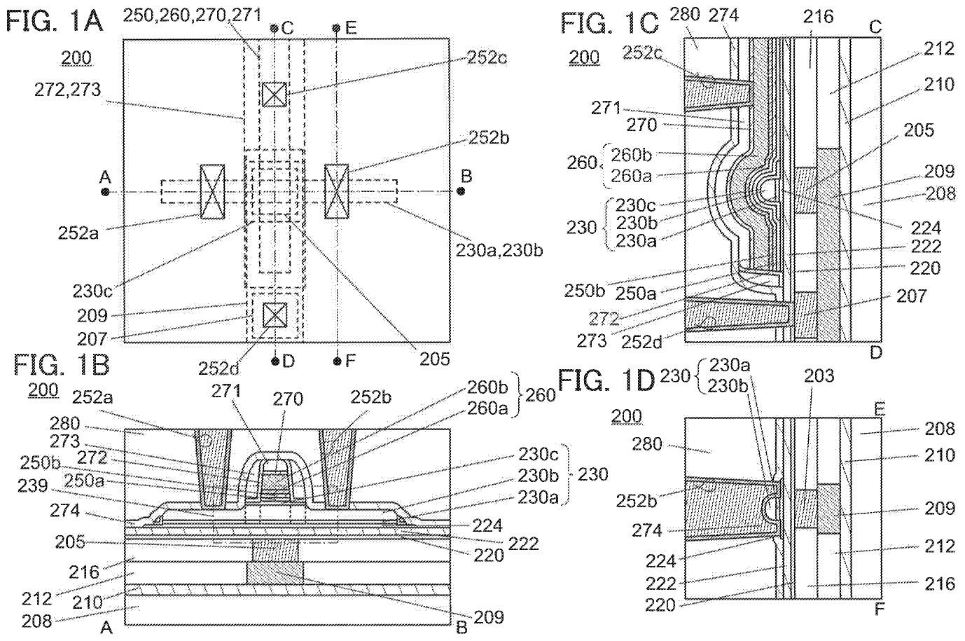

FIG. 1(A), FIG. 1(B), FIG. 1(C), and FIG. 1(D) are a top view and cross-sectional views of a semiconductor device of one embodiment of the present invention.

FIG. 1(A) is a top view of the transistor 200. FIG. 1(B), FIG. 1(C), and FIG. 1(D) are cross-sectional views of the transistor 200. Here, FIG. 1(B) is a cross-sectional view of a portion indicated by dashed-dotted line A-B in FIG. 1(A), and is also a cross-sectional view of the transistor 200 in the channel length direction. FIG. 1(C) is a cross-sectional view of a portion indicated by dashed-dotted line C-D in FIG. 1(A), and is also a cross-sectional view of the transistor 200 in the channel width direction. FIG. 1(D) is a cross-sectional view of a portion indicated by dashed-dotted line E-F in FIG. 1(A). For clarity of the drawing, some components are not illustrated in the top view of FIG. 1(A).

### [Transistor 200]

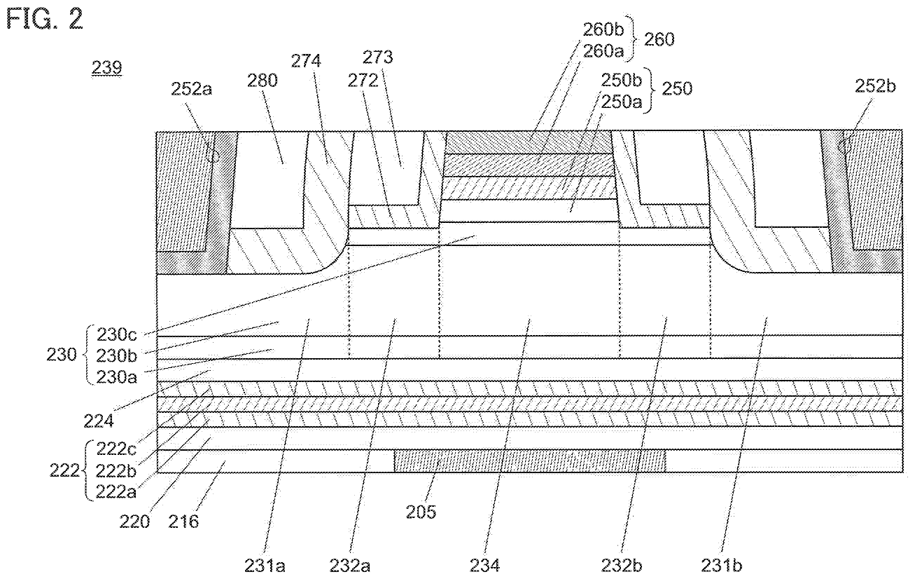

As illustrated in FIG. 1 and FIG. 2, the transistor 200 includes an insulator 208 placed over a substrate (not illustrated); a conductor 209 over an insulator 210 placed over the insulator 208; an insulator 212 placed around the conductor 209; a conductor 205 placed over the conductor 209 and the insulator 212; an insulator 216 placed around the insulator 216; the insulator 220 placed over the insulator 216 and the conductor 205; an insulator 222 (an insulator 222a, an insulator 222b, and an insulator 222c) placed over the insulator 220; an insulator 224 placed over the insulator 222; an oxide 230 (an oxide 230a, an oxide 230b, and an oxide 230c) placed over the insulator 224; an insulator 250 (an insulator 250a and an insulator 250b) placed over the oxide 230; a conductor 260 (a conductor 260a and a conductor 260b) placed over the insulator 250; an insulator 270 placed over the conductor 260; an insulator 271 placed over the insulator 270; an insulator 272 placed in contact with at least a side surface of the insulator 250 and the a side surface of the conductor 260; an insulator 273 placed in contact with part of a top surface and part of a side surface of the insulator 272; and an insulator 274 placed to cover at least the oxide 230, the insulator 271, the insulator 272, and the insulator 273.

In addition, an insulator 280 is placed to cover the transistor 200.

The insulator 212 can be formed by polishing an insulating film placed to cover the conductor 209 by a CMP method or the like to expose the conductor 209. Thus, the surfaces of the insulator 212 and the conductor 209 have high planarity.

Note that the method for forming the conductor 209 and the insulator 212 is not limited to the above. The insulator 212 may be formed first, and the conductor 209 may be formed to be embedded in an opening portion such as a groove or a slit formed in the insulator 212. Such a method for forming a conductor and an insulator is referred to as a damascene process. Alternatively, depending on a structure of the layer below the conductor 209, a single damascene process may be employed or a dual damascene process may be employed. A dual damascene process is preferably employed because the conductor 209 and a component such as an element or a wiring which are positioned in a layer below the conductor 209 can be directly connected to each other.

The insulator 216 can be formed by polishing an insulating film placed to cover the conductor 205 by a CMP method or the like to expose the conductor 205. Thus, the surfaces of the insulator 216 and the conductor 205 have high planarity. Note that the formation of the insulator 216 and the conductor 205 of one embodiment of the present invention is not limited thereto. The insulator 216 and the conductor 205 may be formed using the above-described damascene process.

The conductor 209 may have a stacked-layer structure. In this case, a structure is preferable in which a conductor having a better oxidation resistance than a conductor in a lower layer is placed over a conductor having better conductivity than a conductor in an upper layer. When a material that is less likely to be oxidized is used for the upper layer in the conductor 209, oxidation of the conductor 209 can be inhibited at the time of forming the insulator 216, at the time of forming the opening portion provided in the insulator 216, and at the time of forming the conductor 205. Thus, an increase in the electrical resistance due to oxidation of the conductor 209 can be inhibited. That is, the contact between the conductor 209 and the conductor 205 becomes favorable.

The conductor 205 may have a stacked-layer structure. In this case, a structure is preferable in which a conductor having a better oxidation resistance than a conductor in a lower layer is placed over a conductor having better conductivity than a conductor in an upper layer. When a material that is less likely to be oxidized is used for the upper layer in the conductor 205, oxidation of the conductor 205 can be inhibited at the time of forming the insulator 220. Thus, an increase in the electrical resistance due to oxidation of the conductor 205 can be inhibited.

As for the insulator 220, the insulator 222, and the insulator 224 that are placed between the conductor 205 and the oxide 230, the insulator 220 and the insulator 224 each preferably contain an oxide containing silicon, and further preferably is an oxide containing silicon and nitrogen. What is called a high-k material with a high dielectric constant is preferably used for the insulator 222.

Examples of the insulator with a high dielectric constant include aluminum oxide, gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

In the case where the insulator 222 has a three-layer structure of the insulator 222a, the insulator 222b, and the insulator 222c, the insulator 222 is formed with a stack of two kinds or three kinds of insulators selected from the above insulators with a high dielectric constant. The insulator 222a and the insulator 222c may be hafnium oxide, and the insulator 222b may be aluminum oxide, for example. Alternatively, the insulator 222a and the insulator 222c may be aluminum oxide, and the insulator 222b may be hafnium oxide. Note that the insulator 222 of the present invention is not limited to the three-layer structure. The insulator 222 may have a single-layer structure, a two-layer structure, or a stacked-layer structure of four or more layers.

Each layer of the insulator 222 is preferably formed by an ALD method. The insulator 220 and the insulator 224 can be formed by a plasma CVD method, but are preferably formed by an ALD method. In the case where the insulator 220, the insulator 222, and the insulator 224 are formed by an ALD method, what is called a multi-chamber ALD apparatus, which includes a plurality of deposition chambers, is preferably used as the apparatus for forming the insulators. With the use of a multi-chamber ALD apparatus, a substrate over which the insulators are formed can be in a reduced-pressure atmosphere from the beginning of the formation of the insulator 220 to the end of the formation of the insulator 224; thus, the insulator 220, the insulator 222, and the insulator 224 can be successively formed without being exposed to an air atmosphere. The insulator 220, the insulator 222, and the insulator 224 are successively formed, whereby contamination of an interface between the insulator 220 and the insulator 222 and an interface between the insulator 222 and the insulator 224 can be prevented; accordingly, a semiconductor device using these insulators can have favorable characteristics and high reliability.

Note that as illustrated in FIG. 1, the transistor 200 having a structure in which the oxide 230a, the oxide 230b, and the oxide 230c are stacked is illustrated; however, the present invention is not limited thereto. For example, a two-layer structure of the oxide 230a and the oxide 230b or a two-layer structure of the oxide 230b and the oxide 230c may be employed. That is, one of the oxide 230a and the oxide 230c is not necessarily provided. Alternatively, a stacked-layer structure of four or more layers may be employed. Alternatively, a single layer of only the oxide 230b may be employed. Moreover, although the transistor 200 having a structure in which the conductor 260a and the conductor 260b are stacked is illustrated, the present invention is not limited thereto. For example, a single layer or a stacked-layer structure of three or more layers may be employed.

Here, an enlarged view of a region 239 in the vicinity of a channel, which is surrounded by a dashed line in FIG. 1(B), is illustrated in FIG. 2.

As illustrated in FIG. 1(B) and FIG. 2, the oxide 230 includes a region 232 (a region 232a and a region 232b) between a region 234 functioning as a channel formation region of the transistor 200 and a region 231 (a region 231a and a region 231b) functioning as a source region and a drain region. The region 231 functioning as the source region and the drain region is a region having a high carrier density and reduced resistance. The region 234 functioning as the channel formation region is a region having a lower carrier density than the region 231 functioning as the source region and the drain region. Moreover, the region 232 is a region having a lower carrier density than the region 231 functioning as the source region and the drain region and having a higher carrier density than the region 234 functioning as the channel formation region.

The region 231 and the region 232 can be provided by addition of a rare gas typified by helium or argon to the oxide 230. For the addition of the rare gas, for example, an ion implantation method by which an ionized source gas is subjected to mass separation and then added, an ion doping method by which an ionized source gas is added without mass separation, a plasma immersion ion implantation method, or plasma treatment can be used.

It can be considered that when a rare gas is added to the oxide 230, a bond between a metal element and an oxygen atom in the oxide 230 is broken, and an oxygen vacancy is generated in the oxide 230. When impurities such as hydrogen are trapped by the oxygen vacancy, carriers are generated, and the resistance of the oxide 230, that is, the resistance of the region 231 and the region 232 is reduced. Impurities such as hydrogen exist in the oxide 230 in some cases. In this case, the impurities may exist without being connected to a metal element or an oxygen atom. The impurities can be supplied from an insulator provided in contact with the oxide 230, for example, from the insulator 274.

Examples of an element that forms an oxygen vacancy in the oxide 230 or an element that is bonded to an oxygen vacancy include boron and phosphorus. Hydrogen, carbon, nitrogen, fluorine, sulfur, chlorine, titanium, or the like can be used as well as boron and phosphorus. Other examples of the above elements include metal elements such as aluminum, chromium, copper, silver, gold, platinum, tantalum, nickel, molybdenum, tungsten, hafnium, vanadium, niobium, manganese, magnesium, zirconium, beryllium, indium, ruthenium, iridium, strontium, and lanthanum. One or more elements selected from the above elements may be added to the oxide 230. Among the above-described elements, boron or phosphorus is preferable as the element to be added. Since an apparatus in a manufacturing line for amorphous silicon or low-temperature polysilicon can be used for the addition of boron or phosphorus, capital investment can be reduced. The concentration of any of the above elements is measured by secondary ion mass spectrometry (SIMS) or the like.

The region 234 is a highly purified region where oxygen vacancies and impurities such as hydrogen are reduced as much as possible. The highly purified oxide becomes a substantially intrinsic region, and the region 234 can function as a channel formation region.

Although the region 232 does not overlap with the conductor 260 functioning as a gate electrode in FIG. 1 and FIG. 2, this embodiment is not limited thereto. Depending on the method for forming the region 231 and the region 232, the region 232 overlaps with the conductor 260 functioning as a gate electrode in some cases.

The region 232 can be a region having a lower carrier density than the region 231 functioning as the source region and the drain region and having a higher carrier density than the region 234 functioning as the channel formation region. In this case, the region 232 functions as a junction region between the channel formation region and the source region or the drain region.

The provision of the junction region is preferable because a high-resistance region is not formed between the region 231 functioning as the source region or the drain region and the region 234 functioning as the channel formation region, thereby increasing on-state current of the transistor.

The region 234 overlaps with the conductor 260. The region 234 is placed between the region 232a and the region 232b, and preferably has a lower concentration of at least one of a metal element such as indium and an impurity element such as hydrogen or nitrogen than that in each of the region 231 and the region 232.

In order that the concentration of at least one of a metal element such as indium and an impurity element such as hydrogen or nitrogen in the region 234 is lower than that in each of the region 231 and the region 232, the metal element or the impurity is added to the oxide 230 using the conductor 260 and the insulator 250 as masks. Alternatively, it is preferable to add the metal element or the impurity after formation of an insulating film to be the insulator 272 because the insulating film placed on the side surfaces of the conductor 260 and the insulator 250 can also function as a mask. With the use of the conductor 260, the insulator 250, and part of the insulating film as masks, the metal element or the impurity can be inhibited from being added to the region 234. That is, the width of the region 234 in the channel length direction depends on the widths of the conductor 260 and the insulator 250 in the channel length direction and the thickness of the insulating film. Thus, the widths of the conductor 260 and the insulator 250 in the channel length direction and the thickness of the insulating film are adjusted in accordance with the required value of the electrical characteristics and the circuit configuration of the transistor 200, whereby a desired width of the region 234 in the channel length direction can be obtained.

In addition, the insulator 272 and the insulator 273 are provided at least on the side surfaces of the conductor 260 and the insulator 250, and control a region where the oxide 230 and the insulator 274 that can supply impurities to the oxide 230 are in contact with each other. The region where the oxide 230 and the insulator 274 are in contact with each other serves as the region 231, and the region between the region 234 and the region 231 serve as the region 232. That is, the width of the region 232 in the channel length direction and the width of the region 231 in the channel length direction depend on the widths of the insulator 272 and the insulator 273 in the channel length direction.

The widths of the insulator 272 and the insulator 273 in the channel length direction depend on the thickness of the insulating film to be the insulator 272 and the thickness of an insulating film to be the insulator 273. Thus, the widths of insulating films are adjusted to adjust the widths of the insulator 272 and the insulator 273 in the channel length direction, in accordance with the required value of the electrical characteristics and the circuit configuration of the transistor 200, whereby a desired width of the region 232 in the channel length direction and a desired width of the region 231 in the channel length direction can be obtained.

In the oxide 230, boundaries between the region 231, the region 232, and the region 234 cannot be observed clearly in some cases. The concentrations of a metal element such as indium and an impurity element such as hydrogen or nitrogen detected in each region may be not only gradually changed between the regions, but also continuously changed (also referred to as gradation) in each region. That is, the region closer to the region 234, from the region 231 to the region 232, preferably has a lower concentration of a metal element such as indium and an impurity element such as hydrogen or nitrogen.

Furthermore, in FIG. 1(B) and FIG. 2, the region 234, the region 231, and the region 232 are formed in the oxide 230a, the oxide 230b, and the oxide 230c; however, without being limited thereto, it is acceptable as long as these regions are formed at least in the oxide 230b. Alternatively, these regions may be formed only in the oxide 230b and the oxide 230c, for example. Although the boundaries between the regions are illustrated as being substantially perpendicular to the interface between the insulator 224 and the oxide 230 in the drawings, this embodiment is not limited thereto. For example, the region 232 may project to the region 234 side in the vicinity of the surface of the oxide 230b, and recede to the region 231 side in the vicinity of a bottom surface of the oxide 230b.

Note that in the transistor 200, a metal oxide functioning as an oxide semiconductor (hereinafter, also referred to as an oxide semiconductor) is preferably used as the oxide 230. Since a transistor using an oxide semiconductor has an extremely low leakage current (off-state current) in a non-conduction state, a semiconductor device with low power consumption can be provided. Moreover, an oxide semiconductor can be deposited by a sputtering method or the like, and thus can be used for a transistor included in a highly integrated semiconductor device.

On the other hand, the transistor using an oxide semiconductor is likely to have its electrical characteristics changed by impurities and oxygen vacancies in the oxide semiconductor; accordingly, the reliability is decreased in some cases. Furthermore, hydrogen contained in an oxide semiconductor reacts with oxygen bonded to a metal atom to be water, and thus forms an oxygen vacancy in some cases. Entry of hydrogen into the oxygen vacancy generates an electron serving as a carrier in some cases. Accordingly, a transistor using an oxide semiconductor containing oxygen vacancies in the channel formation region is likely to have normally-on characteristics. Thus, it is preferable that oxygen vacancies in the channel formation region be reduced as much as possible.

In particular, when oxygen vacancies exist at an interface between the region 234 of the oxide 230 where a channel is formed and the insulator 250 functioning as a gate insulating film, a change in the electrical characteristics is likely to occur, resulting in a decrease in reliability in some cases.

In view of the above, the insulator 250 in contact with the region 234 of the oxide 230 preferably contains oxygen at a higher proportion than oxygen in the stoichiometric composition (also referred to as excess oxygen). That is, excess oxygen contained in the insulator 250 is diffused into the region 234, whereby oxygen vacancies in the region 234 can be reduced.

When the insulator 250 has a stacked-layer structure including the insulator 250a and the insulator 250b, and the insulator 250b is formed over the insulator 250a in an atmosphere containing oxygen, for example, a larger amount of oxygen, that is, excess oxygen can be contained in 250a. Alternatively, when the insulator 250a is exposed to an atmosphere containing oxygen just before the formation of the insulator 250b, a larger amount of oxygen can be contained in the insulator 250a. The atmosphere containing oxygen includes not only an atmosphere containing oxygen molecules but also an atmosphere containing at least one of oxygen ions, oxygen radicals, oxygen molecular ions, oxygen molecular radicals, and ozone, which are generated by exciting oxygen molecules.

For the insulator 250a, silicon oxide or silicon oxynitride can be used, for example. The insulator 250a can be formed by an ALD method or a plasma CVD method. For the insulator 250b, what is called a high-k material with a high dielectric constant is preferably used.

Examples of the insulator with a high dielectric constant include aluminum oxide, gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

The insulator 250b can be formed by an ALD method or a sputtering method. In the case where the insulator 250a and the insulator 250b are formed by an ALD method, what is called a multi-chamber ALD apparatus, which includes a plurality of deposition chambers, is preferably used as the apparatus for forming the insulators. With the use of a multi-chamber ALD apparatus, a substrate over which the insulators are formed can be in a reduced-pressure atmosphere from the beginning of the formation of the insulator 250a to the end of the formation of the insulator 250b; thus, the insulator 250a and the insulator 250b can be successively formed without being exposed to an air atmosphere. The insulator 250a and the insulator 250b are successively formed, whereby contamination of an interface between the insulator 250a and the insulator 250b can be prevented; accordingly, a semiconductor device using these insulators can have favorable characteristics and high reliability.

The conductor 260 is provided over the insulator 250. The conductor 260 includes the conductor 260a and the conductor 260b over the conductor 260a. Titanium nitride or the like is preferably used for the conductor 260a. Moreover, a metal with high conductivity such as tungsten can be used for the conductor 260b, for example.

The conductor 260a can be formed by an ALD method or a sputtering method. In the case where the insulator 250a, the insulator 250b, and the conductor 260a are formed by an ALD method, what is called a multi-chamber ALD apparatus, which includes a plurality of deposition chambers, is preferably used as the apparatus for forming the insulators and the conductor. With the use of a multi-chamber ALD apparatus, a substrate over which the insulators and the conductor are formed can be in a reduced-pressure atmosphere from the beginning of the formation of the insulator 250a to the end of the formation of the conductor 260a; thus, the insulator 250a, the insulator 250b, and the conductor 260a can be successively formed without being exposed to an air atmosphere. The insulator 250a, the insulator 250b, and the conductor 260a are successively formed, whereby contamination of the interface between the insulator 250a and the insulator 250b and an interface between the insulator 250b and the conductor 260a can be prevented. A semiconductor device in which contamination of the gate insulating film and an interface between the gate insulating film and the gate electrode is reduced can have favorable characteristics and high reliability.

The conductor 260b can be formed by a sputtering method, an ALD method, or a metal CVD method.

In addition, the insulator 272 is preferably provided in contact with at least the side surface of the insulator 250. For example, it is preferable that the insulator 272 have a function of inhibiting diffusion of oxygen (e.g., at least one of oxygen atoms, oxygen molecules, and the like) (that the insulator 272 do not easily transmit the above oxygen). When the insulator 272 has a function of inhibiting diffusion of oxygen, oxygen in an excess-oxygen region is not diffused to the insulator 274 side and is efficiently supplied to the region 234. Thus, the formation of oxygen vacancies at the interface between the oxide 230 and the insulator 250 is inhibited, leading to an improvement in the reliability of the transistor 200.

In order to form the insulator 272 on the side surface of the insulator 250 with good coverage, an ALD method is preferably used. With the use of an ALD method, the insulator 272 can be formed on the side surface of the insulator to have a uniform thickness, which is effective to inhibit diffusion of oxygen contained in the insulator 250.

It is also preferable that oxygen, i.e., excess oxygen be supplied to the insulator 250 and/or the oxide 230 when the insulator 272 is formed. Thus, the insulator 272 is preferably formed in an atmosphere containing oxygen. Alternatively, the insulator 272 is preferably formed after the insulator 250 is exposed to an atmosphere containing oxygen just before the formation of the insulator 272.

Furthermore, the transistor 200 is preferably surrounded by an insulator having a barrier property that prevents entry of impurities such as water and hydrogen. The insulator having a barrier property is an insulator that uses an insulating material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, and the like), and a copper atom (an insulating material which does not easily transmit the above impurities). Alternatively, it is preferable to use an insulating material having a function of inhibiting diffusion of oxygen (e.g., at least one of oxygen atoms, oxygen molecules, and the like) (an insulating material which does not easily transmit the above oxygen).

The structure of the semiconductor device including the transistor 200 of one embodiment of the present invention is described in detail below.

In the transistor 200, the conductor 260 functions as a first gate electrode in some cases. The conductor 205 functions as a second gate electrode in some cases. In that case, by changing a potential applied to the conductor 205 not in synchronization with but independently of a potential applied to the conductor 260, the threshold voltage of the transistor 200 can be controlled. In particular, by applying a negative potential to the conductor 205, the threshold voltage of the transistor 200 can be shifted in the positive direction. In addition, when the threshold voltage of the transistor 200 is higher than 0 V, the off-state current can be reduced. Accordingly, a drain current when a voltage applied to the conductor 260 is 0 V can be reduced.

The conductor 205 functioning as the second gate electrode is placed to overlap with the oxide 230 and the conductor 260.

That is, the channel formation region of the region 234 can be electrically surrounded by the electric field of the conductor 260 functioning as the first gate electrode and the electric field of the conductor 205 functioning as the second gate electrode. In this specification, a transistor structure in which a channel formation region is electrically surrounded by electric fields of a first gate electrode and a second gate electrode is referred to as a surrounded channel (S-channel) structure.

For the conductor 205, a conductive material containing tungsten, copper, or aluminum as its main component is preferably used. Note that the conductor 205 is illustrated as a single layer but may have a stacked-layer structure; for example, a second conductive material containing titanium, titanium nitride, tantalum, tantalum nitride, ruthenium, ruthenium oxide, or the like may be provided over a first conductive material containing tungsten, copper, or aluminum as its main component. In particular, when a material with a higher oxidation resistance (being less likely to be oxidized) than the first conductive material is used as the second conductive material, oxidation of the first conductive material can be inhibited and an increase in electrical resistance or a contact resistance with a plug or the like electrically connected to the conductor 205 can be inhibited.

The conductor 209 can function as an electrode or a wiring. In the case where the conductor 205 is used as the second gate electrode of the transistor 200, part of the conductor 209 can function as a gate wiring. In this case, the conductor 205 and a conductor 252d may be electrically connected to each other through a conductor 207 and the conductor 209. The conductor 207 can be fabricated in the same step as the conductor 205.

The insulator 210 preferably functions as a barrier insulating film for preventing impurities such as water and hydrogen from entering the transistor from the substrate side. Accordingly, for the insulator 214, it is preferable to use an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material which does not easily transmit the above impurities). Alternatively, it is preferable to use an insulating material having a function of inhibiting diffusion of oxygen (e.g., at least one of oxygen atoms, oxygen molecules, and the like) (an insulating material which does not easily transmit the above oxygen).

For example, aluminum oxide or silicon nitride is preferably used for the insulator 210. Thus, impurities such as hydrogen and water can be inhibited from being diffused to the transistor side through the insulator 210. In addition, oxygen contained in the insulator 224 and the like can be inhibited from being diffused to the substrate side through the insulator 210.

Moreover, the insulator 212 and the insulator 216 functioning as interlayer films preferably have a lower permittivity than the insulator 210. When a material with a low permittivity is used for an interlayer film, the parasitic capacitance generated between wirings can be reduced.

For example, as the insulator 212 and the insulator 216 functioning as interlayer films, a single layer or a stacked layer of an insulator such as silicon oxide, silicon oxynitride, silicon nitride oxide, aluminum oxide, hafnium oxide, tantalum oxide, zirconium oxide, lead zirconate titanate (PZT), strontium titanate (SrTiO₃), or (Ba,Sr)TiO₃ (BST) can be used. Alternatively, to the insulator of these, aluminum oxide, bismuth oxide, germanium oxide, niobium oxide, silicon oxide, titanium oxide, tungsten oxide, yttrium oxide, or zirconium oxide may be added, for example. Alternatively, the insulator may be subjected to nitriding treatment. The above insulator over which silicon oxide, silicon oxynitride, or silicon nitride is stacked may be used.

The insulator 220, the insulator 222, and the insulator 224 each have a function of a gate insulator.

Here, as the insulator 224 in contact with the oxide 230, an oxide insulator that contains more oxygen than that in the stoichiometric composition is preferably used. That is, an excess-oxygen region is preferably formed in the insulator 224. When such an insulator containing excess oxygen is provided in contact with the oxide 230, oxygen vacancies in the oxide 230 can be reduced and reliability can be improved.

As the insulator including an excess-oxygen region, specifically, an oxide material from which part of oxygen is released by heating is preferably used. An oxide that releases part of oxygen by heating is an oxide film of which the amount of released oxygen converted into oxygen atoms is greater than or equal to 1.0×10¹⁸ atoms/cm³, preferably greater than or equal to 3.0×10²⁰ atoms/cm³ in TDS (Thermal Desorption Spectroscopy) analysis. Note that the temperature of the film surface in the TDS analysis is preferably in a range higher than or equal to 100° C. and lower than or equal to 700° C., or higher than or equal to 100° C. and lower than or equal to 400° C.

For the insulator 224, silicon oxide or silicon oxynitride can be used, for example. The thickness of the insulator 224 is greater than or equal to 1 nm and less than or equal to 30 nm, preferably greater than or equal to 1 nm and less than or equal to 10 nm, further preferably greater than or equal to 1 nm and less than or equal to 5 nm.

In the case where the insulator 224 includes an excess-oxygen region, it is preferable that the insulator 222 have a function of inhibiting diffusion of oxygen (e.g., at least one of oxygen atoms and oxygen molecules) (that the insulator 222 do not easily transmit the above oxygen).

When the insulator 222 has a function of inhibiting diffusion of oxygen, oxygen in the excess-oxygen region is not diffused to the insulator 220 side and thus can be efficiently supplied to the oxide 230. In addition, the conductor 205 can be inhibited from reacting with oxygen in the excess-oxygen region included in the insulator 224.

For the insulator 222, it is preferable to use a single layer or a stacked layer of an insulator containing what is called a high-k material such as aluminum oxide, hafnium oxide, tantalum oxide, zirconium oxide, lead zirconate titanate (PZT), strontium titanate (SrTiO₃), or (Ba,Sr)TiO₃ (BST), for example. When a high-k material is used for the insulator functioning as a gate insulator, miniaturization and high integration of the transistor become possible. It is particularly preferable to use an insulating material such as aluminum oxide and hafnium oxide having a function of inhibiting diffusion of oxygen, impurities, and the like (an insulating material which does not easily transmit the above oxygen). When formed using such a material, the insulator 222 can function as a layer that prevents release of oxygen from the oxide 230 and entry of impurities such as hydrogen from the periphery of the transistor 200.

Alternatively, to the insulator of these, aluminum oxide, bismuth oxide, germanium oxide, niobium oxide, silicon oxide, titanium oxide, tungsten oxide, yttrium oxide, or zirconium oxide may be added, for example. Alternatively, the insulator may be subjected to nitriding treatment. The above insulator over which silicon oxide, silicon oxynitride, or silicon nitride is stacked may be used.

The insulator 222 preferably has a stacked-layer structure including three layers of the insulator 222a, the insulator 222b, and the insulator 222c. At this time, the insulator 222a and the insulator 222c may be hafnium oxide, and the insulator 222b may be aluminum oxide. Alternatively, the insulator 222a and the insulator 222c may be aluminum oxide, and the insulator 222b may be hafnium oxide. The insulator 222 is not limited to the stacked-layer structure including three layers. The insulator 222 may have a single-layer structure, a two-layer structure, or a stacked-layer structure of four or more layers.

The thicknesses of the insulator 222a, the insulator 222b, and the insulator 222c are each greater than or equal to 0.5 nm and less than or equal to 5 nm, preferably greater than or equal to 1 nm and less than or equal to 3 nm. For example, a 2-nm-thick insulator 222a including hafnium oxide, a 2-nm-thick insulator 222b including aluminum oxide, and a 2-nm-thick insulator 222c including hafnium oxide are successively deposited by an ALD method. In this case, the thickness of the insulator 222 is 6 nm. Note that the structure of the insulator 222 of the present invention is not limited thereto. The thicknesses of the insulator 222a, the insulator 222b, and the insulator 222c may be the same or different from each other, or any one of the thicknesses may be different.

It is preferable that the insulator 220 be thermally stable. Because silicon oxide and silicon oxynitride are thermally stable, combination of silicon oxide or silicon oxynitride with an insulator which is a high-k material allows the stacked-layer structure to be thermally stable and have a high dielectric constant, for example. The thickness of the insulator 220 is greater than or equal to 1 nm and less than or equal to 10 nm, preferably greater than or equal to 1 nm and less than or equal to 5 nm.

Note that the insulator 220, the insulator 222, and the insulator 224 may each have a stacked-layer structure of two or more layers. In that case, without limitation to a stacked-layer structure formed of the same material, a stacked-layer structure formed of different materials may be employed. Moreover, although a structure in which the insulator 220, the insulator 222, and the insulator 224 function as gate insulators in the transistor 200 is described, this embodiment is not limited thereto. For example, two layers or one layer of any of the insulator 220, the insulator 222, and the insulator 224 may be provided as a gate insulator may be employed.

The oxide 230 includes the oxide 230a, the oxide 230b over the oxide 230a, and the oxide 230c over the oxide 230b. The oxide 230 includes the region 231, the region 232, and the region 234. Note that at least part of the region 231 is preferably in contact with the insulator 274. Moreover, it is preferable that at least part of the region 231 have a higher concentration of at least one of hydrogen, nitrogen, and a metal element such as indium than the region 234.

When the transistor 200 is turned on, the region 231a or the region 231b functions as the source region or the drain region. At least part of the region 234 functions as the region where a channel is formed.

Here, as illustrated in FIG. 2, the oxide 230 preferably includes the region 232. When the region 232 is a junction region, on-state current can be increased and leakage current (off-state current) in a non-conduction state can be reduced.

When the oxide 230b is included over the oxide 230a, impurities can be inhibited from being diffused into the oxide 230b from the components formed below the oxide 230a. Moreover, when the oxide 230b is included under the oxide 230c, impurities can be inhibited from being diffused into the oxide 230b from the components formed above the oxide 230c.

That is, the region 234 provided in the oxide 230b is surrounded by the oxide 230a and the oxide 230c, the concentration of impurities such as hydrogen and nitrogen in the region can be kept low, and the concentration of oxygen can be kept high. A semiconductor device using the oxide 230 having such a structure has favorable electrical characteristics and high reliability.

The oxide 230 has a curved surface between the side surface and the top surface. That is, an end portion of the side surface and an end portion of the top surface are preferably curved (hereinafter such a curved shape is also referred to as a rounded shape). The radius of curvature of the curved surface at an end portion of the oxide 230b is greater than or equal to 3 nm and less than or equal to 10 nm, preferably greater than or equal to 5 nm and less than or equal to 6 nm.

As the oxide 230, a metal oxide functioning as an oxide semiconductor (hereinafter also referred to as an oxide semiconductor) is preferably used. For example, a metal oxide having an energy gap of 2 eV or more, preferably 2.5 eV or more is preferably used as the metal oxide to be the region 234. With the use of a metal oxide having such a wide energy gap, the off-state current of the transistor can be reduced.

Note that in this specification and the like, a metal oxide containing nitrogen is also collectively referred to as a metal oxide in some cases. Moreover, a metal oxide containing nitrogen may be referred to as a metal oxynitride.

A transistor using an oxide semiconductor has an extremely low leakage current in a non-conduction state; thus, a semiconductor device with low power consumption can be provided. Moreover, an oxide semiconductor can be deposited by a sputtering method or the like, and thus can be used for a transistor included in a highly integrated semiconductor device.

For example, as the oxide 230, a metal oxide such as an In—M—Zn oxide (the element M is one or more kinds selected from aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like) is preferably used. Furthermore, as the oxide 230, an In—Ga oxide or an In—Zn oxide may be used.

Here, the region 234 of the oxide 230 is described.

The region 234 preferably has a stacked-layer structure of oxides which differ in the atomic ratio of metal elements. Specifically, in the case of the stacked-layer structure of the oxide 230a and the oxide 230b, the atomic proportion of the element M in constituent elements in the metal oxide used as the oxide 230a is preferably greater than the atomic proportion of the element M in constituent elements in the metal oxide used as the oxide 230b. Moreover, the atomic ratio of the element M to In in the metal oxide used as the oxide 230a is preferably greater than the atomic ratio of the element M to In in the metal oxide used as the oxide 230b. Furthermore, the atomic ratio of In to the element M in the metal oxide used as the oxide 230b is preferably greater than the atomic ratio of In to the element M in the metal oxide used as the oxide 230a. A metal oxide that can be used as the oxide 230a or the oxide 230b can be used as the oxide 230c.

As the oxide 230a, for example, a metal oxide having a composition of In:Ga:Zn=1:3:4, In:Ga:Zn=1:3:2, or In:Ga:Zn=1:1:1 can be used. As the oxide 230b, for example, a metal oxide having a composition of In:Ga:Zn=4:2:3, In:Ga:Zn=1:1:1, or In:Ga:Zn=5:1:6 can be used. As the oxide 230c, for example, a metal oxide having a composition of In:Ga:Zn=1:3:4, In:Ga:Zn=1:3:2, In:Ga:Zn=4:2:3, or In:Ga:Zn=1:1:1 can be used. Note that the above composition represents the atomic ratio of an oxide formed over a substrate or the atomic ratio of a sputtering target.

A combination of a metal oxide having a composition of In:Ga:Zn=1:3:4 as the oxide 230a, a metal oxide having a composition of In:Ga:Zn=4:2:3 as the oxide 230b, a metal oxide having a composition of In:Ga:Zn=1:3:4 as the oxide 230c is particularly preferable because the oxide 230b can be sandwiched between the oxide 230a and the oxide 230b each having a wider energy gap. Here, each of the oxide 230a and the oxide 230c having a wide energy gap relative to the oxide 230b is referred to as a wide gap, and the oxide 230b having a narrow energy gap relative to the oxide 230a and the oxide 230c is referred to as a narrow gap in some cases. The wide gap and the narrow gap are described in [Composition of metal oxide].

Next, the region 231 of the oxide 230 is described.

The region 231 is a region whose resistance is reduced by addition of a metal atom such as indium, a rare gas such as helium or argon, or impurities such as hydrogen and nitrogen to a metal oxide provided as the oxide 230. Note that each of the regions has higher conductivity than at least the oxide 230b in the region 234. Note that for addition of a metal atom, a rare gas, or impurities to the region 231, for example, at least one of a metal element, a rare gas, and impurities is added as a dopant by an ion implantation method by which an ionized source gas is subjected to mass separation and then added, an ion doping method by which an ionized source gas is added without mass separation, a plasma immersion ion implantation method, or plasma treatment.

That is, when the content percentage of a metal atom such as indium in the region 231 of the oxide 230 is increased, the electron mobility can be increased and the resistance can be reduced.

Furthermore, when the insulator 274 containing elements serving as impurities is deposited in contact with the oxide 230, impurities can be added to the region 231.

That is, the resistance of the region 231 to which an element that forms an oxygen vacancy or an element trapped by an oxygen vacancy is added is reduced. Typical examples of such an element include hydrogen, boron, carbon, nitrogen, fluorine, phosphorus, sulfur, chlorine, titanium, and a rare gas. Typical examples of the rare gas element include helium, neon, argon, krypton, and xenon. Accordingly, the region 231 are made to contain one or more of the above elements.

Alternatively, as the insulator 274, a film which extracts and absorbs oxygen contained in the region 231 may be used. When oxygen is extracted, oxygen vacancies are generated in the region 231. Hydrogen, boron, carbon, nitrogen, fluorine, phosphorus, sulfur, chlorine, titanium, a rare gas, or the like is trapped by oxygen vacancies, whereby the resistance of the region 231 is reduced.

The width of the region 232 in the channel length direction can be controlled by the widths of the insulator 272 and the insulator 273.

Thus, by appropriately selecting the area of the region 232, a transistor having electrical characteristics that meet the demand for the circuit design can be easily provided.

The insulator 250 functions as a gate insulating film. The insulator 250 is preferably placed in contact with the top surface of the oxide 230c. The insulator 250 is preferably formed using an insulator from which oxygen is released by heating. The insulator 250 is an oxide film of which the amount of released oxygen converted into oxygen atoms is greater than or equal to 1.0×10¹⁸ atoms/cm³, preferably greater than or equal to 3.0×10²⁰ atoms/cm³ in thermal desorption spectroscopy analysis (TDS analysis), for example. Note that temperature of the film surface in the TDS analysis is preferably in a range higher than or equal to 100° C. and lower than or equal to 700° C., or higher than or equal to 100° C. and lower than or equal to 500° C.

The insulator 250 may have a stacked-layer structure including the insulator 250a and the insulator 250b, for example. When an insulator from which oxygen is released by heating is provided as the insulator 250a in contact with the top surface of the oxide 230c, oxygen can be efficiently supplied to the region 234 of the oxide 230b. Furthermore, as in the insulator 224, the concentration of impurities such as water and hydrogen in the insulator 250a is preferably reduced. The thickness of the insulator 250a is greater than or equal to 1 nm and less than or equal to 20 nm, preferably greater than or equal to 1 nm and less than or equal to 10 nm, further preferably greater than or equal to 1 nm and less than or equal to 5 nm.

The insulator 250b is preferably an insulator that can supply oxygen to the insulator 250a at or after the formation of the insulator 250b. When such an insulator is formed in an atmosphere containing oxygen or the insulator 250a is exposed to an atmosphere containing oxygen just before the formation of the insulator 250b, a larger amount of oxygen, that is, excess oxygen can be contained in 250a. Alternatively, the insulator 250b can be formed using a target containing oxygen. For example, aluminum oxide is formed in an atmosphere containing oxygen by an ALD method or a sputtering method. The thickness of the insulator 250b is greater than or equal to 1 nm and less than or equal to 20 nm, preferably greater than or equal to 1 nm and less than or equal to 10 nm, further preferably greater than or equal to 1 nm and less than or equal to 5 nm.

When the insulator 250b is provided over the insulator 250a, a larger amount of oxygen, that is, excess oxygen can be contained in the insulator 250a.

The conductor 260 functioning as the first gate electrode includes the conductor 260a and the conductor 260b over the conductor 260a. Titanium nitride or the like is preferably used for the conductor 260a. Moreover, a metal with high conductivity such as tungsten can be used for the conductor 260b, for example.

The conductor 260a can be formed by an ALD method or a sputtering method. In the case where the insulator 250a, the insulator 250b, and the conductor 260a are formed by an ALD method, what is called a multi-chamber ALD apparatus, which includes a plurality of deposition chambers, is preferably used as the apparatus for forming the insulators and the conductor. With the use of a multi-chamber ALD apparatus, a substrate over which the insulators and the conductor are formed can be in a reduced-pressure atmosphere from the beginning of the formation of the insulator 250a to the end of the formation of the conductor 260a; thus, the insulator 250a, the insulator 250b, and the conductor 260a can be successively formed without being exposed to an air atmosphere. The insulator 250a, the insulator 250b, and the conductor 260a are successively formed, whereby contamination of the interface between the insulator 250a and the insulator 250b and the interface between the insulator 250b and the conductor 260a can be prevented. A semiconductor device in which contamination of the gate insulating film and an interface between the gate insulating film and the gate electrode is reduced can have favorable characteristics and high reliability.

The conductor 260b can be formed by a sputtering method, an ALD method, or a metal CVD method.

In the case where potentials are applied to the conductor 260 and the conductor 205, the channel formation region formed in the oxide 230 can be covered with an electric field generated from the conductor 260 and an electric field generated from the conductor 205.

That is, the channel formation region in the region 234 can be electrically surrounded by the electric field of the conductor 260 having a function of the first gate electrode and the electric field of the conductor 205 having a function of the second gate electrode.

The insulator 272 functioning as a barrier film is provided in contact with the side surface of the insulator 250 and the side surface of the conductor 260. In addition, the insulator 270 functioning as a barrier film is provided over the conductor 260.

Here, for the insulator 270 and the insulator 272, an insulating material that has a function of inhibiting the passage of oxygen and impurities such as water and hydrogen is preferably used. For example, an oxide insulator containing one or both of aluminum and hafnium can be used. Aluminum oxide, hafnium oxide, an oxide containing aluminum and hafnium (hafnium aluminate), or the like is preferably used for the oxide insulator containing one or both of aluminum and hafnium. In this manner, oxygen in the insulator 250 can be prevented from being diffused to the outside. In addition, impurities such as hydrogen and water can be inhibited from entering the oxide 230 from the end portion of the insulator 250 or the like.

By provision of the insulator 270 and the insulator 272, a top surface and the side surface of the conductor 260 and the side surface of the insulator 250 can be covered with the insulator having a function of inhibiting the passage of oxygen and impurities such as water and hydrogen. This can prevent oxidation of the conductor 260 and entry of impurities such as water and hydrogen into the oxide 230 through the conductor 260 and the insulator 250. Thus, the insulator 270 and the insulator 272 function as side barriers that protect the gate electrode and the gate insulating film.

In order to form the insulator 272 on the side surface of the insulator 250 and the side surface of the conductor 260 with good coverage, an ALD method is preferably used. With the use of an ALD method, the insulator 272 can be formed on the side surface of the insulator 250 to have a uniform thickness; thus, using an ALD method for the formation of the insulator 272 is effective to inhibit diffusion of oxygen contained in the insulator 250 and oxidation of the conductor 260.

It is also preferable that oxygen, i.e., excess oxygen be supplied to the insulator 250 and/or the oxide 230 when the insulator 272 is formed. Thus, the insulator 272 is preferably formed in an atmosphere containing oxygen. Alternatively, the insulator 272 is preferably formed after the insulator 250 is exposed to an atmosphere containing oxygen just before the formation of the insulator 272.

The insulator 271 is provided over the insulator 270. The insulator 271 can be used as a hard mask when the conductor 260 and the insulator 250 are formed. The insulator 271 preferably has a lower permittivity than the insulator 270. When a semiconductor device has a structure in which a capacitor is provided in the same layer as the transistor 200 using part of components of the transistor 200, a material with a low permittivity is used for the insulator 271, whereby the parasitic capacitance generated between a conductor 130 described later and the conductor 260 can be reduced, which will be described in detail later. A material similar to that for the insulator 212 and the insulator 216 can be used for the insulator 271.

In the case where the transistor is miniaturized and formed so that a channel length is approximately greater than or equal to 10 nm and less than or equal to 30 nm, impurity elements contained in the structure bodies provided in the vicinity of the transistor 200 might be diffused, and the region 231a and the region 231b, or the region 232a and the region 232b might be electrically connected to each other.

In view of the above, the insulator 272 and the insulator 273 are formed as described in this embodiment so that impurities such as hydrogen and water can be inhibited from entering the insulator 250 and the conductor 260, and oxygen in the insulator 250 can be prevented from being diffused to the outside. Accordingly, when a first gate voltage is 0 V, the source region and the drain region can be prevented from being electrically connected to each other directly or through the region 232 or the like.

The insulator 273 preferably has a lower permittivity than the insulator 272. When a semiconductor device has a structure in which a capacitor is provided in the same layer as the transistor 200 using part of components of the transistor 200, a material with a low permittivity is used for the insulator 273, whereby the parasitic capacitance generated between the conductor 130 described later and the conductor 260 can be reduced, which will be described in detail later. A material similar to that for the insulator 212 and the insulator 216 can be used for the insulator 273.

In this embodiment, the side surfaces of at least the insulator 250, the conductor 260, the insulator 270, and the insulator 271 are tapered. When an insulating film to be the insulator 272 and the insulator 273 is formed, the side surfaces of the insulator 250 and the conductor 260 are preferably tapered because coverage is improved. However, the present invention is not limited to this. When the insulator 272 and the insulator 273 are formed on the side surfaces of the insulator 250 and the conductor 260, it is preferable that at least the side surfaces of the insulator 250 and the conductor 260 be perpendicular to the surface of the substrate or the surfaces of the insulator 220 and the insulator 222. The angle of the side surfaces of the insulator 250 and the conductor 260 can be adjusted as appropriate in consideration of the ease of the fabrication in the process.

The insulator 274 is provided to cover at least the oxide 230, the insulator 271, the insulator 272, and the insulator 273.

Moreover, for the insulator 274, an insulating material having a function of inhibiting the passage of oxygen and impurities such as water and hydrogen is preferably used. For the insulator 274, silicon nitride, silicon nitride oxide, silicon oxynitride, aluminum nitride, or aluminum nitride oxide is preferably used, for example. When such an insulator 274 is formed, entry of oxygen through the insulator 274 and supply of oxygen to oxygen vacancies in the region 231a and the region 231b, which decrease the carrier density, can be prevented. Furthermore, impurities such as water and hydrogen can be prevented from passing through the insulator 274 and being diffused into the region 234.

Note that when the region 231 is provided by deposition of the insulator 274, the insulator 274 preferably contains at least one of hydrogen and nitrogen. When an insulator containing impurities such as hydrogen and nitrogen is used as the insulator 274, impurities such as hydrogen and nitrogen are added to the oxide 230, so that the resistance of the region 231 of the oxide 230 can be reduced.

The insulator 280 functioning as an interlayer film is preferably provided over the insulator 274. As in the insulator 224 or the like, the concentration of impurities such as water and hydrogen in the film of the insulator 280 is preferably reduced. Note that the insulator 280 may have a stacked-layer structure of similar insulators.

The insulator 280 preferably has a lower permittivity than the insulator 210. When a material with a low permittivity is used for an interlayer film, the parasitic capacitance generated between wirings can be reduced.

For example, as the insulator 280 functioning as an interlayer film, a single layer or a stacked layer of any of insulators such as silicon oxide, silicon oxynitride, silicon nitride oxide, aluminum oxide, hafnium oxide, tantalum oxide, zirconium oxide, lead zirconate titanate (PZT), strontium titanate (SrTiO₃), and (Ba,Sr)TiO₃ (BST) can be used. Alternatively, to the insulator of these, aluminum oxide, bismuth oxide, germanium oxide, niobium oxide, silicon oxide, titanium oxide, tungsten oxide, yttrium oxide, or zirconium oxide may be added, for example. Alternatively, the insulator may be subjected to nitriding treatment. The above insulator over which silicon oxide, silicon oxynitride, or silicon nitride is stacked may be used.

Furthermore, the conductor 252 (the conductor 252a, the conductor 252b, the conductor 252c, and the conductor 252d) is placed in the opening formed in the insulator 280 and the like.

The conductor 252 is formed in contact with an inner wall of the opening in the insulator 280. Here, the level of the top surface of the conductor 252 and the level of the top surface of the insulator 280 can be substantially the same. Note that although the conductor 252 having a two-layer structure is illustrated in FIG. 1, the present invention is not limited thereto. For example, the conductor 252 may be a single layer or have a stacked-layer structure of three or more layers.

The conductor 252a is in contact with the region 231a functioning as one of the source region and the drain region of the transistor 200 through the opening formed in the insulator 280 and the insulator 274. The conductor 252b is in contact with the region 231b functioning as the other of the source region and the drain region of the transistor 200 through the opening formed in the insulator 280 and the insulator 274. Because the region 231 is reduced in resistance, the contact resistance between the conductor 252a and the region 231a and the contact resistance between the conductor 252b and the region 231b can be reduced. The conductor 252c is in contact with the conductor 260 functioning as the first gate electrode of the transistor 200 through the opening formed in the insulator 280, the insulator 274, the insulator 271, and the insulator 270. The conductor 252d is in contact with the conductor 207 through the opening formed in the insulator 280, the insulator 274, the insulator 222, and the insulator 220, and is electrically connected to the conductor 205 functioning as the second gate electrode of the transistor 200 through the conductor 209.

Here, the conductor 252a and the conductor 252b are in contact with at least the top surface of the oxide 230, preferably further in contact with the side surface of the oxide 230. It is preferable that the conductor 252a (the conductor 252b) be in contact with one or both of the side surface on the C side and the side surface on the D side, which intersect with the channel width direction of the oxide 230 (dashed-dotted line C-D). Moreover, the conductor 252a (the conductor 252b) may be in contact with the side surface on the A side (the side surface on the B side), which intersects with the channel length direction of the oxide 230 (dashed-dotted line A-B). When a structure is employed in which the conductor 252a and the conductor 252b are in contact with not only the top surface of the oxide 230 but also the side surface of the oxide 230, the areas of the contact portions between the oxide 230 and each of the conductor 252a and the conductor 252b can be increased without an increase in the area of the top surface of the contact portion, so that the contact resistances between the oxide 230 and each of the conductor 252a and the conductor 252b can be reduced. Accordingly, the source electrode and the drain electrode of the transistor can be miniaturized and the on-state current can be increased.

For the conductor 252, a conductive material containing tungsten, copper, or aluminum as its main component is preferably used. The conductor 252 may have a stacked-layer structure, and may be, for example, a stacked layer of any of the above conductive materials and titanium or titanium nitride.

In the case where the conductor 252 has a stacked-layer structure, a conductive material having a function of inhibiting the passage of impurities such as water and hydrogen is preferably used for a conductor in contact with the insulator 274 and the insulator 280, as in the conductor 205 or the like. For example, tantalum, tantalum nitride, titanium, titanium nitride, ruthenium, ruthenium oxide, or the like is preferably used. A single layer or a stacked layer of the conductive material having a function of inhibiting the passage of impurities such as water and hydrogen may be used. With the use of the conductive material, impurities such as hydrogen and water can be inhibited from entering the oxide 230 through the conductor 252 from a layer above the insulator 280.

A structure may be employed in which an insulator having a function of inhibiting the passage of impurities such as water and hydrogen is provided in contact with the inner wall of the opening in the insulator 274 and the insulator 280 in which the conductor 252 is embedded. As such an insulator, an insulator which can be used as the insulator 210, such as aluminum oxide, is preferably used. Accordingly, impurities such as hydrogen and water can be inhibited from entering the oxide 230 through the conductor 252 from the insulator 280 or the like. Moreover, the insulator can be deposited with good coverage by an ALD method, a CVD method, or the like.

Although not illustrated, conductors functioning as wirings may be placed in contact with the top surface of the conductor 252. For the conductors functioning as wirings, a conductive material containing tungsten, copper, or aluminum as its main component is preferably used.

### Structure Example 2 of Semiconductor Device

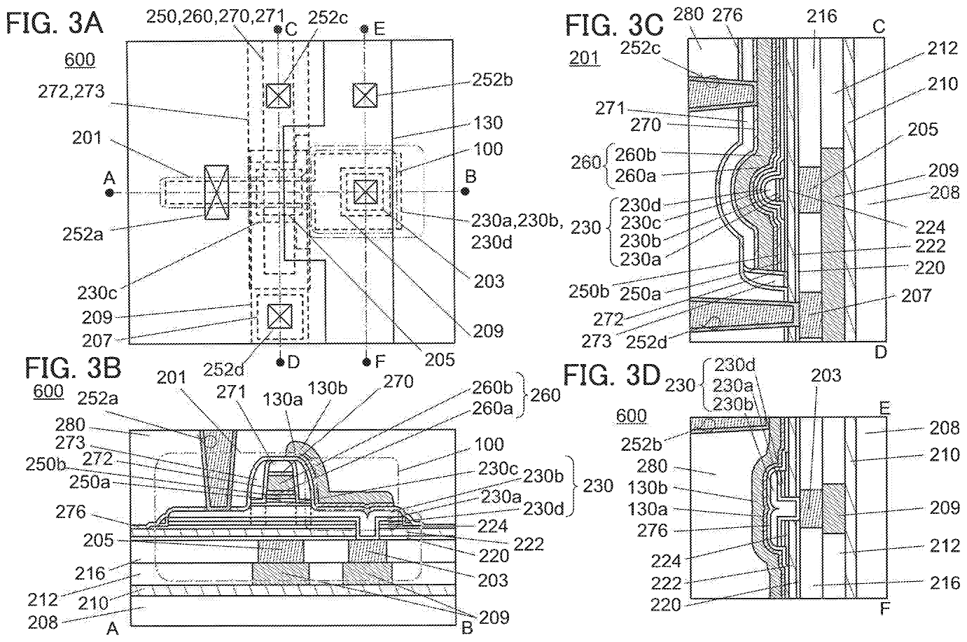

FIG. 3 is a top view and cross-sectional views of a semiconductor device having a structure different from that of the semiconductor device illustrated in FIG. 1. In the semiconductor device illustrated in FIG. 3, a capacitor 100 is provided in the same layer as the transistor 201 using part of components of the transistor 201. In this specification, a semiconductor device including a transistor and a capacitor is referred to as a cell in some cases. A cell 600 including the transistor 201 and the capacitor 100 is described below.

FIG. 3(A), FIG. 3(B), FIG. 3(C), and FIG. 3(D) are a top view and cross-sectional views of the semiconductor device of one embodiment of the present invention.

FIG. 3(A) is a top view of the cell 600. FIG. 3(B), FIG. 3(C), and FIG. 3(D) are cross-sectional views of the cell 600, the transistor 201, and the capacitor 100. Here, FIG. 3(B) is a cross-sectional view of a portion indicated by dashed-dotted line A-B in FIG. 3(A), and is also a cross-sectional view of the transistor 201 in the channel length direction. FIG. 3(C) is a cross-sectional view of a portion indicated by dashed-dotted line C-D in FIG. 3(A), and is also a cross-sectional view of the transistor 201 in the channel width direction. FIG. 3(D) is a cross-sectional view of a portion indicated by dashed-dotted line E-F in FIG. 3(A), and is also a cross-sectional view of the capacitor 100. For clarity of the drawing, some components are not illustrated in the top view of FIG. 3(A).

### [Transistor 201]

In the transistor 201 illustrated in FIG. 3, the same portions as those in the transistor 200 illustrated in FIG. 1 are denoted by the same reference numerals and the description thereof is omitted in some cases.

In the transistor 201, an opening is provided in the insulator 220, the insulator 222, and the insulator 224, and the oxide 230 is electrically connected to the conductor 203 through the opening. The conductor 203 can be formed using a material similar to that for the conductor 205 through a process similar to that for the conductor 205. It is particularly preferable that the conductor 203 be formed concurrently with the conductor 205.

The conductor 203 can function as an electrode or a wiring. The conductor 209 is electrically connected to the oxide 230 through the conductor 203, and can function as a source wiring or a drain wiring of the transistor 200. The conductor 203 and the conductor 209 may be used as electrodes for electrical connection with an element or a wiring positioned below the insulator 210.

The conductor 203 and the conductor 209 are provided under the oxide 230 to overlap with each other, so that a plug or an electrode for connecting the transistor 201 and the element or the wiring positioned below the insulator 210 can be provided to overlap with the transistor 201. Thus, the cell size can be reduced, which is preferable.

In addition, an oxide 230d may be provided between the insulator 224 and the oxide 230a. An oxide film to be the oxide 230d may be formed over the insulator 224, a mask for forming the opening portion in the insulator 220, the insulator 222, and the insulator 224 may be provided over the oxide film, and then the opening portion may be formed. When the mask is formed over the oxide film to be the oxide 230d, the mask is not formed on a surface of the insulator (the insulator 220, the insulator 222, and the insulator 224) functioning as the gate insulating film. Therefore, since the mask is not in contact with the surface of the insulator functioning as the gate insulating film, damage to the gate insulating film during the formation of the mask or contamination of the gate insulating film due to components or impurities contained in the mask can be prevented. Furthermore, contamination or damage of the gate insulating film due to a chemical solution or plasma used for removal of the mask can be inhibited. Through such a process, a method for fabricating a highly reliable semiconductor device can be provided.

A material similar to that for the oxide 230a or the oxide 230c can be used for the oxide 230d. Moreover, when the oxide 230d is included, impurities can be inhibited from being diffused into the oxide 230b from the components formed below the oxide 230d.

Moreover, the atomic proportion of the element M in constituent elements in the metal oxide used as the oxide 230d is preferably greater than the atomic proportion of the element Min constituent elements in the metal oxide used as the oxide 230a. Moreover, the atomic ratio of the element M to In in the metal oxide used as the oxide 230d is preferably greater than the atomic ratio of the element M to In in the metal oxide used as the oxide 230a. Furthermore, the atomic ratio of In to the element M in the metal oxide used as the oxide 230a is preferably greater than the atomic ratio of In to the element M in the metal oxide used as the oxide 230d.

As the oxide 230d, for example, a metal oxide having a composition of In:Ga:Zn=1:3:4, In:Ga:Zn=1:3:2, or In:Ga:Zn=1:1:1 can be used. Note that the above composition represents the atomic ratio of an oxide formed over a substrate or the atomic ratio of a sputtering target.

A combination of a metal oxide having a composition of In:Ga:Zn=1:3:4 as the oxide 230d, a metal oxide having a composition of In:Ga:Zn=1:1:1 as the oxide 230a, a metal oxide having a composition of In:Ga:Zn=4:2:3 as the oxide 230b, and a metal oxide having a composition of In:Ga:Zn=1:3:4 as the oxide 230c is particularly preferable because the oxide 230b can be sandwiched between the oxides 230d and 230a and the oxide 230c each having a wider energy gap. Here, the oxide 230d having a wide energy gap relative to the oxide 230b is referred to as a wide gap in some cases.

### [Capacitor 100]

As illustrated in FIG. 3, the capacitor 100 has a structure in which some components are shared with the transistor 201. This embodiment shows an example of the capacitor 100 in which part of the region 231b provided in the oxide 230 of the transistor 201 functions as one electrode of the capacitor 100.

The capacitor 100 includes part of the region 231b of the oxide 230, an insulator 276, and the conductor 130 (a conductor 130a and a conductor 130b) over the insulator 276. Furthermore, at least part of the conductor 130 is preferably placed to overlap with part of the region 231b.

Part of the region 231b of the oxide 230 functions as one electrode of the capacitor 100, and the conductor 130 functions as the other electrode of the capacitor 100. That is, the region 231b functions as both one of the source and the drain of the transistor 201 and one electrode of the capacitor 100. Part of the insulator 276 functions as a dielectric of the capacitor 100.

In the case where the insulator 276 is used as a dielectric of the capacitor 100, it is preferable to remove part or the whole of the insulator 274 illustrated in FIG. 1 after the formation of the region 231. The insulator 276 is formed after the removal of part or the whole of the insulator 274. Alternatively, the insulator 274 may be used as a dielectric of the capacitor 100.

When a high-k material with a high dielectric constant is used for the insulator 276, the capacitance value of the capacitor 100 can be increased.

Moreover, examples of the insulator with a high dielectric constant include aluminum oxide, gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

In the case where the insulator 276 has a three-layer structure of an insulator 276a, an insulator 276b, and an insulator 276c, the insulator 276 is formed with a stack of two kinds or three kinds of insulators selected from the above insulators with a high dielectric constant. For example, the insulator 276a and the insulator 276c may be hafnium oxide, and the insulator 276b may be aluminum oxide. Alternatively, the insulator 276a and the insulator 276c may be aluminum oxide, and the insulator 276b may be hafnium oxide. Note that the insulator 276 of the present invention is not limited to the three-layer structure. The insulator 276 may have a single-layer structure, a two-layer structure, or a stacked-layer structure of four or more layers.

Each layer of the insulator 276 is preferably formed by an ALD method. In the case where the insulator 276a, the insulator 276b, and the insulator 276c are formed by an ALD method, what is called a multi-chamber ALD apparatus, which includes a plurality of deposition chambers, is preferably used as the apparatus for forming the insulators. With the use of a multi-chamber ALD apparatus, a substrate over which the insulators are formed can be in a reduced-pressure atmosphere from the beginning of the formation of the insulator 276a to the end of the formation of the insulator 276c; thus, the insulator 276a, the insulator 276b, and the insulator 276c can be successively formed without being exposed to an air atmosphere. The insulator 276a, the insulator 276b, and the insulator 276c are successively formed, whereby contamination of an interface between the insulator 276a and the insulator 276b and an interface between the insulator 276b and the insulator 276c can be prevented; accordingly, a semiconductor device using these insulators can have favorable characteristics and high reliability.

The thicknesses of the insulator 276a, the insulator 276b, and the insulator 276c are each preferably greater than or equal to 0.5 nm and less than or equal to 5 nm, further preferably greater than or equal to 0.5 nm and less than or equal to 3 nm. For example, a 1-nm-thick insulator 276a including hafnium oxide, a 1-nm-thick insulator 276b including aluminum oxide, and a 1-nm-thick insulator 276c including hafnium oxide are successively deposited by an ALD method. Note that the structure of the insulator 276 of the present invention is not limited thereto. The thicknesses of the insulator 276a, the insulator 276b, and the insulator 276c may be the same or different from each other, or any one of the thicknesses may be different.

It is important that the resistance value of the region 231, which is reduced by the insulator 274, is not increased when the insulator 276 is formed. In the case where the resistance of the region 231 is reduced by addition of impurities to the oxide 230, the insulator 276 is formed so that the impurities are not released (removed) from the region 231 in the process. In such a case, the deposition temperature of the insulator 276 is set lower than the deposition temperature of the insulating film 250b, whereby release of impurities is inhibited. In contrast, in the case where the resistance of the region 231 is reduced by generation of oxygen vacancies in the oxide 230, it is preferable to reduce supply of oxygen to the oxide 230 during the deposition of the insulator 276. For example, when oxygen or ozone is not introduced before the deposition and during the deposition, or the amount of the introduction is reduced, supply of oxygen to the oxide 230 can be reduced.

Here, the insulator 272 and the insulator 273 are provided on the side surface of the conductor 260 functioning as a first gate electrode of the transistor 201. Since the insulator 272 and the insulator 273 are provided between the conductor 260 and the conductor 130, the parasitic capacitance between the conductor 260 and the conductor 130 can be reduced.

The conductor 130 preferably has a stacked-layer structure including the conductor 130a and the conductor 130b placed over the conductor 130a. For example, a conductive material containing titanium, titanium nitride, tantalum, or tantalum nitride as its main component is preferably used for the conductor 130a, and a conductive material containing tungsten, copper, or aluminum as its main component is preferably used for the conductor 130b. The conductor 130 may have a single-layer structure or a stacked-layer structure of three or more layers.

### [Cell 600]

The semiconductor device of one embodiment of the present invention includes the transistor 201, the capacitor 100, and the insulator 280 functioning as an interlayer film. The conductor 252 (the conductor 252a, the conductor 252b, the conductor 252c, and the conductor 252d) functioning as a plug that is electrically connected to the transistor 201 and the capacitor 100 is also included.

As a plug electrically connected to the conductor 130 functioning as the electrode of the capacitor 100, the conductor 252b may be provided. In addition, the conductor 130 can be shared as the electrodes of the capacitors 100 of a plurality of the cells 600. Thus, the conductor 252b is not necessarily provided in each cell 600 and the number of plugs to be provided in the plurality of cells may be smaller than the number of cells. For example, in a cell array in which the cells 600 are arranged in a matrix, one plug may be provided for each row or one plug may be provided for each column.

The insulator 280 is preferably provided to cover the insulator 276 and the conductor 130.

The conductor 252a is in contact with the region 231a functioning as one of the source region and the drain region of the transistor 201 through the opening formed in the insulator 280 and the insulator 276. Since the resistance of the region 231 is reduced, the contact resistance between the conductor 252a and the region 231a can be reduced. The conductor 252b is in contact with the conductor 130 that is one electrode of the capacitor 100 through the opening formed in the insulator 280. The conductor 252c is in contact with the conductor 260 functioning as the first gate electrode of the transistor 201 through the opening formed in the insulator 280, the insulator 276, the insulator 271, and the insulator 270. The conductor 252d is in contact with the conductor 207 through the opening formed in the insulator 280, the insulator 276, the insulator 222, and the insulator 220, and is electrically connected to the conductor 205 functioning as a second gate electrode of the transistor 201 through the conductor 209.

Although not illustrated, conductors functioning as wirings may be placed in contact with the top surface of the conductor 252. For the conductors functioning as wirings, a conductive material containing tungsten, copper, or aluminum as its main component is preferably used.

### <Deposition Method Using ALD Apparatus and ALD Method>

A deposition method using an ALD apparatus and an ALD method that can be used for formation of the insulator 222, the insulator 250b, the insulator 272, the insulator 276, and the like is described.

In a deposition apparatus utilizing an ALD method, deposition is performed in such a manner that a first source gas (also referred to as a precursor or a metal precursor) and a second source gas (also referred to as a reactant or a nonmetallic precursor) are alternately introduced into a chamber for reaction, and then the introduction of these source gases is repeated. Note that the source gases to be introduced can be switched by switching the respective switching valves (also referred to as high-speed valves), for example. When the source gases are introduced, an inert gas such as nitrogen (N₂) or argon (Ar) may be introduced as a carrier gas with the source gases into the chamber. With the use of a carrier gas, the source gases can be inhibited from being adsorbed onto an inner side of a pipe or an inner side of a valve and can be introduced into the chamber, even in the case where the volatility of the source gases is low or the vapor pressure is low. Moreover, uniformity of the formed film is improved, which is preferable.

Deposition is performed in the following manner, for example. First, the first source gas is introduced into a chamber and the precursor is adsorbed onto a substrate surface (a first step). Here, the precursor is adsorbed onto the substrate surface, whereby a self-limiting mechanism of surface chemical reaction works and no more precursor is adsorbed onto a layer of the precursor over the substrate. Note that the proper range of substrate temperatures at which the self-limiting mechanism of surface chemical reaction works is also referred to as an ALD Window. The ALD Window is determined depending on the temperature characteristics, vapor pressure, decomposition temperature, and the like of a precursor. Next, an excessive precursor, a reaction product, and the like are released from the chamber by vacuum evacuation (a second step). Alternatively, instead of performing vapor evacuation, an inert gas (e.g., argon or nitrogen) or the like may be introduced into the chamber to release an excessive precursor, a reaction product, and the like from the chamber. Then, a reactant (e.g., an oxidizer (ozone (O₃), oxygen (O₂), water (H₂O), or the like)) is introduced as the second source gas into the chamber to react with the precursor adsorbed onto the substrate surface, whereby part of the precursor is removed while the constituent molecules of the film are adsorbed onto the substrate (a third step). After that, an excessive reactant, a reaction product, and the like are released from the chamber by vapor evacuation or introduction of an inert gas (a fourth step).

Note that in the above description, an example in which the second source gas is introduced into the chamber after the first source gas is introduced into the chamber is shown; however, the present invention is not limited thereto. The first source gas may be introduced into the chamber after the second source gas is introduced into the chamber. In other words, deposition may be performed in such a manner that the third step and the fourth step are performed first, the first step, the second step, the third step, and the fourth step are performed, and then the first step to the fourth step are repeated. Alternatively, deposition may be performed in such a manner that the third step and the fourth step are repeated a plurality of times, and then the first step to the fourth step are repeated.

In this manner, the third step and the fourth step are preferably performed once or more before the first step because the deposition atmosphere in the chamber can be controlled. For example, an oxidizer is introduced as the third step, so that the chamber can have an oxygen atmosphere. Deposition began in an oxygen atmosphere is preferable because the formed film can have a high concentration of oxygen. Furthermore, oxygen can also be supplied to the insulator and the oxide that are to be bases of the film. A semiconductor device formed by such a method can have favorable characteristics and obtain high reliability.

After the first step and the second step, introduction of the second source gas in the third step and vapor evacuation or introduction of an inert gas in the fourth step may be repeated a plurality of times. That is, after the first step and the second step, the third step and the fourth step may be repeated in an alternate manner, like the third step, the fourth step, the third step, and the fourth step . . . .

For example, O₃ and O₂ are introduced as oxidizers in the third step, vacuum evacuation is performed in the fourth step, and then these steps may be repeated a plurality of times.

In the case where the third step and the fourth step are repeated, it is not necessary to repeat the introduction of the same kind of source gas. For example, H₂O may be used as an oxidizer in the third step in the first cycle, and O₃ may be used as an oxidizer in the third steps in and after the second cycle.

In this manner, the introduction of an oxidizer and vacuum evacuation (or the introduction of an inert gas) in the chamber are repeated a plurality of times in a short time, whereby excess hydrogen atoms and the like can be more certainly removed from the precursor adsorbed onto the substrate surface and released to the outside of the chamber. When the number of the kinds of the oxidizer is increased to two, more excess hydrogen atoms and the like can be removed from the precursor adsorbed onto the substrate surface. In this manner, hydrogen atoms are prevented from being taken into the film during the deposition, so that water, hydrogen, and the like contained in the deposited insulator and the like can be reduced.

With the use of such a method, it is possible to form an insulator of which the released amount of water molecules is greater than or equal to 1.0×10¹³ molecules/cm² and less than or equal to 1.0×10¹⁶ molecules/cm², preferably greater than or equal to 1.0×10¹³ molecules/cm² and less than or equal to 3.0×10¹⁵ molecules/cm² in TDS analysis in a film-surface temperature range of 100° C. to 700° C. or 100° C. to 500° C.

A first single layer can be deposited on the substrate surface in the above manner, and a second single layer can be stacked over the first single layer by performing the first step to the fourth step again. The first step to the fourth step are repeated a plurality of times until a desired film thickness is obtained, whereby a thin film with excellent step coverage can be formed. The thickness of the thin film can be adjusted by the number of repetitions; therefore, an ALD method makes it possible to accurately adjust a film thickness and thus is suitable for a case of fabricating a miniaturized transistor.

An ALD method is a method in which deposition is performed through reaction of a precursor and a reactant using thermal energy. Moreover, an ALD method in which treatment is performed by introducing a plasma-excited reactant into the chamber as a third source gas in addition to the precursor and the reactant which react with each other is referred to as a plasma ALD method in some cases. In this case, a plasma generation apparatus is provided in the introduction portion of the third source gas. Inductively coupled plasma (ICP) can be used for plasma generation. On the other hand, an ALD method in which reaction between the precursor and the reactant is performed using thermal energy is sometimes referred to as a thermal ALD method.

In the deposition by a plasma ALD method, the first step to the fourth step are repeated while a plasma-excited reactant (a second reactant) is introduced. In this case, the reactant introduced in the third step is referred to as a first reactant. In the plasma ALD method, the second reactant used as the third source gas may be a nitriding agent as well as an oxidizer. As the nitriding agent, nitrogen (N₂) or ammonia (NH₃) can be used. A mixed gas of nitrogen (N₂) and hydrogen (H₂) can also be used as the nitriding agent. For example, a mixed gas of nitrogen (N₂) of 5% and hydrogen (H₂) of 95% can be used as the nitriding agent. Deposition is performed while plasma-excited nitrogen or ammonia is introduced, whereby a nitride film such as a metal nitride film can be formed.

Argon (Ar) or nitrogen (N₂) may be used as a carrier gas for the second reactant. The use of a carrier gas such as argon or nitrogen is preferable because plasma is easily discharged and the plasma-excited second reactant is easily generated. Note that in the case where an oxide film such as a metal oxide film is formed by a plasma ALD method and nitrogen is used as a carrier gas, nitrogen enters the film and a desired film quality cannot be obtained in some cases. In this case, argon is preferably used as the carrier gas. For example, in the case where aluminum oxide is formed by a plasma ALD method, a metal precursor containing aluminum and a carrier gas containing argon are used as a first material gas, ozone and oxygen are used as a second material gas, and oxygen and a carrier gas containing argon is used as a third material gas.

By an ALD method, an extremely thin film can be deposited to have a uniform thickness. In addition, the coverage of an uneven surface with the film is high.

When deposition is performed by a plasma ALD method, deposition can be performed at a lower temperature than that by a thermal ALD method. By a plasma ALD method, for example, deposition can be performed without decreasing the deposition rate even at 100° C. or lower. Furthermore, in a plasma ALD method, not only an oxidizer but also any of a variety of reactants such as a nitriding agent can be used; therefore, it is possible to form various kinds of films of a nitride, a fluoride, a metal, and the like as well as an oxide.

In the case where a plasma ALD method is employed, as in an ICP (Inductively Coupled Plasma) method or the like, plasma can be generated in a state apart from a substrate. When plasma is generated in this manner, plasma damage can be reduced.

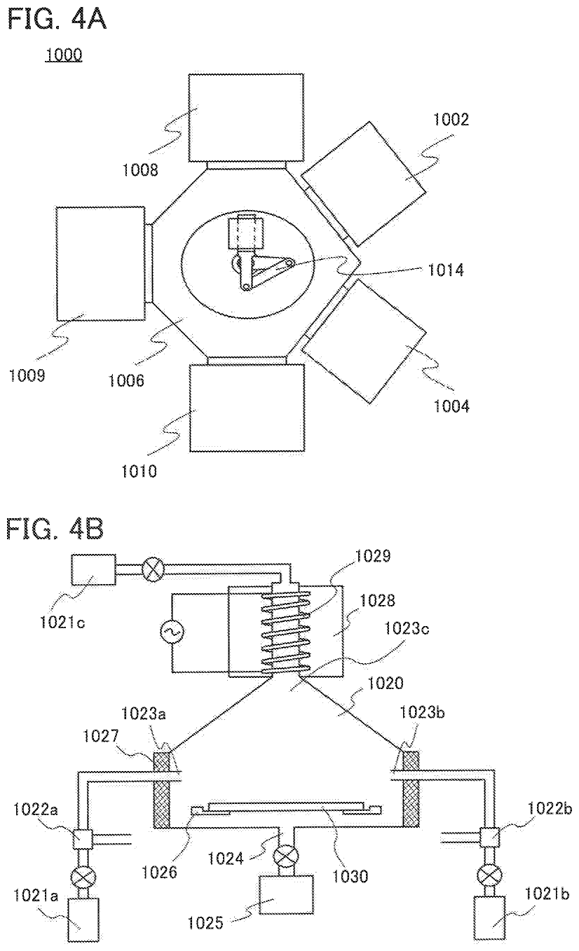

Here, a structure of a deposition apparatus 1000 is described with reference to FIG. 4(A) and FIG. 4(B) as an example of an apparatus with which deposition can be performed by an ALD method. FIG. 4(A) is a schematic view of the multi-chamber deposition apparatus 1000, and FIG. 4(B) is a cross-sectional view of an ALD apparatus that can be used for the deposition apparatus 1000.

### Structure Example of Deposition Apparatus

The deposition apparatus 1000 includes a carrying-in/out chamber 1002, a carrying-in/out chamber 1004, a transfer chamber 1006, a deposition chamber 1008, a deposition chamber 1009, a deposition chamber 1010, and a transfer arm 1014. Here, the carrying-in/out chamber 1002, the carrying-in/out chamber 1004, and the deposition chambers 1008 to 1010 are connected to the transfer chamber 1006. Thus, successive deposition can be performed in the deposition chambers 1008 to 1010 without exposure to the air, whereby entry of impurities into a film can be prevented. Moreover, contamination of an interface between a substrate and a film and interfaces between films can be reduced, so that clean interfaces can be obtained.

Note that in order to prevent attachment of moisture and the like, the carrying-in/out chamber 1002, the carrying-in/out chamber 1004, the transfer chamber 1006, and the deposition chambers 1008 to 1010 are preferably filled with an inert gas (such as a nitrogen gas) whose dew point is controlled, and desirably maintain reduced pressure.

An ALD apparatus can be used for the deposition chambers 1008 to 1010. Alternatively, a structure may be employed in which a deposition apparatus other than an ALD apparatus is used for any of the deposition chambers 1008 to 1010. Examples of the deposition apparatus that can be used for the deposition chambers 1008 to 1010 include a sputtering apparatus, a PECVD apparatus, a TCVD apparatus, and an MOCVD apparatus.

Although the deposition apparatus 1000 has a structure including the carrying-in/out chamber 1002, the carrying-in/out chamber 1004, and the deposition chambers 1008 to 1010, the present invention is not limited thereto. The deposition apparatus 1000 may have a structure with four or more deposition chambers or may have a structure with an additional treatment chamber for heat treatment or plasma treatment. The deposition apparatus 1000 may be of a single-wafer type or may be of a batch type, in which case deposition is performed on a plurality of substrates at a time.

### <ALD Apparatus>

Next, a structure of an ALD apparatus that can be used for the deposition apparatus 1000 is described. The ALD apparatus includes a deposition chamber (chamber 1020), source material supply portions 1021a, 1021b, and 1021c, high-speed valves 1022a and 1022b which are flow rate controllers, source material introduction ports 1023a, 1023b, and 1023c, a source material exhaust port 1024, and an evacuation unit 1025. The source material introduction ports 1023a, 1023b, and 1023c provided in the chamber 1020 are connected to the source material supply portions 1021a, 1021b, and 1021c, respectively, through supply tubes and valves, and the source material exhaust port 1024 is connected to the evacuation unit 1025 through an exhaust tube, a valve, and a pressure controller.

A plasma generation apparatus 1028 is connected to the chamber 1020 as illustrated in FIG. 4(B), whereby deposition can be performed by a plasma ALD method as well as a thermal ALD method. It is preferable that the plasma generation apparatus 1028 be an ICP-type plasma generation apparatus using a coil 1029 connected to a high frequency power source. A plasma ALD method enables deposition without decreasing the deposition rate even at low temperatures, and thus is preferably used for a single-wafer type deposition apparatus with low deposition efficiency.

There is a substrate holder 1026 in the chamber, and a substrate 1030 over which a film is to be deposited is placed over the substrate holder 1026. A heater 1027 is provided on an outside wall of the chamber.

In the source material supply portions 1021a, 1021b, and 1021c, a source gas is generated from a solid source material or a liquid source material using a vaporizer, a heating unit, or the like. Alternatively, the source material supply portions 1021a, 1021b, and 1021c may supply a source gas.

Although an example in which three source material supply portions 1021a, 1021b, and 1021c are provided is described, there is no particular limitation and two or four or more source material supply portions may be provided. The high-speed valves 1022a and 1022b can be accurately controlled by time, and one of the first source gas and the second source gas is supplied to the chamber 1020. The high-speed valves 1022a and 1022b are flow rate controllers for the first source gas, and can also be referred to as flow rate controllers for the second source gas.

In the ALD apparatus illustrated in FIG. 4(B), a thin film is formed over a substrate surface in the following manner: the substrate 1030 is transferred onto the substrate holder 1026, the chamber 1020 is sealed, the substrate 1030 is heated to a desired temperature (e.g., higher than or equal to 80° C., higher than or equal to 100° C., or higher than or equal to 150° C.) by the heater 1027; and supply of the first source gas, evacuation with the evacuation unit 1025, supply of the second source gas, and evacuation with the evacuation unit 1025 are repeated. The formation of the thin film may be performed while the third source gas is supplied. The temperature of the heater 1027 is determined as appropriate depending on the kind of the film to be formed, the source gas, a desired film quality, and heat resistances of a substrate and a film and an element that are provided over the substrate. For example, deposition may be performed at higher than or equal to 200° C. and lower than or equal to 300° C., or deposition may be performed at higher than or equal to 300° C. and lower than or equal to 500° C.

When deposition is performed while the substrate 1030 is heated by the heater 1027, heat treatment for the substrate 1030 that is necessary in a later step can be omitted. That is, with the use of the deposition apparatus 1000 or the chamber 1020 provided with the heater 1027, formation of a film over the substrate 1030 can also serve as heat treatment for the substrate 1030.

With the deposition apparatus illustrated in FIG. 4(B), an insulating layer formed using an oxide (including a composite oxide) containing one or more kinds of elements selected from hafnium, aluminum, tantalum, zirconium, and the like can be deposited by appropriate selection of a source material (e.g., a volatile organometallic compound) used for the source material supply portions 1021a, 1021b, and 1021c. Specifically, an insulating layer formed using hafnium oxide, an insulating layer formed using aluminum oxide, an insulating layer formed using hafnium silicate, an insulating layer formed using aluminum silicate, or the like can be deposited. Alternatively, a thin film, e.g., a metal layer such as a tungsten layer or a titanium layer, or a nitride layer such as a titanium nitride layer can be deposited by appropriate selection of a source material (e.g., a volatile organometallic compound) used for the source material supply portions 1021a, 1021b, and 1021c.

For example, in the case where a hafnium oxide layer is formed by an ALD apparatus, the first source gas which is obtained by vaporizing liquid containing a solvent and a hafnium precursor compound (hafnium alkoxide or hafnium amide such as tetrakis(dimethylamide)hafnium (TDMAHf)), and the second source gas of ozone (O₃) and oxygen (O₂) as an oxidizer are used. In this case, the first source gas supplied from the source material supply portion 1021a is TDMAHf, and the second source gas supplied from the source material supply portion 1021b is ozone and oxygen. Note that the chemical formula of tetrakis(dimethylamide)hafnium is Hf[N(CH₃₎₂]₄. Furthermore, examples of another material liquid include tetrakis(ethylmethylamide)hafnium. Alternatively, H₂O can be used as the second source gas.

In the case where an aluminum oxide layer is formed by an ALD apparatus, the first source gas which is obtained by vaporizing a liquid containing a solvent and an aluminum precursor compound (e.g., TMA: trimethylaluminum) and the second source gas containing ozone (O₃) and oxygen (O₂) as an oxidizer are used. In this case, the first source gas supplied from the source material supply portion 1021a is TMA, and the second source gas supplied from the source material supply portion 1021b is ozone and oxygen. Note that the chemical formula of trimethylaluminum is Al(CH₃)₃. Examples of another material liquid include tris(dimethylamide)aluminum, triisobutylaluminum, and aluminum tris(2,2,6,6-tetramethyl-3,5-heptanedionate). Alternatively, H₂O can be used as the second source gas.

### <Deposition Sequence>

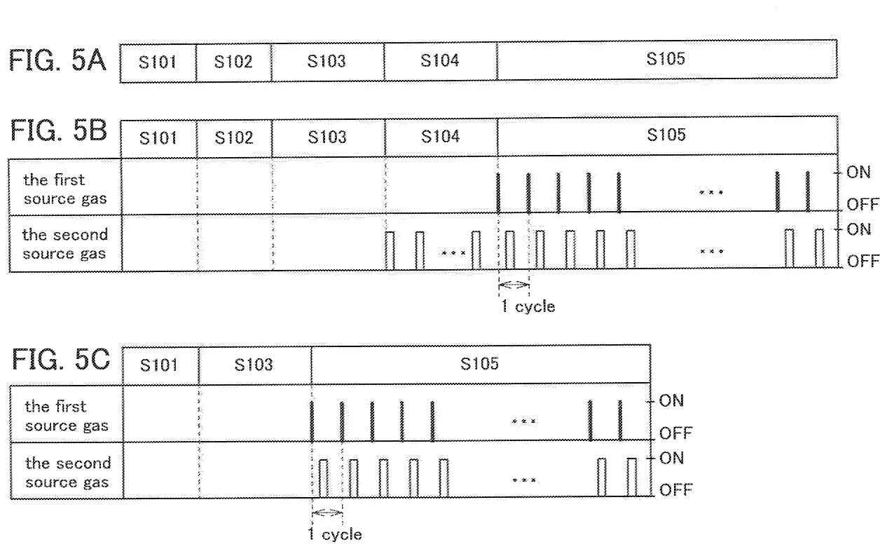

FIG. 5(A) shows a deposition sequence using an ALD apparatus. First, the substrate 1030 is set on the substrate holder 1026 in the chamber 1020 (S101). Next, the temperature of the heater 1027 is adjusted (S102). Then, the substrate 1030 is held on the substrate holder 1026 so that the temperature of the substrate 1030 becomes uniform in the substrate surface (S103). Next, the inside of the chamber 1020 is set in an oxygen atmosphere (S104). After that, deposition is performed through the first step to the fourth step that are described above. In other words, the first source gas and the second source gas are alternately introduced into the chamber 1020 to perform deposition over the substrate 1030 (S105). The inside of the chamber 1020 is set in an oxygen atmosphere after setting and holding the substrate 1030, whereby oxygen can be added to the substrate 1030 and the film provided over the substrate 1030 in some cases. Furthermore, hydrogen can be released from the substrate 1030 and the film provided over the substrate 1030 in some cases. Hydrogen in the substrate 1030 or the film sometimes reacts with oxygen added to the substrate 1030 or the film, and is released from the substrate 1030 or the film as water (H₂O).

FIG. 5(B) shows a specific example of the above deposition sequence. In accordance with S101 to S103, the substrate 1030 is set on the substrate holder 1026, the temperature of the heater 1027 is adjusted, and the substrate 1030 is held. Next, the second source gas is introduced into the chamber 1020 (S104). It is preferable that one or more selected from ozone (O₃), oxygen (O₂), and water (H₂O), which function as oxidizers, be introduced as the second source gas. In this embodiment, ozone (O₃) and oxygen (O₂) are used as the second source gas. In this case, the second source gas is preferably introduced in a pulsed form; however, the present invention is not limited thereto. The second source gas may be successively introduced. In FIG. 5(B), introduction of the second source gas is indicated by ON and a period during which the second source gas is not introduced is indicated by OFF. In the period during which the second source gas is not introduced, the chamber 1020 is evacuated. The pulse time of introducing the second source gas into the chamber 1020 is preferably longer than or equal to 0.1 second and shorter than or equal to 30 seconds, further preferably longer than or equal to 0.3 second and shorter than or equal to 15 seconds. The period during which the second source gas is not introduced, that is, the time for evacuating the chamber 1020, is longer than or equal to 1 second and shorter than or equal to 15 seconds, preferably longer than or equal to 1 second and shorter than or equal to 5 seconds. When the second source gas such as an oxidizer is introduced into the chamber 1020, the substrate 1030 or the film provided over the substrate 1030 is exposed to the second source gas such as an oxidizer.

Next, the first source gas and the second source gas are alternately introduced to perform deposition over the substrate 1030 (S105). The first source gas and the second source gas are introduced in a pulsed form. In FIG. 5(B), introductions of the first source gas and the second source gas are each indicated by ON, and periods during which the source gases are not introduced are each indicated by OFF. The pulse time of introducing the first source gas into the chamber 1020 is preferably longer than or equal to 0.1 second and shorter than or equal to 1 second, further preferably longer than or equal to 0.1 second and shorter than or equal to 0.5 second. The period during which the first source gas is not introduced, that is, the time for evacuating the chamber 1020, is longer than or equal to 1 second and shorter than or equal to 15 seconds, preferably longer than or equal to 1 second and shorter than or equal to 5 seconds. The pulse time of introducing the second source gas into the chamber 1020 is preferably longer than or equal to 0.1 second and shorter than or equal to 30 seconds, further preferably longer than or equal to 0.3 second and shorter than or equal to 15 seconds. The period during which the second source gas is not introduced, that is, the time for evacuating the chamber 1020, is longer than or equal to 1 second and shorter than or equal to 15 seconds, preferably longer than or equal to 1 second and shorter than or equal to 5 seconds.

In the deposition, introduction of the first source gas (the first step), evacuation of the first source gas (the second step), introduction of the second source gas (the third step), and evacuation of the second source gas (the fourth step) are regarded as one cycle, and a film having a desired thickness is formed by repetition of this cycle.

Note that in the case where the temperature of the heater 1027 need not be adjusted after setting the substrate 1030 (S101), S102 may be omitted. Moreover, in the case where the inside of the chamber 1020 need not be set in an oxygen atmosphere after the substrate 1030 is held (S103), S104 may be omitted. FIG. 5(C) shows an example of the deposition sequence in which deposition over the substrate 1030 (S105) is performed in such a manner that the substrate 1030 is set (S101), the substrate 1030 is held on the substrate holder 1026 so that the temperature of the substrate 1030 becomes uniform in the substrate surface, and then the first source gas and the second source gas are alternately introduced.

### <Structure 1 of Cell Array>

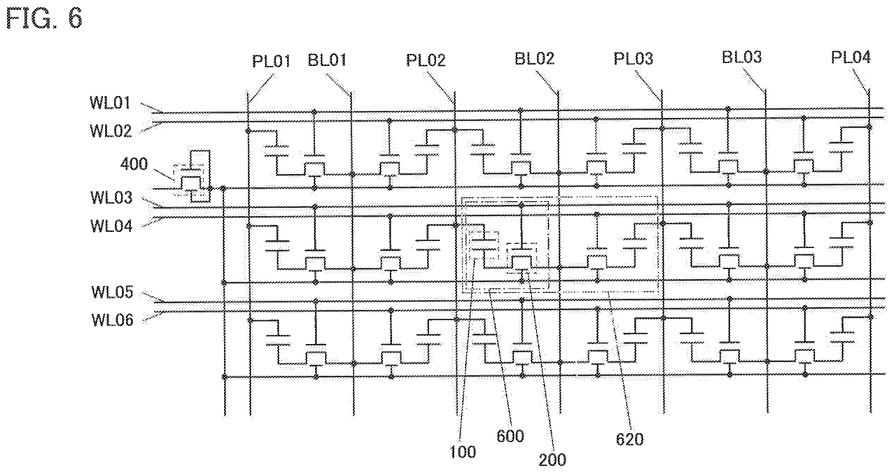

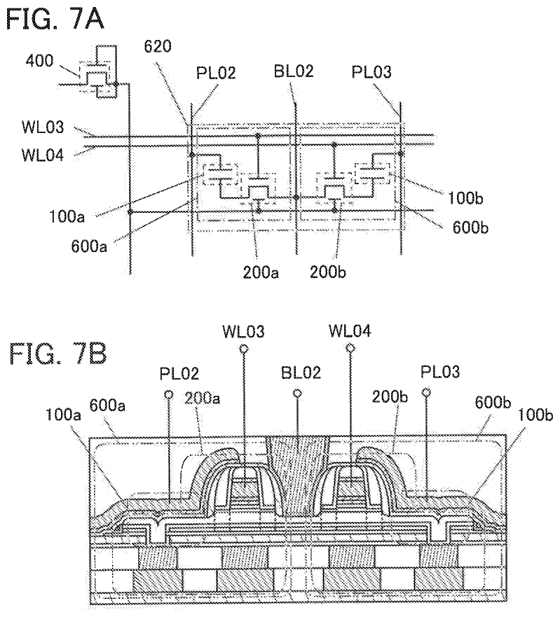

Here, an example of a cell array of this embodiment is shown in FIG. 6 and FIG. 7. In FIG. 6 and FIG. 7, the cells 600 each including the transistor 200 and the capacitor 100 are arranged in a matrix, whereby a cell array can be formed. Note that the transistor 200 illustrated in FIG. 1 or the transistor 201 illustrated in FIG. 3 can be used as the transistor 200 (a transistor 200a and a transistor 200b).

FIG. 6 is a circuit diagram showing an embodiment of the cell array in which the cells 600 illustrated in FIG. 3 are arranged in a matrix. FIG. 7(A) is a circuit diagram of a circuit 620 that is an extracted part of the cell array, and FIG. 7(B) is a schematic cross-sectional view of the cell 600 corresponding to the cell array.

In FIG. 6, sources or drains of the transistors 200 included in the cells 600 which are adjacent in the row direction are electrically connected to common BLs (BL01, BL02, and BL03). Furthermore, the wirings are also electrically connected to one of the source and the drain of each of the transistors 200 included in the cells arranged in the column direction. In contrast, the first gates of the transistors 200 included in the cells 600 which are adjacent in the row direction are electrically connected to different WLs (WL01 to WL06). Furthermore, the second gates of the transistors 200 included in the cells 600 may be electrically connected to a transistor 400. By a potential applied to the second gate of the transistor 200 through the transistor 400, the threshold voltage of the transistor 200 can be controlled.

A first electrode of the capacitor 100 included in the cell 600 is electrically connected to the other of the source and the drain of the transistor 200. At this time, the first electrode of the capacitor 100 is formed using part of components of the transistor 200 in some cases. A second electrode of the capacitor 100 included in the cell 600 is electrically connected to PLs (PL01, PL02, PL03, and PL04). In the example shown here, the second electrodes of the capacitors 100 included in the cells 600 which are adjacent to each other in the row direction and do not share a common BL are electrically connected to a common PL; however, the present invention is not limited thereto. The second electrodes of the capacitors 100 may have the same potential or different potentials between the cells 600. For example, the second electrode of the capacitor 100 may have a common potential per column or may have a common potential per row.

As illustrated in FIG. 7(B), the cell 600a includes the transistor 200a and the capacitor 100a. The cell 600b includes the transistor 200b and the capacitor 100b.

One of a source and a drain of the transistor 200a and one of a source and a drain of the transistor 200b are both electrically connected to BL02. As illustrated in FIG. 7(B), one of the source and the drain of the transistor 200a and one of the source and the drain of the transistor 200b may be directly connected to each other. That is, two transistors may be provided using one island-shaped oxide that is to be a semiconductor layer and one of the source and the drain of each transistor may be shared.

When the other of the source and the drain of the transistor 200 is electrically connected to the first electrode of the capacitor 100, a desired potential can be applied to the capacitor 100 and retained therein. The transistor 200 using an oxide semiconductor in its channel formation region has an extremely low leakage current in a non-conduction state. Thus, a potential applied to the capacitor 100 can be retained for a long time.

Such a cell array can be used for a memory device or an arithmetic circuit.

### <Structure 2 of Cell Array>

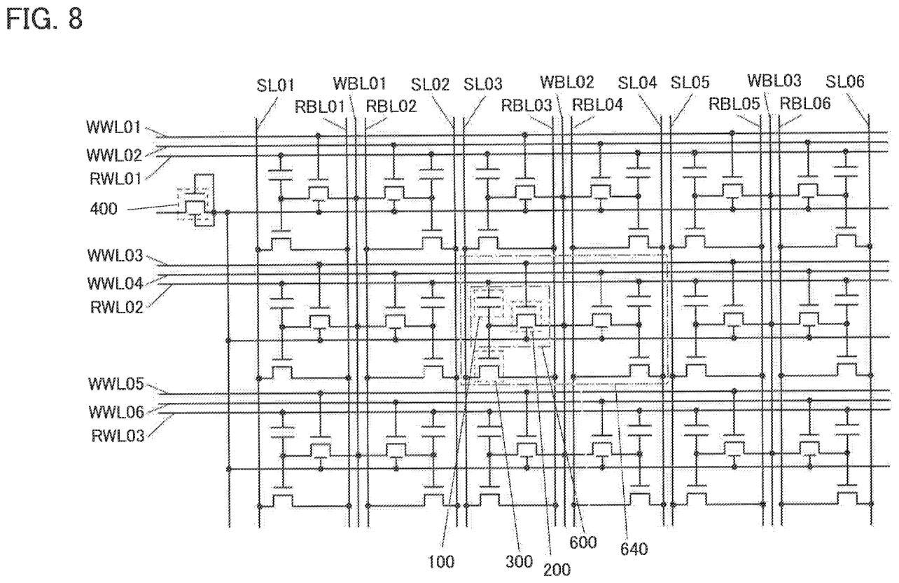

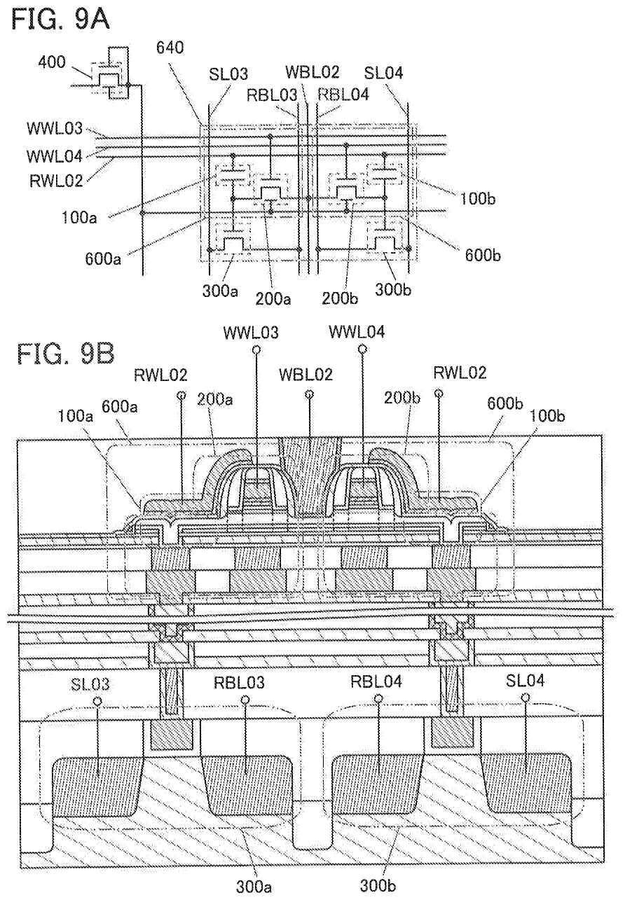

Here, examples of a cell array of this embodiment are shown in FIG. 8 and FIG. 9. In FIG. 8 and FIG. 9, the cells 600 each including the transistor 200 and the capacitor 100 and transistors 300 electrically connected to the cells 600 are arranged in a matrix, whereby a cell array can be formed. Note that the transistor 200 illustrated in FIG. 1 or the transistor 201 illustrated in FIG. 3 can be used as the transistor 200 (the transistor 200a and the transistor 200b).

FIG. 8 is a circuit diagram showing one embodiment of a cell array in which the cells 600 illustrated in FIG. 3 and the transistors 300 electrically connected to the cells 600 are arranged in a matrix. FIG. 9(A) is a circuit diagram of a circuit 640 extracted from the cell array, and FIG. 9(B) is a schematic cross-sectional view of the cell 600 and the transistor 300 and corresponds to the cell array.

A transistor provided over a semiconductor substrate can be used as the transistor 300. The semiconductor substrate preferably includes a semiconductor such as a silicon-based semiconductor, and preferably contains single crystal silicon. Alternatively, a semiconductor substrate containing Ge (germanium), SiGe (silicon germanium), GaAs (gallium arsenide), GaAlAs (gallium aluminum arsenide), or the like may be used. In this case, the transistor 300 is of either a p-channel type or an n-channel type. Like the transistor 200, the transistor 300 can be a transistor using an oxide semiconductor.

In FIG. 8, one of the source and the drain of the transistors 200 included in the cells 600 which are adjacent in the row direction are electrically connected to common WBLs (WBL01, WBL02, and WBL03). Furthermore, the wirings are also electrically connected to one of the source and the drain of each of the transistors 200 included in the cells arranged in the column direction. In contrast, the first gates of the transistors 200 included in the cells 600 which are adjacent in the row direction are electrically connected to different WWLs (WWL01 to WWL06). Furthermore, the second gates of the transistors 200 included in the cells 600 may be electrically connected to the transistor 400. By a potential applied to the second gate of the transistor 200 through the transistor 400, the threshold voltage of the transistor can be controlled.

The first electrode of the capacitor 100 included in the cell 600 is electrically connected to the other of the source and the drain of the transistor 200 and a gate of the transistor 300. At this time, the first electrode of the capacitor 100 is formed using part of components of the transistor 200 in some cases. The second electrode of the capacitor 100 included in the cell 600 is electrically connected to RWLs (RWL01, RWL 02, and RWL 03). The second electrodes of the capacitors 100 may have the same potential or different potentials between the cells 600. For example, the second electrode of the capacitor 100 may have a common potential per column or may have a common potential per row.

One of a source and a drain of the transistor 300 is electrically connected to a wiring SL (SL01 to SL06), and the other of the source and the drain of the transistor 300 is electrically connected to a wiring RBL (RBL01 to RBL06).

As illustrated in FIG. 9(B), the cell 600a includes the transistor 200a and the capacitor 100a, and is electrically connected to a gate of a transistor 300a. The cell 600b includes the transistor 200b and the capacitor 100b, and is electrically connected to a gate of a transistor 300b.

One of the source and the drain of the transistor 200a and one of the source and the drain of the transistor 200b are both electrically connected to WBL02. Alternatively, as illustrated in FIG. 9(B), one of the source and the drain of the transistor 200a and one of the source and the drain of the transistor 200b may be directly connected to each other. That is, two transistors may be provided using one island-shaped oxide that is to be a semiconductor layer and one of the source and the drain of each transistor may be shared.

When the other of the source and the drain of the transistor 200 is electrically connected to the gate of the transistor 300 and the first electrode of the capacitor 100, a desired potential can be applied to the gate of the transistor 300 and retained therein. The transistor 200 using an oxide semiconductor in its channel formation region has an extremely low leakage current in a non-conduction state. Thus, the potential applied to the gate of the transistor 300 can be retained for a long time.

Such a cell array can be used for a memory device or an arithmetic circuit.

### [Transistor 400]

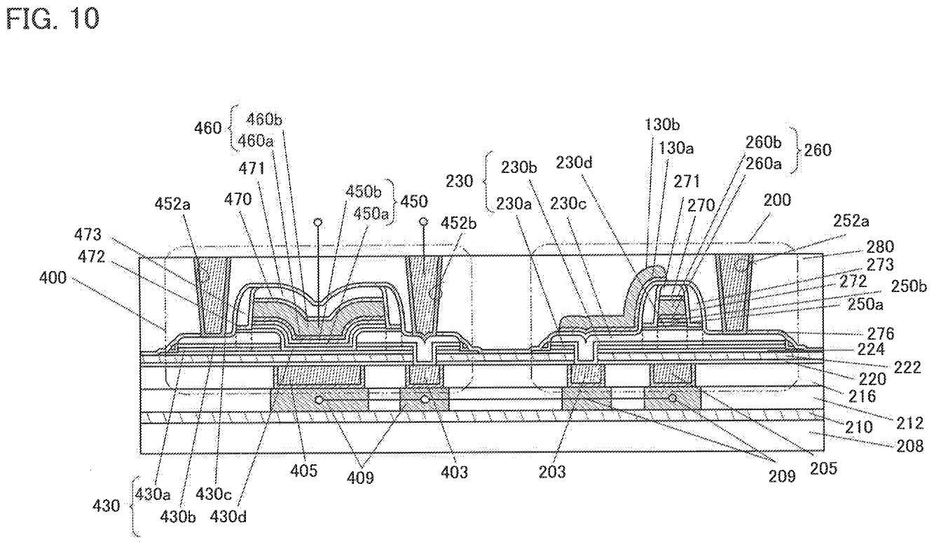

FIG. 10 is a schematic cross-sectional view illustrating one embodiment of the transistor 400. The transistor 400 may have a structure different from that of the transistor 200.

The transistor 400 is preferably fabricated using the same material as that for the transistor 200.

A conductor 409 can be formed using a material similar to that for the conductor 209 in the same step as the conductor 209. A conductor 403 and a conductor 405 can be formed using a material similar to that for the conductor 203 and the conductor 205 in the same step as those conductors. The conductor 405 can function as a second gate electrode of the transistor 400.

An oxide 430a, an oxide 430b, an oxide 430c, and an oxide 430d can be formed using a material similar to that for the oxide 230a, the oxide 230b, the oxide 230c, and the oxide 230d in the same step as those oxides. In the transistor 400, part of the oxide 430d functions as a channel formation region, and the oxide 430a, the oxide 430b, the oxide 430c, and the oxide 430d each include, like the oxide 230, a low-resistance region functioning as a source region or a drain region. Furthermore, a contact region having a lower resistance is preferably provided in each of the oxide 430a, the oxide 430b, and the oxide 430c.

An insulator 450a and an insulator 450b can be formed using a material similar to that for the insulator 250a and the insulator 250b in the same step as those insulators, and an insulator 450 including the insulator 450a and the insulator 450b can function as a gate insulating film. A conductor 460a and a conductor 460b can be formed using a material similar to that for the conductor 260a and the conductor 260b in the same step as those conductors, and a conductor 460 including the conductor 460a and the conductor 460b can function as a first gate electrode.

An insulator 470 can be formed using a material similar to that for the insulator 270 in the same step as the insulator 270. An insulator 471 can be formed using a material similar to that for the insulator 271 in the same step as the insulator 271. An insulator 472 can be formed using a material similar to that for the insulator 272 in the same step as the insulator 272. An insulator 473 can be formed using a material similar to that for the insulator 273 in the same step as the insulator 273.

Opening portions are provided in the insulator 280 and the insulator 276, and a conductor 452a and a conductor 452b, which are connected to the oxide 430, are placed.

In the transistor 400, one of a source region and a drain region is electrically connected to the conductor 403 through an opening provided in the oxide 430a, the insulator 224, the insulator 222, and the insulator 220. The conductor 403 is electrically connected to the conductor 405 functioning as the second gate electrode through the conductor 409. One of the source region and the drain region is electrically connected to the conductor 460 functioning as the first gate electrode through the conductor 452b. In other words, one of the source region and the drain region, the first gate electrode, and the second gate electrode are electrically connected to each other, whereby a diode connection is formed in the transistor 400.

One of the source and the drain of the diode-connected transistor 400 is electrically connected to the second gate electrode of the transistor 200 through the conductor 409, the conductor 209, and the like. Thus, the potential of the second gate electrode of the transistor 200 can be controlled by the transistor 400. A channel formation region is provided in the oxide 430d; therefore, the transistor 400 has an extremely low leakage current in a non-conduction state. Thus, when a negative potential is applied to the second gate electrode of the transistor 200, for example, the potential of the second gate electrode of the transistor 200 can be retained for a long time even without power supply to the transistor 400.

The transistor 400 is not necessarily provided in each cell 600 and the number of the transistors 400 to be provided in the plurality of cells 600 may be smaller than the number of the cells. For example, in a cell array in which the cells 600 are arranged in a matrix, one transistor 400 may be provided in the cell array, one transistor 400 may be provided in each row, or one transistor 400 may be provided in each column.

The transistor 400 and the transistor 200 can be fabricated using the same material through the same process. Therefore, the transistor 400 can be fabricated without an especial step and an increase in the manufacturing cost.

### <Material for Semiconductor Device>

Materials that can be used for a semiconductor device are described below.

### <<Substrate>>

As a substrate over which the transistor 200 is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon, germanium, or the like and a compound semiconductor substrate containing silicon carbide, silicon germanium, gallium arsenide, indium phosphide, zinc oxide, or gallium oxide. Moreover, a semiconductor substrate in which an insulator region is included in the above semiconductor substrate, e.g., an SOI (Silicon On Insulator) substrate or the like is used. Examples of the conductor substrate include a graphite substrate, a metal substrate, an alloy substrate, and a conductive resin substrate. Alternatively, a substrate including a metal nitride, a substrate including a metal oxide, or the like is used. Moreover, an insulator substrate provided with a conductor or a semiconductor, a semiconductor substrate provided with a conductor or an insulator, a conductor substrate provided with a semiconductor or an insulator, or the like is used. Alternatively, any of these substrates over which an element is provided may be used. Examples of the element provided over the substrate include a capacitor, a resistor, a switching element, a light-emitting element, and a memory element.

A flexible substrate may be used as the substrate. Note that as a method of providing a transistor over a flexible substrate, there is a method in which the transistor is fabricated over a non-flexible substrate and then the transistor is separated and transferred to a flexible substrate. In that case, a separation layer is preferably provided between the non-flexible substrate and the transistor. In addition, the substrate may have elasticity. Furthermore, the substrate may have a property of returning to its original shape when bending or pulling is stopped. Alternatively, the substrate may have a property of not returning to its original shape. The substrate has a region with a thickness of, for example, greater than or equal to 5 μm and less than or equal to 700 μm, preferably greater than or equal to 10 μm and less than or equal to 500 μm, further preferably greater than or equal to 15 μm and less than or equal to 300 μm. When the substrate has a small thickness, the weight of the semiconductor device including the transistor can be reduced. Moreover, when the substrate has a small thickness, even in the case of using glass or the like, the substrate may have elasticity or a property of returning to its original shape when bending or pulling is stopped. Thus, an impact applied to a semiconductor device over the substrate, which is caused by dropping or the like, can be reduced. That is, a durable semiconductor device can be provided.

For the flexible substrate, metal, an alloy, a resin, glass, or fiber thereof can be used, for example. Note that as the substrate, a sheet, a film, a foil or the like that contains a fiber may be used. The flexible substrate preferably has a lower coefficient of linear expansion because deformation due to an environment is inhibited. For the flexible substrate, a material whose coefficient of linear expansion is lower than or equal to 1×10⁻³/K, lower than or equal to 5×10⁻⁵/K, or lower than or equal to 1×10⁻⁵/K can be used, for example. Examples of the resin include polyester, polyolefin, polyamide (nylon, aramid, or the like), polyimide, polycarbonate, and acrylic. In particular, aramid is preferable for the flexible substrate because of its low coefficient of linear expansion.

### <<Insulator>>

Examples of an insulator include an oxide, a nitride, an oxynitride, a nitride oxide, a metal oxide, a metal oxynitride, and a metal nitride oxide, each of which has an insulating property.

When a high-k material having a high dielectric constant is used for the insulator functioning as the gate insulator, miniaturization and high integration of the transistor can be achieved. In contrast, when a material having a low dielectric constant is used for the insulator functioning as an interlayer film, the parasitic capacitance generated between wirings can be reduced. Therefore, a material is preferably selected depending on the function of an insulator.

Moreover, examples of the insulator having a high dielectric constant include aluminum oxide, gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator having a low dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

In particular, silicon oxide and silicon oxynitride are thermally stable. Accordingly, a stacked-layer structure which is thermally stable and has a low dielectric constant can be obtained by combination with a resin, for example. Examples of the resin include polyester, polyolefin, polyamide (e.g., nylon or aramid), polyimide, polycarbonate, and acrylic. Furthermore, combining silicon oxide and silicon oxynitride with an insulator having a high dielectric constant enables a stacked-layer structure to have thermal stability and a high dielectric constant.

In addition, when a transistor using an oxide semiconductor is surrounded by an insulator having a function of inhibiting the passage of oxygen and impurities such as hydrogen, the transistor can have stable electrical characteristics.

As the insulator having a function of inhibiting the passage of oxygen and impurities such as hydrogen, a single layer or a stacked layer of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. Specifically, as the insulator having a function of inhibiting the passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; silicon nitride; or the like can be used.

For example, an insulator that has a function of inhibiting the passage of oxygen and impurities such as hydrogen is used as the insulator 222, the insulator 210, and the insulator 250b. Note that an oxide insulator containing one or both of aluminum and hafnium can be used as the insulator 222, the insulator 210, and the insulator 250b. Aluminum oxide, hafnium oxide, an oxide containing aluminum and hafnium (hafnium aluminate), or the like is preferably used for the oxide insulator containing one or both of aluminum and hafnium.

As the insulator 220, the insulator 224, the insulator 250a, for example, a single layer or a stacked layer of an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum are used. Specifically, the insulators preferably contain silicon oxide, silicon oxynitride, or silicon nitride.

For example, when aluminum oxide, gallium oxide, hafnium aluminate, or hafnium oxide in each of the insulator 224 and the insulator 250a functioning as gate insulators, is in contact with the oxide 230, entry of silicon contained in silicon oxide or silicon oxynitride into the oxide 230 can be inhibited. In contrast, when silicon oxide or silicon oxynitride in each of the insulator 224 and the insulator 250a is in contact with the oxide 230, trap centers might be formed at the interface between aluminum oxide, gallium oxide, hafnium aluminate, or hafnium oxide and silicon oxide or silicon oxynitride. The trap centers can shift the threshold voltage of the transistor in the positive direction by trapping electrons in some cases.

For the insulator 276 functioning as a dielectric, for example, a single layer or a stacked layer using silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, hafnium nitride, or hafnium aluminate is provided. For example, a stacked-layer structure of a high-k material such as aluminum oxide and a material with high dielectric strength, such as silicon oxynitride, is preferable. With such a structure, the capacitor 100 can have sufficient capacitance owing to a high-k material and increased dielectric strength owing to a material with high dielectric strength; thus, the electrostatic breakdown of the capacitor 100 can be inhibited, which leads to improvement in the reliability of the capacitor 100. In addition, the insulator 276 preferably has a stacked-layer structure in which hafnium oxide, aluminum oxide, and hafnium oxide are stacked in this order because the capacitor 100 can obtain a larger capacitance value.

The insulator 212, the insulator 216, the insulator 273, and the insulator 280 each preferably include an insulator having a low dielectric constant. For example, the insulator 212, the insulator 216, the insulator 273, and the insulator 280 each preferably include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. Alternatively, the insulator 212, the insulator 216, the insulator 273, and the insulator 280 each preferably has a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide. When silicon oxide or silicon oxynitride, which is thermally stable, is combined with a resin, the stacked-layer structure can have thermal stability and a low dielectric constant. Examples of the resin include polyester, polyolefin, polyamide (e.g., nylon or aramid), polyimide, polycarbonate, and acrylic.

As the insulator 270 and the insulator 272, an insulator having a function of inhibiting the passage of oxygen and impurities such as hydrogen is used. For the insulator 270 and the insulator 272, a metal oxide such as aluminum oxide, hafnium oxide, hafnium aluminate, magnesium oxide, gallium oxide, germanium oxide, yttrium oxide, zirconium oxide, lanthanum oxide, neodymium oxide, or tantalum oxide; silicon nitride oxide; or silicon nitride may be used, for example.

### <<Conductor>>

For the conductors, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Furthermore, a semiconductor having high electrical conductivity, typified by polycrystalline silicon containing an impurity element such as phosphorus, or silicide such as nickel silicide may be used.

Furthermore, a stack of a plurality of conductive layers formed with the above materials may be used. For example, a stacked-layer structure combining a material containing the above-described metal element and a conductive material containing oxygen may be employed. Furthermore, a stacked-layer structure combining a material containing the above-described metal element and a conductive material containing nitrogen may be employed. Furthermore, a stacked-layer structure combining a material containing the above-described metal element, a conductive material containing oxygen, and a conductive material containing nitrogen may be employed.

Note that when an oxide is used for the channel formation region of the transistor, a stacked-layer structure combining a material containing any of the above-described metal elements and a conductive material containing oxygen is preferably used for the conductor functioning as the gate electrode. In this case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in a metal oxide where a channel is formed. Furthermore, a conductive material containing the above-described metal element and nitrogen may be used. For example, a conductive material containing nitrogen, such as titanium nitride or tantalum nitride, may be used. Furthermore, indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Furthermore, indium gallium zinc oxide containing nitrogen may be used. With the use of such a material, hydrogen contained in the metal oxide where a channel is formed can be trapped in some cases. Alternatively, hydrogen entering from an external insulator or the like can be trapped in some cases.

For the conductor 260, the conductor 203, the conductor 205, the conductor 207, the conductor 209, the conductor 130, and the conductor 252, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Furthermore, a semiconductor having high electrical conductivity, typified by polycrystalline silicon containing an impurity element such as phosphorus, or silicide such as nickel silicide may be used.

### <<Metal Oxide>>

As the oxide 230, a metal oxide functioning as an oxide semiconductor (hereinafter also referred to as an oxide semiconductor) is preferably used. A metal oxide that can be used as the oxide 230 of the present invention is described below.

An oxide semiconductor preferably contains at least indium or zinc. It is particularly preferable that indium and zinc are contained. Furthermore, aluminum, gallium, yttrium, tin, or the like is preferably contained in addition to them. Furthermore, one or more kinds selected from boron, silicon, titanium, iron, nickel, germanium, zirconium, molybdenum, lanthanum, cerium, neodymium, hafnium, tantalum, tungsten, magnesium, and the like may be contained.

Here, the case where the oxide semiconductor is an In—M—Zn oxide that contains indium, an element M, and zinc is considered. Note that the element M is aluminum, gallium, yttrium, tin, or the like. Other elements that can be used as the element M include boron, silicon, titanium, iron, nickel, germanium, zirconium, molybdenum, lanthanum, cerium, neodymium, hafnium, tantalum, tungsten, magnesium, and the like. Note that a plurality of the above-described elements may be combined as the element M.

Note that in this specification and the like, a metal oxide containing nitrogen is also collectively referred to as a metal oxide in some cases. A metal oxide containing nitrogen may be referred to as a metal oxynitride.

### [Composition of Metal Oxide]

Described below is the composition of a CAC—(Cloud-Aligned composite) OS that can be used for a transistor disclosed in one embodiment of the present invention.

Note that in this specification and the like, “CAAC (c-axis aligned crystal)” or “CAC (Cloud-Aligned Composite)” might be stated. Note that CAAC refers to an example of a crystal structure, and CAC refers to an example of a function or a material composition.

A CAC-OS or a CAC-metal oxide has a conducting function in part of the material and has an insulating function in another part of the material; as a whole, the CAC-OS or the CAC-metal oxide has a function of a semiconductor. In the case where the CAC-OS or the CAC-metal oxide is used in an active layer of a transistor, the conducting function is a function of allowing electrons (or holes) serving as carriers to flow, and the insulating function is a function of not allowing electrons serving as carriers to flow. By the complementary action of the conducting function and the insulating function, a switching function (On/Off function) can be given to the CAC-OS or the CAC-metal oxide. In the CAC-OS or the CAC-metal oxide, separation of the functions can maximize each function.

Furthermore, the CAC-OS or the CAC-metal oxide includes conductive regions and insulating regions. The conductive regions have the above-described conducting function, and the insulating regions have the above-described insulating function. Furthermore, in some cases, the conductive regions and the insulating regions in the material are separated at the nanoparticle level. Furthermore, in some cases, the conductive regions and the insulating regions are unevenly distributed in the material. Furthermore, the conductive regions are observed to be coupled in a cloud-like manner with their boundaries blurred, in some cases.

Furthermore, in the CAC-OS or the CAC-metal oxide, the conductive regions and the insulating regions each have a size greater than or equal to 0.5 nm and less than or equal to 10 nm, preferably greater than or equal to 0.5 nm and less than or equal to 3 nm, and are dispersed in the material, in some cases.

Furthermore, the CAC-OS or the CAC-metal oxide includes components having different bandgaps. For example, the CAC-OS or the CAC-metal oxide includes a component having a wide gap due to the insulating region and a component having a narrow gap due to the conductive region. In the case of the structure, when carriers flow, carriers mainly flow in the component having a narrow gap. Furthermore, the component having a narrow gap complements the component having a wide gap, and carriers also flow in the component having a wide gap in conjunction with the component having a narrow gap. Therefore, in the case where the above-described CAC-OS or CAC-metal oxide is used in a channel formation region of a transistor, high current driving capability in an on state of the transistor, that is, a high on-state current and high field-effect mobility can be obtained.

In other words, the CAC-OS or the CAC-metal oxide can also be referred to as a matrix composite or a metal matrix composite.

### [Structure of Metal Oxide]

Oxide semiconductors can be classified into single crystal oxide semiconductors and the others, non-single-crystal oxide semiconductors. Oxide semiconductors (metal oxides) are classified into a single-crystal oxide semiconductor and a non-single-crystal oxide semiconductor. Examples of the non-single-crystal oxide semiconductors include a CAAC-OS (c-axis-aligned crystalline oxide semiconductor), a polycrystalline oxide semiconductor, an nc-OS (nanocrystalline oxide semiconductor), an amorphous-like oxide semiconductor (a-like OS), and an amorphous oxide semiconductor.

The CAAC-OS has c-axis alignment, a plurality of nanocrystals are connected in the a-b plane direction, and its crystal structure has distortion. Note that the distortion refers to a portion where the direction of a lattice arrangement changes between a region with a regular lattice arrangement and another region with a regular lattice arrangement in a region where the plurality of nanocrystals are connected.

The nanocrystal is basically a hexagon but is not always a regular hexagon and is a non-regular hexagon in some cases. Furthermore, a pentagonal or heptagonal lattice arrangement, for example, is included in the distortion in some cases. Note that a clear crystal grain boundary (also referred to as grain boundary) cannot be observed even in the vicinity of distortion in the CAAC-OS. That is, it is found that formation of a crystal grain boundary is inhibited by the lattice arrangement distortion. This is probably because the CAAC-OS can tolerate distortion owing to non-dense arrangement of oxygen atoms in the a-b plane direction, an interatomic bond length changed by metal element substitution, and the like.

Furthermore, the CAAC-OS tends to have a layered crystal structure (also referred to as a layered structure) in which a layer containing indium and oxygen (hereinafter, In layer) and a layer containing the element M, zinc, and oxygen (hereinafter, (M,Zn) layer) are stacked. Note that indium and the element M can be replaced with each other, and when the element M in the (M,Zn) layer is replaced with indium, the layer can also be referred to as an (In,M,Zn) layer. Furthermore, when indium in the In layer is replaced with the element M, the layer can be referred to as an (In,M) layer.

The CAAC-OS is an oxide semiconductor with high crystallinity. On the other hand, a clear crystal grain boundary cannot be observed in the CAAC-OS; thus, it can be said that a reduction in electron mobility due to the crystal grain boundary is less likely to occur. Furthermore, entry of impurities, formation of defects, or the like might decrease the crystallinity of the oxide semiconductor; thus, it can also be said that the CAAC-OS is an oxide semiconductor having small amounts of impurities and defects (e.g., oxygen vacancies). Thus, an oxide semiconductor including the CAAC-OS is physically stable. Therefore, the oxide semiconductor including the CAAC-OS is resistant to heat and has high reliability.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor depending on the analysis method.

The a-like OS is an oxide semiconductor having a structure between those of the nc-OS and an amorphous oxide semiconductor. The a-like OS includes a void or a low-density region. That is, the a-like OS has lower crystallinity than the nc-OS and the CAAC-OS.

An oxide semiconductor can have various structures which show different properties. Two or more of the amorphous oxide semiconductor, the polycrystalline oxide semiconductor, the a-like OS, the nc-OS, and the CAAC-OS may be included in an oxide semiconductor of one embodiment of the present invention.

### [Transistor Including Oxide Semiconductor]

Next, the case where the above oxide semiconductor is used for a transistor is described.

Note that when the above oxide semiconductor is used for a transistor, a transistor with high field-effect mobility can be achieved. In addition, the transistor having high reliability can be achieved.

An oxide semiconductor with a low carrier density is preferably used for a transistor. In the case where the carrier density of an oxide semiconductor film is reduced, the concentration of impurities in the oxide semiconductor film is reduced so that the density of defect states is reduced. In this specification and the like, a state with a low impurity concentration and a low density of defect states is referred to as a highly purified intrinsic or substantially highly purified intrinsic state. For example, the carrier density of the oxide semiconductor is lower than 8×10¹¹/cm³, preferably lower than 1×10¹¹/cm³, further preferably lower than 1×10¹⁰/cm³, and greater than or equal to 1×10⁻⁹/cm³.

Furthermore, a highly purified intrinsic or substantially highly purified intrinsic oxide semiconductor film has a low density of defect states and accordingly has a low density of trap states in some cases.

Furthermore, charges trapped by the trap states in the oxide semiconductor take a long time to disappear and may behave like fixed charges. Thus, a transistor whose channel formation region is formed in an oxide semiconductor with a high density of trap states has unstable electrical characteristics in some cases.

Thus, in order to stabilize electrical characteristics of the transistor, reducing the impurity concentration in the oxide semiconductor is effective. Furthermore, in order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon.

### [Impurities]

Here, the influence of each impurity in the oxide semiconductor is described.

When silicon or carbon, which is one of the Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) is set lower than or equal to 2×10¹⁸ atoms/cm³, preferably lower than or equal to 2×10¹⁷ atoms/cm³.

Furthermore, when the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Accordingly, it is preferable to reduce the concentration of an alkali metal or an alkaline earth metal in the oxide semiconductor. Specifically, the concentration of an alkali metal or an alkaline earth metal in the oxide semiconductor obtained by SIMS is set lower than or equal to 1×10¹⁸ atoms/cm³, preferably lower than or equal to 2×10¹⁶ atoms/cm³.

Furthermore, when containing nitrogen, the oxide semiconductor easily becomes n-type by generation of electrons serving as carriers and an increase of carrier density. As a result, a transistor using an oxide semiconductor containing nitrogen as a semiconductor is likely to have normally-on characteristics. For this reason, nitrogen in the oxide semiconductor is preferably reduced as much as possible. For example, the concentration of nitrogen in the oxide semiconductor measured by SIMS is set to lower than 5×10¹⁹ atoms/cm³, preferably lower than or equal to 5×10¹⁸ atoms/cm³, further preferably lower than or equal to 1×10¹⁸ atoms/cm³, and still further preferably lower than or equal to 5×10¹⁷ atoms/cm³.

Furthermore, hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, in some cases, bonding of part of hydrogen to oxygen bonded to a metal atom causes generation of an electron serving as a carrier. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor obtained by SIMS is lower than 1×10²⁰ atoms/cm³, preferably lower than 1×10¹⁹ atoms/cm³, further preferably lower than 5×10¹⁸ atoms/cm³, and still further preferably lower than 1×10¹⁸ atoms/cm³.

When an oxide semiconductor with sufficiently reduced impurities is used for a channel formation region of a transistor, stable electrical characteristics can be given.

### <Method 1 for Fabricating Semiconductor Device>

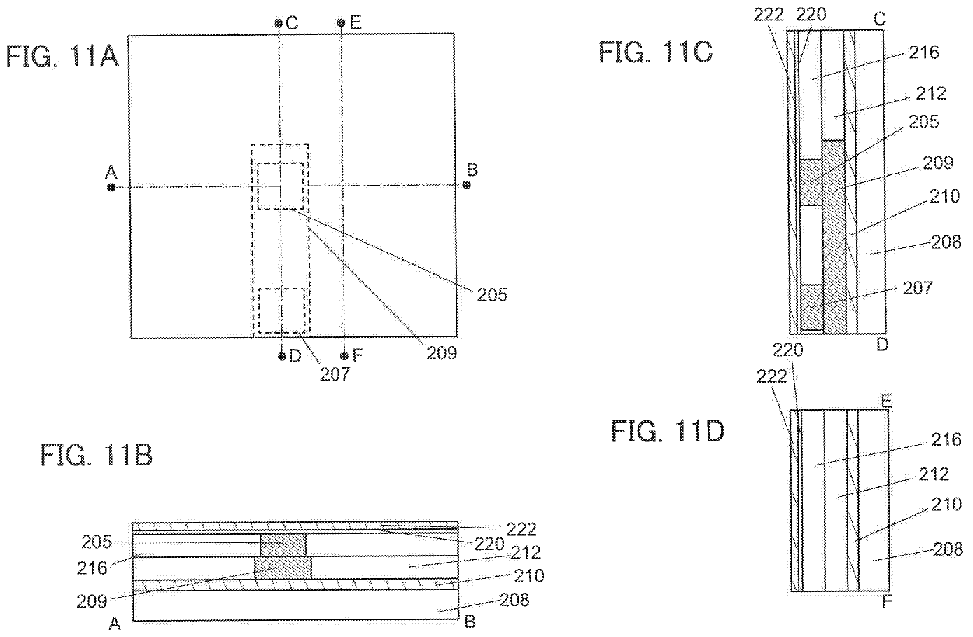

Next, a method for fabricating a semiconductor device including the transistor 200 of the present invention is described with reference to FIG. 11 to FIG. 22. In FIG. 11 to FIG. 22, (A) of each drawing is a top view. Moreover, (B) of each drawing is a cross-sectional view corresponding to a portion indicated by dashed-dotted line A-B in (A). Furthermore, (C) of each drawing is a cross-sectional view corresponding to a portion indicated by dashed-dotted line C-D in (A). Furthermore, (D) of each drawing is a cross-sectional view corresponding to a portion indicated by dashed-dotted line E-F in (A).

First, a substrate (not illustrated) is prepared, and the insulator 208 is deposited over the substrate. The insulator 208 can be deposited by a sputtering method, a chemical vapor deposition (CVD) method, a molecular beam epitaxy (MBE) method, a pulsed laser deposition (PLD) method, an ALD (Atomic Layer Deposition) method, or the like.

Note that CVD methods can be classified into a plasma enhanced CVD (PECVD) method using plasma, a thermal CVD (TCVD) method using heat, a photo CVD method using light, and the like. Moreover, the CVD methods can be classified into a metal CVD (MCVD) method and a metal organic CVD (MOCVD) method depending on a source gas.

By a plasma CVD method, a high-quality film can be obtained at a relatively low temperature. Furthermore, a thermal CVD method is a deposition method that does not use plasma and thus enables less plasma damage to an object. For example, a wiring, an electrode, an element (e.g., transistor or capacitor), or the like included in a semiconductor device might be charged up by receiving charges from plasma. In that case, accumulated charges might break the wiring, electrode, element, or the like included in the semiconductor device. By contrast, such plasma damage is not caused in the case of using a thermal CVD method that does not use plasma, and thus the yield of a semiconductor device can be increased. In addition, a thermal CVD method does not cause plasma damage during deposition, so that a film with few defects can be obtained.

An ALD method is also a deposition method which enables less plasma damage to an object. With the use of an ALD method that does not use plasma, plasma damage during deposition are not caused, so that a film with few defects can be obtained.

Unlike in a deposition method in which particles ejected from a target or the like are deposited, a CVD method and an ALD method are deposition methods in which a film is formed by reaction at a surface of an object. Thus, a CVD method and an ALD method are deposition methods that are less likely to be influenced by the shape of an object and thus have favorable step coverage. In particular, an ALD method has excellent step coverage and excellent thickness uniformity, and thus is suitable for the case of covering a surface of an opening with a high aspect ratio, for example. On the other hand, an ALD method has a relatively low deposition rate, and thus is preferably used in combination with another deposition method with a high deposition rate such as a CVD method, in some cases.

A CVD method or an ALD method enables control of composition of a film to be obtained with a flow rate ratio of the source gases. For example, a CVD method or an ALD method, a film with a desired composition can be deposited by adjusting the flow ratio of the source gases. Moreover, by a CVD method or an ALD method, by changing the flow rate ratio of the source gases during the deposition, a film whose composition is continuously changed can be deposited. In the case of depositing while changing the flow rate ratio of the source gases, as compared with the case of depositing with the use of a plurality of deposition chambers, time taken for the deposition can be shortened because time taken for transfer and pressure adjustment is omitted. Thus, productivity of semiconductor devices can be improved in some cases.

In this embodiment, for the insulator 208, silicon oxide is deposited by a CVD method.

Next, the insulator 210 is formed over the insulator 208. In this embodiment, for the insulator 210, aluminum oxide is deposited by a sputtering method. The insulator 210 may have a multilayer structure. For example, a structure may be employed in which aluminum oxide is deposited by a sputtering method and another aluminum oxide is deposited over the aluminum oxide by an ALD method. Alternatively, a structure may be employed in which aluminum oxide is deposited by an ALD method and another aluminum oxide is deposited over the aluminum oxide by a sputtering method.

Then, a conductive film to be the conductor 209 is formed over the insulator 210. The conductive film can be formed by a sputtering method, a CVD method, an MBE method, a PLD method, an ALD method, or the like. In this embodiment, as the conductive film, tungsten is deposited by a sputtering method. Note that as the conductive film, a conductor such as aluminum or copper can be used as well as tungsten. The conductive film may have a stacked-layer structure, and a conductor containing titanium or tantalum may be stacked over the conductor. For example, a metal nitride such as titanium nitride or tantalum nitride can be stacked over the conductor.

Then, the conductive film is processed by a lithography method to form the conductor 209.

Note that in the lithography method, first, a resist is exposed to light through a photomask. Next, a region exposed to light is removed or left using a developing solution, so that a resist mask is formed. Then, etching treatment through the resist mask is performed, so that the conductor, the semiconductor, the insulator, or the like can be processed into a desired shape. The resist mask is formed by, for example, exposure of the resist to light using KrF excimer laser light, ArF excimer laser light, EUV (Extreme Ultraviolet) light, or the like. Alternatively, a liquid immersion technique may be employed in which a portion between a substrate and a projection lens is filled with liquid (e.g., water) to perform light exposure. Furthermore, an electron beam or an ion beam may be used instead of the above-described light. Note that a mask is not necessary in the case of using an electron beam or an ion beam. Note that for removal of the resist mask, dry etching treatment such as ashing can be performed, wet etching treatment can be performed, wet etching treatment can be performed after dry etching treatment, or dry etching treatment can be performed after wet etching treatment.

A hard mask formed of an insulator or a conductor may be used instead of the resist mask. In the case where a hard mask is used, a hard mask with a desired shape can be formed by forming an insulating film or a conductive film to be the hard mask material over the conductive film, forming a resist mask thereover, and then etching the hard mask material.

For the processing, a dry etching method or a wet etching method can be employed. The processing by a dry etching method is suitable for microfabrication.

As a dry etching apparatus, a capacitively coupled plasma (CCP) etching apparatus including parallel plate type electrodes can be used. The capacitively coupled plasma etching apparatus including the parallel plate type electrodes may have a structure in which a high-frequency power source is applied to one of the parallel plate type electrodes. Alternatively, a structure may be employed in which different high-frequency power sources are applied to one of the parallel plate type electrodes. Alternatively, a structure may be employed in which high-frequency power sources with the same frequency are applied to the parallel plate type electrodes. Alternatively, a structure may be employed in which high-frequency power sources with different frequencies are applied to the parallel plate type electrodes. Alternatively, a dry etching apparatus including a high-density plasma source can be used. As the dry etching apparatus including a high-density plasma source, an inductively coupled plasma (ICP) etching apparatus can be used, for example.

In the case where a hard mask is used for etching of the conductive film, the etching treatment may be performed after the resist mask used for formation of the hard mask is removed or with the resist mask left. In the latter case, the resist mask disappears during the etching in some cases. The hard mask may be removed by etching after the etching of the conductive film.

The hard mask does not need to be removed in the case where the hard mask material does not affect the following process or can be utilized in the following process.

Next, the insulator 212 is formed over the insulator 210 and the conductor 209. The insulator 212 can be formed by a sputtering method, a CVD method, an MBE method, a PLD method, an ALD method, or the like. In this embodiment, for the insulator 212, silicon oxide or oxynitride silicon is formed by a CVD method.

Next, part of the insulator 212 is removed by CMP treatment, so that the conductor 209 is exposed. As a result, the insulator 212 remains around the conductor. In this manner, the insulator 212 and the conductor 209 with flat top surfaces can be formed (see FIG. 11). Note that by the CMP treatment, the conductor 209 is partly removed in some cases.

Note that the method for forming the conductor 209 and the insulator 212 is not limited to the above. The insulator 212 may be formed first, and the conductor 209 may be formed to be embedded in an opening such as a groove or a slit formed in the insulator 212. Such a method for forming a conductor and an insulator is referred to as a damascene process. Alternatively, depending on a structure of the layer below the conductor 209, a single damascene process may be employed or a dual damascene process may be employed. The use of a dual damascene process is preferable because the conductor 209 and a component such as an element or a wiring which are positioned below the conductor 209 can be directly connected to each other.

Next, the conductor 205 and the insulator 216 are deposited over the insulator 212 and the conductor 209. The conductor 205 and the insulator 216 can be formed by a method similar to that for the conductor 209 and the insulator 212. Alternatively, the conductor 205 and the insulator 216 may be formed using a damascene process (see FIG. 11).

Next, the insulator 220 is deposited over the insulator 216 and the conductor 205. The insulator 220 can be deposited by a sputtering method, a CVD method, an MBE method, a PLD method, an ALD method, or the like.

For the insulator 220, silicon oxide or silicon oxynitride can be used. The thickness of the insulator 220 is greater than or equal to 1 nm and less than or equal to 10 nm, preferably greater than or equal to 1 nm and less than or equal to 5 nm.

Next, the insulator 222 is deposited over the insulator 220 (see FIG. 11). The insulator 222 can be deposited by a sputtering method, a CVD method, an MBE method, a PLD method, an ALD method, or the like.

In particular, an oxide insulator containing one or both of aluminum and hafnium is preferably used as the insulator 222. Aluminum oxide, hafnium oxide, an oxide containing aluminum and hafnium (hafnium aluminate), or the like is preferably used for the oxide insulator containing one or both of aluminum and hafnium. The insulator 222 is preferably formed by an ALD method. The insulator 222 deposited by an ALD method has a barrier property against oxygen, hydrogen, and water. When the insulator 222 has a barrier property against hydrogen and water, hydrogen and water in structure bodies provided around the transistor 200 are not diffused into the transistor 200, and generation of oxygen vacancies in the oxide 230 can be inhibited.

For the insulator 222, hafnium oxide is used, for example. The thickness of the insulator 222 is greater than or equal to 1 nm and less than or equal to 30 nm, preferably greater than or equal to 1 nm and less than or equal to 10 nm, further preferably greater than or equal to 1 nm and less than or equal to 5 nm.

The insulator 222 may have a stacked-layer structure. In the case where the insulator 222 has a stacked-layer structure, a three-layer structure of the insulator 222a, the insulator 222b, and the insulator 222c is preferable, as illustrated in FIG. 2. For example, the insulator 222a and the insulator 222c may be hafnium oxide, and the insulator 222b may be aluminum oxide. Alternatively, the insulator 222a and the insulator 222c may be aluminum oxide, and the insulator 222b may be hafnium oxide. In contrast, the insulator 222 of the present invention is not limited to the three-layer structure. The insulator 222 may have a single-layer structure, a two-layer structure, or a stacked-layer structure of four or more layers.

Each layer of the insulator 222 is preferably formed by an ALD method. In the case where the formation is performed by an ALD method, a multi-chamber ALD apparatus is preferably used as the apparatus for forming the insulator. With the use of a multi-chamber ALD apparatus, a substrate over which the insulator 222 is formed can be in a reduced-pressure atmosphere from the beginning of the formation of the insulator 222 to the end of the formation of each layer of the insulator 222; thus, the insulator 222 having a stacked-layer structure can be successively formed without being exposed to an air atmosphere. Each layer of the insulator 222 (e.g., the insulator 222a, the insulator 222b, and the insulator 222c) is successively formed, whereby contamination of an interface between the insulator 222a and the insulator 222b and an interface between the insulator 222b and the insulator 222c can be prevented. A semiconductor device using such an insulator can have favorable characteristics and high reliability. It is further preferable that the insulator 220 and the insulator 222 be successively formed using a multi-chamber ALD apparatus, in which case contamination of the interface between the insulator 220 and the insulator 222 can also be prevented.

In the case where the insulator 222 has a three-layer structure of the insulator 222a, the insulator 222b, and the insulator 222c, the thicknesses of the insulator 222a, the insulator 222b, and the insulator 222c are each greater than or equal to 0.5 nm and less than or equal to 5 nm, preferably greater than or equal to 1 nm and less than or equal to 3 nm. For example, a 2-nm-thick insulator 222a including hafnium oxide, a 2-nm-thick insulator 222b including aluminum oxide, and a 2-nm-thick insulator 222c including hafnium oxide are successively deposited by an ALD method. In this case, the thickness of the insulator 222 is 6 nm. Note that the structure of the insulator 222 of the present invention is not limited thereto. The thicknesses of the insulator 222a, the insulator 222b, and the insulator 222c may be the same or different from each other, or any one of the thicknesses may be different.

Furthermore, in the formation of the insulator 222, the insulator 222 is formed while the substrate is heated, so that heat treatment for the substrate that is necessary in a later step can be omitted. That is, the formation of the insulator 222 can also serve as heat treatment for the substrate.

Sequentially, heat treatment is preferably performed. The heat treatment may be performed at a temperature higher than or equal to 250° C. and lower than or equal to 650° C., preferably higher than or equal to 300° C. and lower than or equal to 500° C., further preferably higher than or equal to 320° C. and lower than or equal to 450° C. The heat treatment is performed in a nitrogen or inert gas atmosphere, an oxygen atmosphere, or an atmosphere containing an oxidizing gas at 10 ppm or more, 1% or more, or 10% or more. The heat treatment may be performed under a reduced pressure. Alternatively, the heat treatment may be performed in such a manner that heat treatment is performed in a nitrogen or inert gas atmosphere, and then another heat treatment is performed in an oxygen atmosphere or an atmosphere containing an oxidizing gas at 10 ppm or more, 1% or more, or 10% or more in order to compensate for released oxygen.

Through the above heat treatment, impurities such as hydrogen and water contained in the insulator 220 and the insulator 222 can be removed, for example. Moreover, by performing heat treatment in an oxygen atmosphere or an atmosphere containing an oxidizing gas at 10 ppm or more, 1% or more, or 10% or more, oxygen can be supplied to the insulator 220 and the insulator 222 in some cases.

Alternatively, as the heat treatment, plasma treatment containing oxygen may be performed under a reduced pressure. The plasma treatment containing oxygen is preferably performed using an apparatus including a power source for generating high-density plasma using microwaves, for example. Alternatively, a power source for applying an RF (Radio Frequency) to a substrate side may be included. The use of high-density plasma enables high-density oxygen radicals to be produced, and application of the RF to the substrate side allows oxygen radicals generated by the high-density plasma to be efficiently introduced into the insulator 222. Alternatively, after plasma treatment containing an inert gas is performed with this apparatus, plasma treatment containing oxygen may be performed to compensate for released oxygen. Note that the first heat treatment is not necessarily performed in some cases.

This heat treatment can also be performed before deposition of the insulator 220 and after deposition of the insulator 220. Although the conditions for the above-described heat treatment can be used for the heat treatment, heat treatment before and after deposition of the insulator 220 is preferably performed in an atmosphere containing nitrogen.

In this embodiment, the heat treatment is performed in such a manner that treatment is performed at 400° C. in a nitrogen atmosphere for one hour after the deposition of the insulator 222, and then another treatment is successively performed at 400° C. in an oxygen atmosphere for one hour.

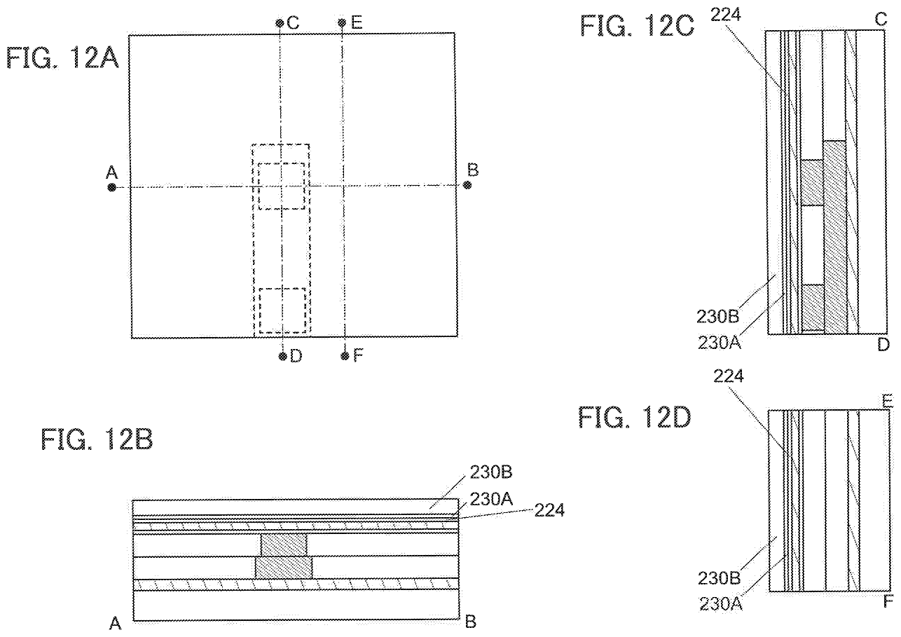

Next, the insulator 224 is deposited over the insulator 222. The insulator 224 can be deposited by a sputtering method, a CVD method, an MBE method, a PLD method, an ALD method, or the like (see FIG. 12). For the insulator 224, silicon oxide or silicon oxynitride can be used, for example. The thickness of the insulator 224 is greater than or equal to 1 nm and less than or equal to 30 nm, preferably greater than or equal to 1 nm and less than or equal to 10 nm, further preferably greater than or equal to 1 nm and less than or equal to 5 nm.

In the case where heat treatment is not performed after the formation of the insulator 222, the insulator 222 and the insulator 224 may be successively formed. Moreover, the insulator 220, the insulator 222, and the insulator 224 may be successively formed.

The above heat treatment may be performed after the insulator 224 is deposited. Through the heat treatment, impurities such as hydrogen and water contained in the insulator 224 can be removed, for example.

Next, an oxide film 230A to be the oxide 230a and an oxide film 230B to be the oxide 230b are formed over the insulator 224 (FIG. 12).

The oxide film 230A and the oxide film 230B can be formed by a sputtering method, a CVD method, an MBE method, a PLD method, an ALD method, or the like.

In the case where the oxide film 230A and the oxide film 230B are formed by a sputtering method, for example, oxygen or a mixed gas of oxygen and a rare gas is used as a sputtering gas. By increasing the proportion of oxygen contained in the sputtering gas, the amount of excess oxygen in the oxide film to be deposited can be increased. In the case where the oxide films are formed by a sputtering method, the above In—M—Zn oxide target can be used.

In particular, part of oxygen contained in the sputtering gas is supplied to the insulator 224 in some cases, at the formation of the oxide film 230A. Note that the proportion of oxygen contained in the sputtering gas for the oxide film 230A is higher than or equal to 70%, preferably higher than or equal to 80%, and further preferably 100%.

The thickness of the oxide film 230A is greater than or equal to 1 nm and less than or equal to 20 nm, preferably greater than or equal to 3 nm and less than or equal to 10 nm. In this embodiment, the oxide film 230A with a thickness off 5 nm is formed using a target of In:Ga:Zn=1:3:4 [atomic ratio] by a sputtering method. The thickness of the oxide film 230B is greater than or equal to 10 nm and less than or equal to 50 nm, preferably greater than or equal to 10 nm and less than or equal to 30 nm, further preferably greater than or equal to 15 nm and less than or equal to 25 nm. In this embodiment, the oxide film 230B with a thickness of 15 nm is deposited by a sputtering method using a target with In:Ga:Zn=4:2:4.1 [atomic ratio]. Note that the oxide films are preferably formed by appropriate selection of deposition conditions and an atomic ratio to have characteristics required for the oxide 230.

After the formation of the oxide film 230A, the oxide film 230B is preferably formed successively without being exposed to an air atmosphere. When a multi-chamber deposition apparatus is used for the formation of the oxide film 230A and the formation of the oxide film 230B, a substrate over which the oxide films are formed can be in a reduced-pressure atmosphere from the beginning of the formation of the oxide film 230A to the end of the formation of the oxide film 230B, so that the oxide film 230B can be formed over the oxide film 230A without exposing the surface of the oxide film 230A to an air atmosphere. By performing the formation of the oxide film 230A and the formation of the oxide film 230B successively, contamination of the interface between the oxide film 230A and the oxide film 230B can be prevented, and a semiconductor device using such oxide films can have favorable characteristics and high reliability.

In the case where the oxide film 230A and the oxide film 230B are formed by a sputtering method, for example, oxygen or a mixed gas of oxygen and a rare gas is used as a sputtering gas. By increasing the proportion of oxygen contained in the sputtering gas, the amount of excess oxygen in the oxide film to be deposited can be increased. In the case where the above oxide films are formed by a sputtering method, the above In—M—Zn oxide target can be used.

In the case where the oxide film 230A and the oxide film 230B are formed by a sputtering method and the proportion of oxygen contained in the sputtering gas is higher than or equal to 1% and lower than or equal to 30%, preferably higher than or equal to 5% and lower than or equal to 20%, an oxygen-deficient oxide semiconductor is formed. In a transistor using an oxygen-deficient oxide semiconductor, relatively high field-effect mobility can be obtained.

In this embodiment, the oxide film 230A is deposited by a sputtering method using a target with In:Ga:Zn=1:3:4 [atomic ratio], and the oxide film 230B is deposited by a sputtering method using a target with In:Ga:Zn=4:2:4.1 [atomic ratio]. In addition, the oxide film 230A and the oxide film 230B are successively formed without being exposed to an air atmosphere with the use of a multi-chamber sputtering apparatus. Note that the oxide films are preferably formed by appropriate selection of deposition conditions and an atomic ratio to have characteristics required for the oxide 230.

Next, heat treatment may be performed. For the heat treatment, the conditions for the above-described heat treatment can be used. Through the heat treatment, impurities such as water and hydrogen contained in the oxide film 230A and the oxide film 230B can be removed, for example. In this embodiment, treatment is performed at 400° C. in a nitrogen atmosphere for one hour, and successively another treatment is performed at 400° C. in an oxygen atmosphere for one hour.

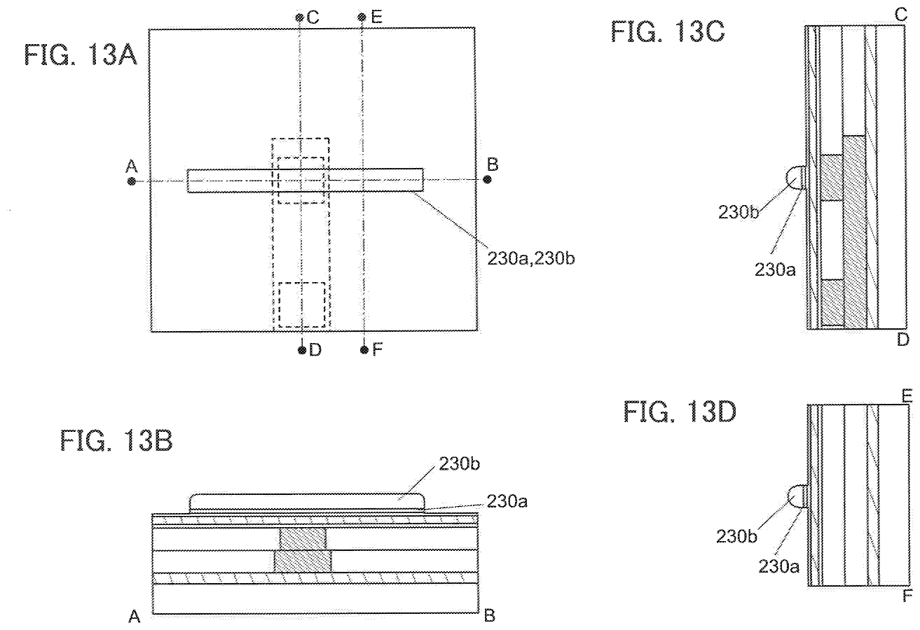

Then, the oxide film 230A and the oxide film 230B are processed into island shapes to form the oxide 230a and the oxide 230b (see FIG. 13).

Note that in the above step, the insulator 224 may be processed into an island shape. Furthermore, the insulator 224 may be subjected to half-etching. When the insulator 224 is subjected to half-etching, the insulator 224 remains also under the oxide 230c to be formed in a later step. Note that the insulator 224 can be processed into an island shape when the conductive film 260A and the conductive film 260B or the insulating film 272A is processed in a later step. In that case, the insulator 222 may be used as an etching stopper film.

Here, the oxide 230a and the oxide 230b are formed to overlap with the conductor 205 at least partly. It is preferable that the side surface of the oxide 230b be on the same plane as the side surface of the oxide 230a. It is also preferable that side surfaces of the oxide 230a and the oxide 230b be substantially perpendicular to the insulator 222. At this time, the end portion of the oxide 230b is substantially aligned with the end portion of the oxide 230a. When the side surfaces of the oxide 230a and the oxide 230b are substantially perpendicular to the insulator 222, a plurality of transistors 200 can be provided in a smaller area at a higher density. Note that a structure may be employed in which an angle formed by the side surfaces of the oxide 230a and the oxide 230b and the top surface of the insulator 222 is an acute angle. In that case, the angle formed by the side surfaces of the oxide 230a and the oxide 230b and the top surface of the insulator 222 is preferably larger.

There is a curved surface between the side surfaces of the oxide 230a and the oxide 230b and the top surface of the oxide 230b. That is, an end portion of the side surface and an end portion of the top surface are preferably curved (hereinafter such a curved shape is also referred to as a rounded shape). The radius of curvature of the curved surface at end portions of the oxide 230a and the oxide 230b is greater than or equal to 3 nm and less than or equal to 10 nm, preferably greater than or equal to 5 nm and less than or equal to 6 nm, for example.

When the end portions are not angular, the coverage with films deposited in the following process can be improved.

Note that for the processing of the oxide films, a lithography method can be employed. Alternatively, a dry etching method or a wet etching method can be employed for the processing. The processing by a dry etching method is suitable for microfabrication.

Note that in the lithography method, first, a resist is exposed to light through a mask. Next, a region exposed to light is removed or left using a developing solution, so that a resist mask is formed. Then, etching treatment through the resist mask is performed, so that the conductor, the semiconductor, the insulator, or the like can be processed into a desired shape. The resist mask is formed by, for example, exposure of the resist to light using KrF excimer laser light, ArF excimer laser light, EUV (Extreme Ultraviolet) light, or the like. Alternatively, a liquid immersion technique may be employed in which a portion between a substrate and a projection lens is filled with liquid (e.g., water) to perform light exposure. Furthermore, an electron beam or an ion beam may be used instead of the above-described light. Note that a mask is not necessary in the case of using an electron beam or an ion beam. Note that for removal of the resist mask, dry etching treatment such as ashing can be performed, wet etching treatment can be performed, wet etching treatment can be performed after dry etching treatment, or dry etching treatment can be performed after wet etching treatment.

A hard mask formed of an insulator or a conductor may be used instead of the resist mask. In the case where a hard mask is used, a hard mask with a desired shape can be formed in the following manner: an insulating film or a conductive film that is the hard mask material is formed over the oxide film 230B, a resist mask is formed thereover, and then the hard mask material is etched. The etching of the oxide film 230A and the oxide film 230B may be performed after the resist mask is removed or with the resist mask left. In the latter case, the resist mask disappears during the etching in some cases. The hard mask may be removed by etching after the etching of the oxide film. The hard mask does not need to be removed in the case where the hard mask material does not affect the following process or can be utilized in the following process.

As a dry etching apparatus, a capacitively coupled plasma (CCP) etching apparatus including parallel plate type electrodes can be used. The capacitively coupled plasma etching apparatus including the parallel plate type electrodes may have a structure in which a high-frequency power source is applied to one of the parallel plate type electrodes. Alternatively, a structure may be employed in which different high-frequency power sources are applied to one of the parallel plate type electrodes. Alternatively, a structure may be employed in which high-frequency power sources with the same frequency are applied to the parallel plate type electrodes. Alternatively, a structure may be employed in which high-frequency power sources with different frequencies are applied to the parallel plate type electrodes. Alternatively, a dry etching apparatus including a high-density plasma source can be used. As the dry etching apparatus including a high-density plasma source, an inductively coupled plasma (ICP) etching apparatus can be used, for example.

In some cases, treatment such as dry etching performed in the above process causes the attachment or diffusion of impurities due to an etching gas or the like to a surface or an inside of the oxide 230a, the oxide 230b, and the like. Examples of the impurities include fluorine and chlorine.

In order to remove the above impurities, cleaning is performed. Examples of the cleaning method include wet cleaning using a cleaning solution or the like, plasma treatment using plasma, and cleaning by heat treatment, and the above cleaning methods may be performed in appropriate combination.

As the wet cleaning, cleaning treatment may be performed using an aqueous solution obtained by diluting an oxalic acid, a phosphoric acid, a hydrofluoric acid, or the like with carbonated water or pure water. Alternatively, ultrasonic cleaning using pure water or carbonated water may be performed. In this embodiment, the ultrasonic cleaning using pure water or carbonated water is performed.

Sequentially, heat treatment may be performed. For the conditions of the heat treatment, the conditions for the above-described heat treatment can be used.

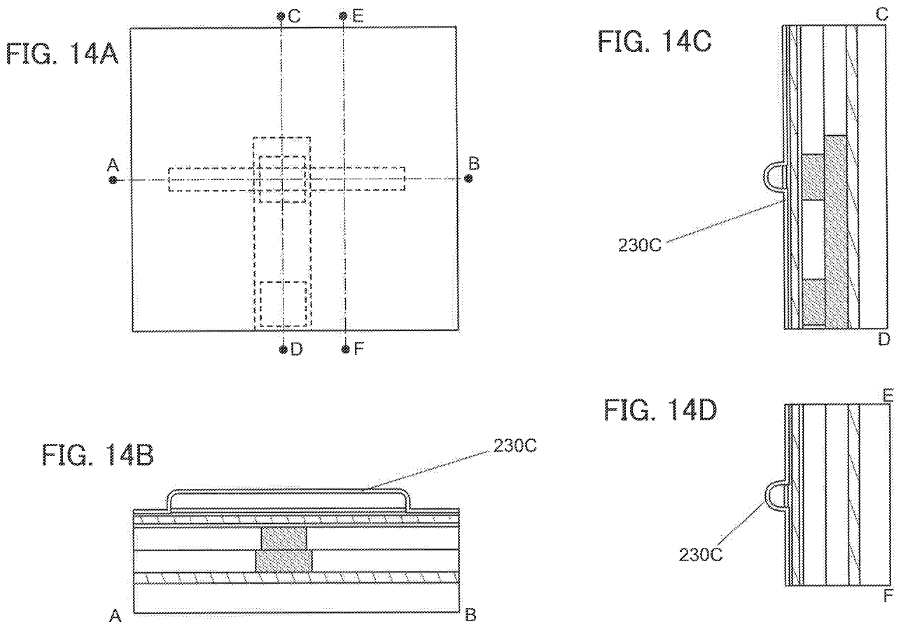

Next, an oxide film 230C to be the oxide 230c is deposited over the insulator 224, the oxide 230a, and the oxide 230b (see FIG. 14).

The oxide film 230C can be formed by a sputtering method, a CVD method, an MBE method, a PLD method, an ALD method, or the like. The oxide film 230C is deposited by a method similar to that for the oxide film 230A or the oxide film 230B in accordance with characteristics required for the oxide 230c. The thickness of the oxide film 230C is greater than or equal to 1 nm and less than or equal to 20 nm, preferably greater than or equal to 3 nm and less than or equal to 10 nm. In this embodiment, the oxide film 230C with a thickness of 5 nm is formed using a target of In:Ga:Zn=1:3:4 [atomic ratio] by a sputtering method.

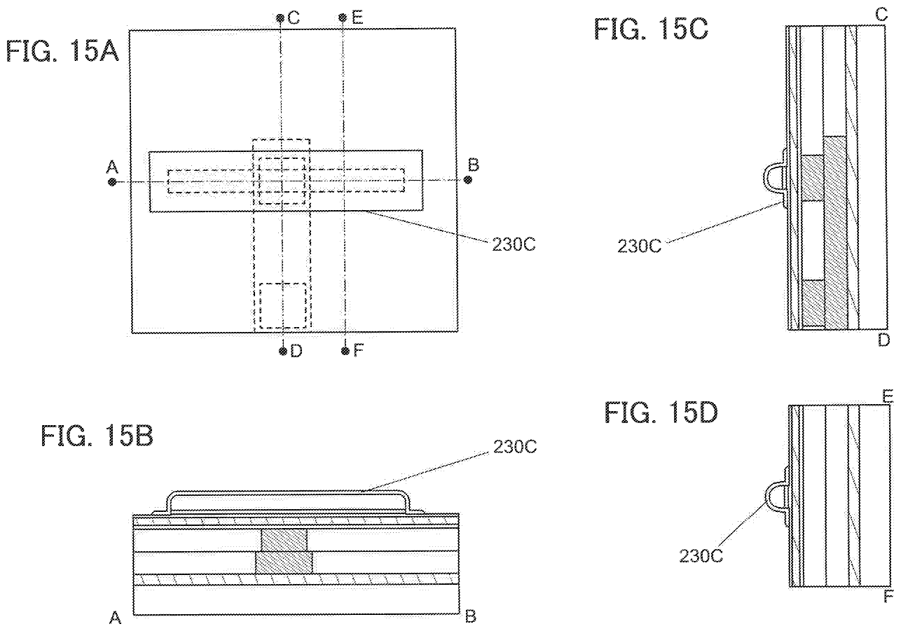

The oxide film 230C may be processed into an island shape as illustrated in FIG. 15. When the oxide film 230C is processed before the formation of the insulator 250 and the conductor 260, part of the oxide film 230C positioned below the insulator 250 and the conductor 260, which are formed in a later step, can be removed. Thus, the oxide film 230C for adjacent cells 600 is divided and leakage through the oxide film 230C between the cells 600 can be prevented, which is preferable.

The oxide film 230C can be processed by dry etching or wet etching. The method used for processing the oxide film 230A and the oxide film 230B may be used.

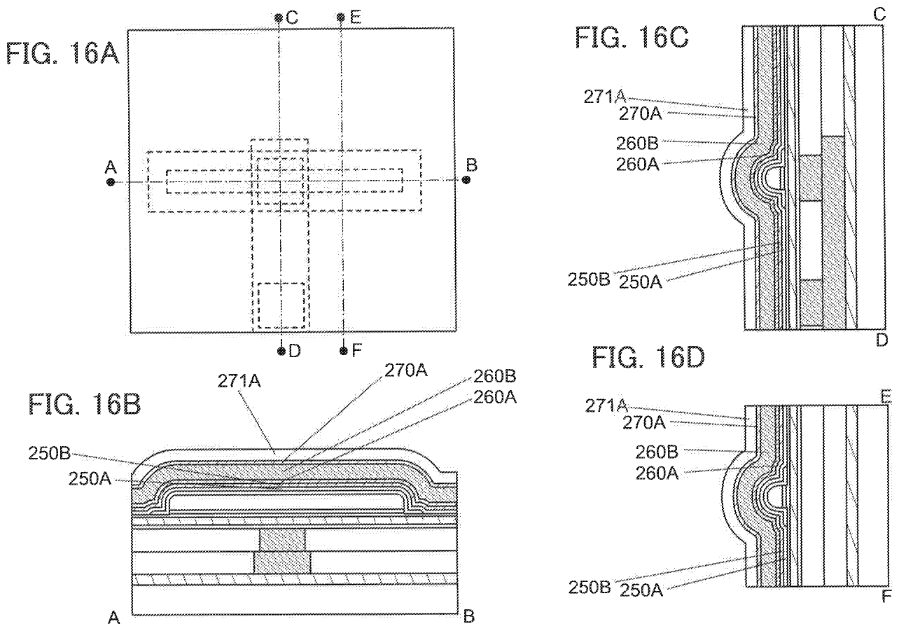

Then, an insulating film 250A, an insulating film 250B, the conductive film 260A, the conductive film 260B, an insulating film 270A, and an insulating film 271A are formed sequentially over the insulator 224 and the oxide film 230C (see FIG. 16).

The insulating film 250A and the insulating film 250B can be deposited by a sputtering method, a CVD method, an MBE method, a PLD method, an ALD method, or the like.

For the insulating film 250A, silicon oxynitride or silicon oxide is formed by a CVD method or an ALD method. For the insulating film 250B, aluminum oxide or hafnium oxide is formed by a sputtering method or an ALD method. In the case where the insulating film 250A and the insulating film 250B are formed by an ALD method, it is preferable that the insulating film 250A and the insulating film 250B be successively deposited with the use of a multi-chamber ALD apparatus. When the insulating film 250A and the insulating film 250B are successively deposited, a substrate over which the insulating films are formed can be in a reduced-pressure atmosphere from the beginning of the formation of the insulating film 250A to the end of the formation of the insulating film 250B, so that the insulating film 250B can be deposited without exposing the surface of the insulating film 250A to an air atmosphere. Accordingly, contamination of an interface between the insulating film 250A and the insulating film 250B can be prevented, and a semiconductor device using these insulating films can have favorable characteristics and high reliability.

It is also preferable that hydrogen or water contained in the insulating film 250A be removed in the formation of the insulating film 250B. It is further preferable that oxygen be supplied to the insulating film 250A in the formation of the insulating film 250B. For example, when the formation temperature of the insulating film 250B is higher than or equal to 200° C., preferably higher than or equal to 400° C., hydrogen or water contained in the insulating film 250A can be released. Moreover, when the insulating film 250B is formed in an atmosphere containing oxygen, oxygen can be supplied to the insulating film 250A. When the insulating film 250B is formed using a target containing oxygen, oxygen can be supplied to the insulating film 250A.

In the formation of the insulating film 250B, the insulating film 250B is formed while the substrate is heated, whereby heat treatment for a substrate that is necessary in a later step can be omitted. That is, the formation of the insulating film 250B can also serve as heat treatment for the substrate.

The thickness of the insulating film 250A is greater than or equal to 1 nm and less than or equal to 20 nm, preferably greater than or equal to 5 nm and less than or equal to 10 nm. The thickness of the insulating film 250B is greater than or equal to 1 nm and less than or equal to 20 nm, preferably greater than or equal to 5 nm and less than or equal to 10 nm.

In this embodiment, 5-nm-thick silicon oxynitride is formed by a CVD method for the insulating film 250A, and 5-nm-thick aluminum oxide is formed by an ALD method for the insulating film 250B. However, the present invention is not limited thereto. For the insulating film 250B, 5-nm-thick hafnium oxide may be formed by an ALD method. Alternatively, the insulating film 250A and the insulating film 250B may be successively formed by an ALD method.

Furthermore, heat treatment may be performed. For the heat treatment, the conditions for the above-described heat treatment can be used. The heat treatment can reduce the moisture concentration and the hydrogen concentration in the insulating film 250A and the insulating film 250B.

The conductive film 260A can be deposited by a sputtering method, a CVD method, an MBE method, a PLD method, an ALD method, or the like. For the conductive film 260A, titanium nitride or tantalum nitride can be used. In this embodiment, for the conductive film 260A, titanium nitride is formed by a sputtering method. Alternatively, the conductive film 260A may be formed by an ALD method. In the case where the conductive film 260A is formed by an ALD method, the insulating film 250B and the conductive film 260A are preferably formed successively. When the insulating film 250B and the conductive film 260A are successively formed, contamination of an interface between the insulating film 250B and the conductive film 260A can be prevented, and a semiconductor device using such an insulating film and a conductive film can have favorable characteristics and high reliability.

The conductive film 260B can be deposited by a sputtering method, a CVD method, an MBE method, a PLD method, an ALD method, or the like. When a low-resistance metal film is stacked for the conductive film 260B, a transistor with a low driving voltage can be provided. In this embodiment, for the conductive film 260B, tungsten is formed by a sputtering method.

Subsequently, heat treatment can be performed. For the heat treatment, the conditions for the above-described heat treatment can be used. Note that the heat treatment is not necessarily performed in some cases. In this embodiment, the treatment is performed at 400° C. in a nitrogen atmosphere for one hour.

The insulating film 270A can be deposited by a sputtering method, a CVD method, an MBE method, a PLD method, an ALD method, or the like. For the insulating film 270A functioning as a barrier film, an insulating material having a function of inhibiting the passage of oxygen and impurities such as water and hydrogen is used. For example, aluminum oxide, hafnium oxide, hafnium aluminate, or silicon nitride is preferably used. Thus, oxidation of the conductor 260 can be prevented. Moreover, this can prevent entry of impurities such as water and hydrogen into the oxide 230 through the conductor 260 and the insulator 250.

The insulating film 271A can be deposited by a sputtering method, a CVD method, an MBE method, a PLD method, an ALD method, or the like. For the insulating film 271A, silicon oxide or silicon oxynitride can be used. Alternatively, silicon nitride may be used for the insulating film 271A. Alternatively, the insulating film 271A may be formed by stacking silicon nitride and silicon oxide, or silicon nitride and silicon oxynitride. Here, the thickness of the insulating film 271A is preferably larger than the thickness of the insulating film 272A to be deposited in a later step. In that case, when the insulator 272 is formed in a later step, the insulator 270 can remain easily over the conductor 260.

The insulator 271 functions as a hard mask. The provision of the insulator 271 makes it possible for a side surface of the insulator 250a, a side surface of the insulator 250b, the side surface of the conductor 260a, the side surface of the conductor 260b, and the side surface of the insulator 270 to be formed substantially perpendicular to the substrate.

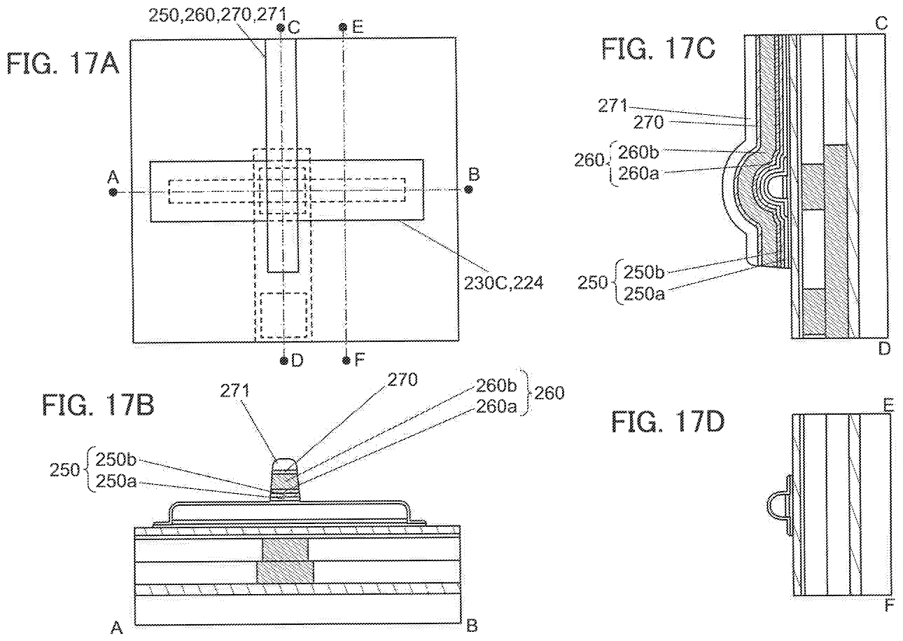

Next, the insulating film 271A is etched to form the insulator 271. Then, using the insulator 271 as a mask, the insulating film 250A, the insulating film 250B, the conductive film 260A, the conductive film 260B, and the insulating film 270A are etched to form the insulator 250 (the insulator 250a and the insulator 250b), the conductor 260 (the conductor 260a and the conductor 260b), and the insulator 270 (see FIG. 17). Note that after the processing, the following process may be performed without removal of the insulator 271. The insulator 271 can also function as a hard mask used for adding a dopant, which is to be performed in a later step.

The side surface of the insulator 250, the side surface of the conductor 260, and the side surface of the insulator 270 are preferably on the same surface. It is preferable that the surface shared by the side surface of the insulator 250, the side surface of the conductor 260, and the side surface of the insulator 270 be substantially perpendicular to the substrate. That is, in a cross-sectional shape, an angle between the top surface of the oxide 230 and the insulator 250, the conductor 260, and the insulator 270 is preferably an acute angle and larger. Note that in the cross-sectional shape, the angle formed by the top surface of the oxide 230, which is in contact with the insulator 250, and the side surfaces of the insulator 250, the conductor 260, and the insulator 270 may be an acute angle. In that case, the angle formed by the top surface of the oxide 230, which is in contact with the insulator 250, and the side surfaces of the insulator 250, the conductor 260, and the insulator 270 is preferably larger.

The insulator 250, the conductor 260, and the insulator 270 are formed to overlap with the conductor 205 and the oxide 230 at least partly.

An upper portion of the oxide film 230C in a region not overlapping with the insulator 250 may be etched by the above etching. In this case, the thickness of the oxide film 230C in a region overlapping with the insulator 250 is larger than the thickness thereof in a region not overlapping with the insulator 250 in some cases.

A region of the insulator 224 not overlapping with the oxide film 230C may be etched by the above etching. In this case, the insulator 222 is exposed in a region not overlapping with the oxide film 230C or the conductor 260.

Subsequently, heat treatment can be performed. For the heat treatment, the conditions for the above-described heat treatment can be used. Note that the heat treatment is not necessarily performed in some cases. In this embodiment, the treatment is performed at 400° C. in a nitrogen atmosphere for one hour.

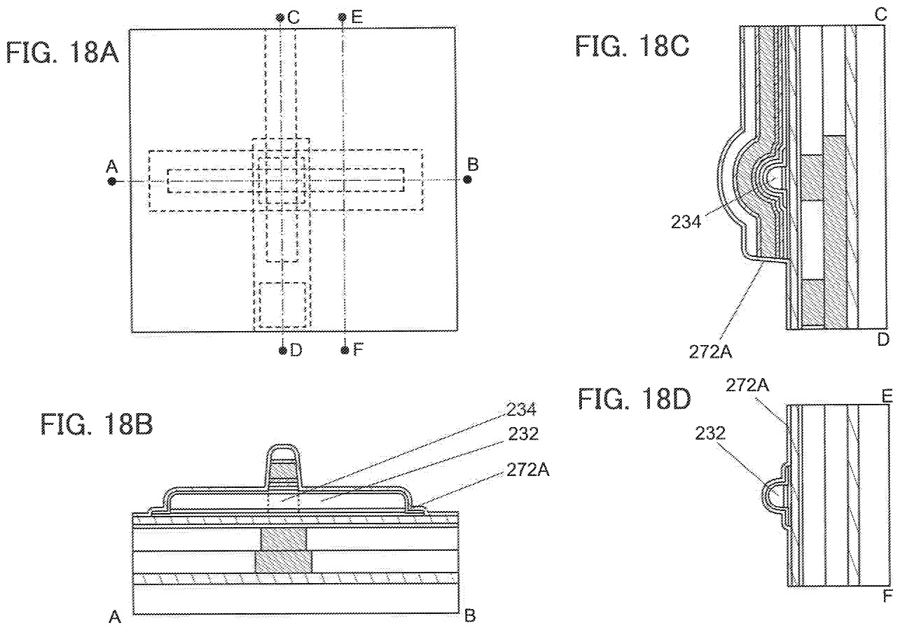

Next, the insulating film 272A is deposited to cover the oxide film 230C, the insulator 250, the conductor 260, the insulator 270, and the insulator 271 (see FIG. 18). The insulating film 272A is preferably deposited by an ALD method which enables good coverage. By using an ALD method, the insulating film 272A having a uniform thickness can be formed on the side surfaces of the insulator 250, the conductor 260, and the insulator 270 even in a step portion formed by the conductor 260 and the like. Forming the insulating film 272A with good coverage on the side surface of the insulator 250 can prevent release of oxygen contained in the insulator 250 from the side surface of the insulator 250.

At this time, the resistance value of the oxide 230 that is in contact with the insulating film 272A is reduced in some cases. This is caused probably because hydrogen, nitrogen, carbon, or the like contained in the source gas enters the oxide 230 in the formation of the insulating film 272A by an ALD method. The region of the oxide 230 whose resistance is reduced by the formation of the insulating film 272A serves as the region 232. A region between the regions 232 serves as the region 234.

In contrast, it is preferable that oxygen can be added to one or both of the oxide 230 and the insulator 250 in the formation of the insulating film 272A. Furthermore, it is preferable that hydrogen can be removed from one or both of the oxide 230 and the insulator 250 in the formation of the insulating film 272A. In order to add oxygen to one or both of the oxide 230 and the insulator 250 or to remove hydrogen from one or both of the oxide 230 and the insulator 250, the insulating film 272A is formed through the deposition sequence shown in FIG. 5(A), FIG. 5(B), or FIG. 5(C).

Furthermore, in the formation of the insulating film 272A, the insulating film 272A is formed while the substrate is heated, so that heat treatment for the substrate that is necessary in a later step can be omitted. That is, the formation of the insulating film 272A can also serve as heat treatment for the substrate.

In addition, a rare gas may be added to the oxide 230 using the insulator 250, the conductor 260, the insulator 270, and the insulator 271, which are covered with the insulating film 272A, as masks. For the addition of the rare gas, for example, an ion implantation method by which an ionized source gas is subjected to mass separation and then added, an ion doping method by which an ionized source gas is added without mass separation, a plasma immersion ion implantation method, or plasma treatment can be used. The region 234 and the region 232 may be provided in the oxide 230 by addition of a rare gas.

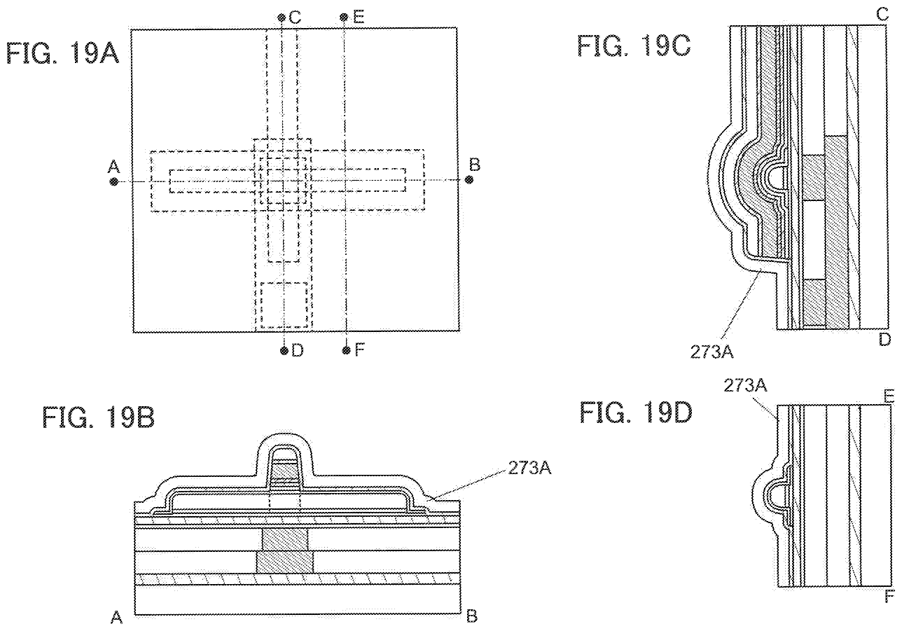

Next, an insulating film 273A is deposited to cover the insulating film 272A (see FIG. 19). For the insulating film 273A, a material with a low permittivity is preferably used, and a material similar to that for the insulator 212 and the insulator 216 can be used. For the insulating film 273A, silicon oxide or silicon oxynitride can be used. Alternatively, silicon nitride may be used for the insulating film 273A.

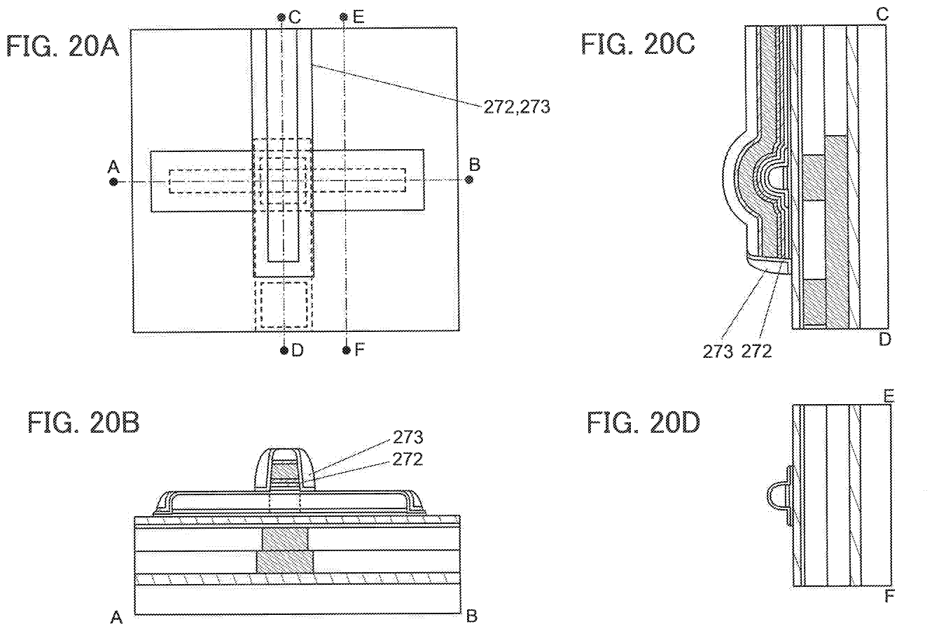

Next, the insulating film 273A and the insulating film 272A are subjected to anisotropic etching treatment, whereby the insulator 272 functioning as a barrier and the insulator 273 functioning as a sidewall are formed in contact with the side surfaces of the insulator 250, the conductor 260, and the insulator 270 (see FIG. 20). Dry etching treatment is preferably performed as the anisotropic etching treatment. In this manner, the insulator 272 and the insulator 273 can be formed in a self-aligned manner. At this time, part of the insulating film 272A and part of the insulating film 273A remain on the side wall of the oxide 230 in some cases.

The insulator 271 is formed over the insulator 270 here, whereby the insulator 270 can be left even when the insulating film 273A and the insulating film 272A in a portion above the insulator 270 are removed. The height of a structure body composed of the insulator 250, the conductor 260, the insulator 270, and the insulator 271 is made greater than the total height of the oxide 230a, the oxide 230b, and the oxide film 230C, whereby the insulating film 273A and the insulating film 272A on the side surfaces of the oxide 230a and the oxide 230b with the oxide film 230C therebetween can be removed. Furthermore, when the end portions of the oxide 230a and the oxide 230b have a round shape, time taken to remove the insulating film 273A and the insulating film 272A, which are deposited on the side surfaces of the oxide 230a and the oxide 230b with the oxide film 230C therebetween, can be shortened, leading to easier formation of the insulator 272 and the insulator 273.

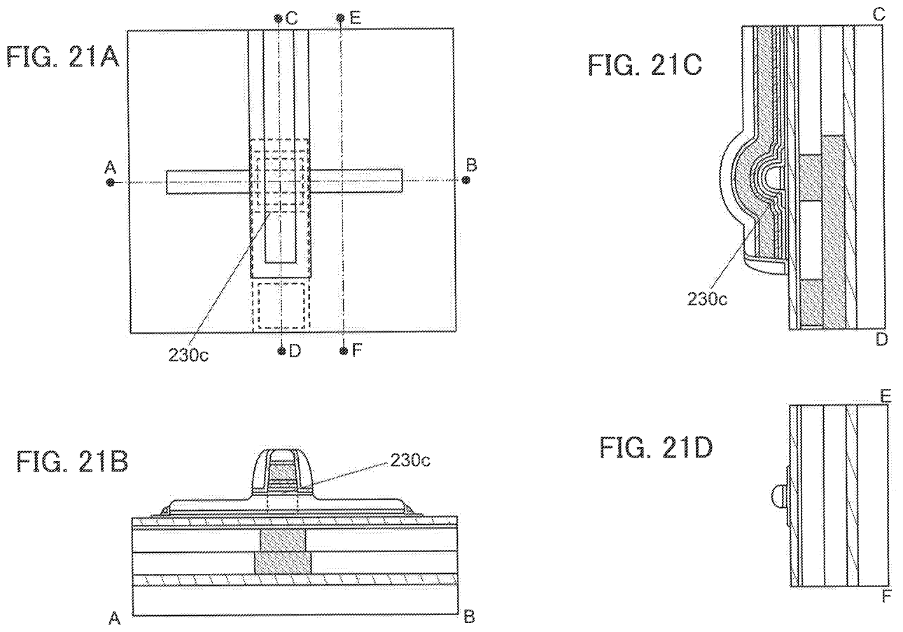

Next, the oxide film 230C is etched using the insulator 250, the conductor 260, the insulator 270, the insulator 271, the insulator 272, and the insulator 273 as masks to remove part of the oxide film 230C, so that the oxide 230c is formed (see FIG. 21). Note that through this process, the top surface and the side surfaces of the oxide 230b and the side surfaces of the oxide 230a are partly removed in some cases. In addition, part of the oxide film 230C, part of the insulating film 272A, and part of the insulating film 273A remain on the side wall of the oxide 230 in some cases.

Here, the region 231 may be formed in the oxide 230a, the oxide 230b, and the oxide 230c. The region 231 is a region whose resistance is reduced by addition of a metal atom such as indium or impurities to metal oxides provided as the oxide 230a, the oxide 230b, and the oxide 230c. Note that each of the regions has higher conductivity than at least the oxide 230b in the region 234.

In order to reduce the resistance of the region 231 and the region 232, at least one of a metal atom such as indium, a rare gas such as helium or argon, and an impurity such as hydrogen and nitrogen is added as a dopant, for example.

As the dopant, an element that forms an oxygen vacancy in the region 231 and the region 232, an element that is bonded to an oxygen vacancy, or the like is used. Typical examples of the element are boron and phosphorus. Moreover, hydrogen, carbon, nitrogen, fluorine, sulfur, chlorine, titanium, a rare gas, or the like may be used are well as boron and phosphorus. Typical examples of the rare gas element are helium, neon, argon, krypton, and xenon. Furthermore, examples of the above element include metal elements such as aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum. One or more elements selected from the above elements may be added to the oxide 230. Among the above elements, boron or phosphorus is preferable as a dopant. In the case where boron or phosphorus is used as a dopant, manufacturing line apparatuses for amorphous silicon or low-temperature polysilicon can be used; thus, capital investment can be reduced.

Heat treatment is preferably performed after addition of the above element. The heat treatment probably allows effective bonding of the element added to the oxide 230 with oxygen in the oxide 230, so that more oxygen vacancies are formed. Impurities such as hydrogen are trapped by the oxygen vacancy, whereby the resistance values of the region 231 and the region 232 of the oxide 230 are further reduced. Note that the heat treatment may be performed just after the addition of the element, after formation of insulators, conductors, and the like, or after processing. That is, another step may be performed between the addition of the element and the heat treatment.

Note that as a method for adding the dopant, an ion implantation method by which an ionized source gas is subjected to mass separation and then added, an ion doping method by which an ionized source gas is added without mass separation, a plasma immersion ion implantation method, or the like can be used. In the case of performing mass separation, ion species to be added and its concentration can be adjusted precisely. On the other hand, in the case of not performing mass separation, ions at a high concentration can be added in a short time. Alternatively, an ion doping method in which atomic or molecular clusters are generated and ionized may be used. Note that a dopant may be referred to as an ion, a donor, an acceptor, an impurity, an element, or the like.

Alternatively, a dopant may be added by plasma treatment. In this case, the plasma treatment can be performed with a plasma CVD apparatus, a dry etching apparatus, or an ashing apparatus to add a dopant to the oxide 230a, the oxide 230b, and the oxide 230c.

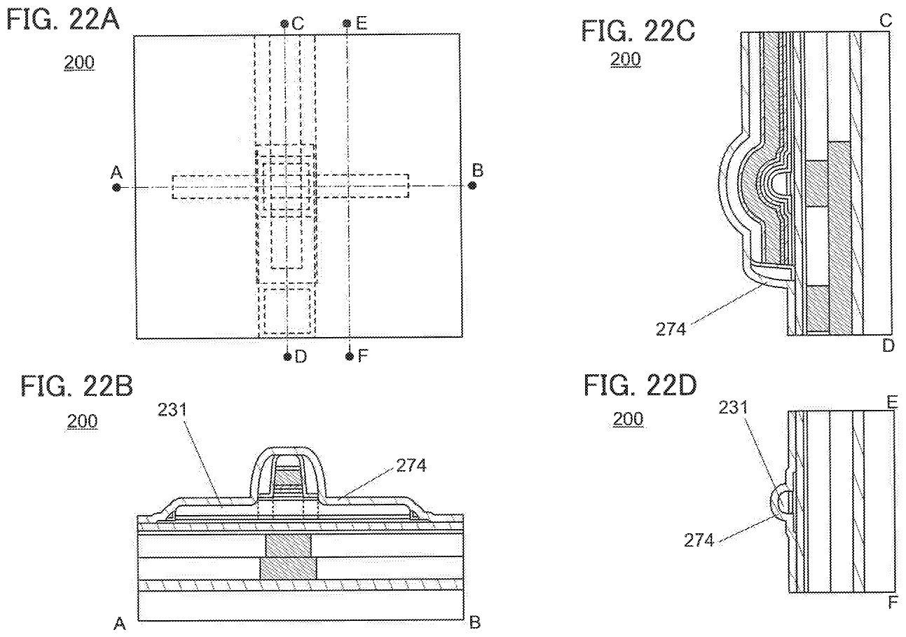

Furthermore, in the case where an impurity is added as a dopant, a film containing a dopant may be formed in contact with the oxide 230. For example, the insulator 274 containing hydrogen, boron, carbon, nitrogen, fluorine, or phosphorus as a dopant is deposited in contact with the oxide 230 positioned outward from the oxide 230c, the insulator 272, and the insulator 273, whereby the region 231 is formed (see FIG. 22). Owing to the deposition of the insulator 274 or heat treatment after the deposition, the resistance of the region 231 is reduced. It is considered that the dopant contained in the insulator 274 is diffused into the region 231 and the resistance of the region is reduced. The dopant contained in the insulator 274 may also be diffused into the region 232, and the resistance of the region 232 may become lower than the resistance value reduced by the above-described addition of the rare gas.

When the indium content in the oxide 230a, the oxide 230b, and the oxide 230c is increased, the carrier density can be increased and the resistance can be reduced. Accordingly, a metal element that improves the carrier density of the oxide 230a, the oxide 230b, and the oxide 230c, such as indium, can be used as a dopant.

That is, when the content of a metal atom such as indium in the oxide 230a, the oxide 230b, and the oxide 230c is increased in the region 231 and the region 232, the electron mobility can be increased and the resistance can be reduced.

In that case, the atomic ratio of indium to the element M at least in the region 231 is larger than the atomic ratio of indium to the element M in the region 234.

As the dopant, the above-described element that forms an oxygen vacancy, the above-described element trapped by an oxygen vacancy, or the like is used. Typical examples of such an element are hydrogen, boron, carbon, nitrogen, fluorine, phosphorus, sulfur, chlorine, titanium, and a rare gas. Typical examples of the rare gas element are helium, neon, argon, krypton, and xenon.

When the region 232 is provided in the transistor 200, a high-resistance region is not formed between the region 231 functioning as the source region or the drain region and the region 234 where a channel is formed, so that the on-state current and the mobility of the transistor can be increased. Moreover, since the gate does not overlap with the source region and the drain region in the channel length direction owing to the region 232, formation of unnecessary capacitance can be inhibited. Furthermore, leakage current in a non-conduction state can be reduced owing to the region 232.

Thus, by appropriately selecting the areas of the region 231a and the region 231b, a transistor having electrical characteristics that meet the demand for the circuit design can be easily provided.

In this embodiment, the insulator 274 is deposited to cover the insulator 222, the oxide 230, the insulator 271, the insulator 272, and the insulator 273 (see FIG. 22).

For the insulator 274, silicon nitride, silicon nitride oxide, or silicon oxynitride which is deposited by a CVD method can be used, for example. In this embodiment, silicon nitride oxide is used for the insulator 274. In the case where the insulator 274 is used as a dielectric of the capacitor 100, its thickness is greater than or equal to 1 nm and less than or equal to 20 nm, preferably greater than or equal to 3 nm and less than or equal to 10 nm.

When the insulator 274 containing an element serving as an impurity such as nitrogen is deposited in contact with the oxide 230, impurity elements such as hydrogen and nitrogen, which are contained in a deposition atmosphere of the insulator 274, are added to the region 231a and the region 231b. Oxygen vacancies are formed because of the added impurity elements, and the impurity elements enter the oxygen vacancies mainly in a region of the oxide 230 which is in contact with the insulator 274, thereby increasing the carrier density and reducing the resistance. At this time, the impurities are diffused also into the region 232 that is not in contact with the insulator 274, whereby the resistance of the region 232 is reduced.

Therefore, the region 231a and the region 231b preferably have a higher concentration of at least one of hydrogen and nitrogen than the region 234. The concentration of hydrogen or nitrogen is measured by secondary ion mass spectrometry (SIMS) or the like. Here, as the concentration of hydrogen or nitrogen in the region 234, the concentration of hydrogen or nitrogen in the middle of the region of the oxide 230b that overlaps with the insulator 250 (e.g., a portion in the oxide 230b which is located equidistant from both side surfaces of the insulator 250 in the channel length direction) is measured.

Note that the resistances of the region 231 and the region 232 to which an element that forms an oxygen vacancy or an element trapped by an oxygen vacancy is added are reduced. Typical examples of such an element are hydrogen, boron, carbon, nitrogen, fluorine, phosphorus, sulfur, chlorine, titanium, and a rare gas. Typical examples of the rare gas element are helium, neon, argon, krypton, and xenon. Accordingly, the region 231 and the region 232 are made to contain one or more of the above elements.

Alternatively, as the insulator 274, a film which extracts and absorbs oxygen contained in the region 231 and the region 232 may be used. When oxygen is extracted, oxygen vacancies are generated in the region 231 and the region 232. Hydrogen, boron, carbon, nitrogen, fluorine, phosphorus, sulfur, chlorine, titanium, a rare gas, or the like is trapped by oxygen vacancies, whereby the resistances of the region 231 and the region 232 are reduced.

In the case of depositing the insulator 274 as an insulator containing an element serving as an impurity or an insulator extracting oxygen from the oxide 230, a sputtering method, a CVD method, an MBE method, a PLD method, an ALD method, or the like can be used for the deposition of the insulator 274.

The insulator 274 containing an element serving as an impurity is preferably deposited in an atmosphere containing at least one of nitrogen and hydrogen. When deposition is performed in such an atmosphere, oxygen vacancies are formed mainly in regions not overlapping with the insulator 250 of the oxide 230b and the oxide 230c and the oxygen vacancies and impurity elements such as nitrogen and hydrogen are bonded to each other, leading to an increase in carrier density. In this manner, the region 231a and the region 231b with reduced resistance can be formed. For the insulator 274, for example, silicon nitride, silicon nitride oxide, or silicon oxynitride formed by a CVD method can be used. In this embodiment, silicon nitride oxide is used for the insulator 274.

The insulator 274 may have a stacked-layer structure of two or more layers of an insulator. The insulator 274 can be formed by a CVD method, an ALD method, a sputtering method, or the like. An ALD method is favorable for deposition on a step portion formed by the oxide 230 or the conductor 260 because of its excellent step coverage, excellent thickness uniformity, and excellent thickness controllability. The insulator 274 may be formed in such a manner that an insulator with a thickness of greater than or equal to 0.5 nm and less than or equal to 5.0 nm is formed by an ALD method, and then an insulator with a thickness of greater than or equal to 1 nm and less than or equal to 20 nm, preferably greater than or equal to 3 nm and less than or equal to 10 nm is stacked thereover by a plasma CVD method. For example, over aluminum oxide, hafnium oxide, or an oxide containing aluminum and hafnium (hafnium aluminate) formed by an ALD method, silicon nitride, silicon nitride oxide, silicon oxynitride, or silicon oxide formed by a plasma CVD method is stacked, so that the insulator 274 may be formed. Alternatively, an insulator with a thickness of greater than or equal to 1 nm and less than or equal to 20 nm, preferably greater than or equal to 3 nm and less than or equal to 10 nm may be formed to be a single-layer insulator 274 by a plasma CVD method. For example, silicon nitride, silicon nitride oxide, silicon oxynitride, or silicon oxide formed by a plasma CVD method may be the insulator 274.

Accordingly, the source region and the drain region can be formed in a self-aligned manner owing to the deposition of the insulator 274. Thus, miniaturized or highly integrated semiconductor devices can be manufactured with high yield.

Here, the top surfaces and the side surfaces of the conductor 260 and the insulator 250 are covered with the insulator 270 and the insulator 272, whereby impurity elements such as nitrogen and hydrogen can be prevented from entering the conductor 260 and the insulator 250. Thus, the impurity elements such as nitrogen and hydrogen can be prevented from entering the region 234 functioning as the channel formation region of the transistor 200 through the conductor 260 and the insulator 250. Accordingly, the transistor 200 having favorable electrical characteristics can be provided.

Note that although the region 231 is formed by the reduction in the resistance of the oxide 230 owing to the deposition of the insulator 274 in the above, this embodiment is not limited thereto. For example, each region and the like may be formed by dopant addition treatment or plasma treatment, or the combination of these treatments.

For example, plasma treatment may be performed on the oxide 230 using the insulator 250, the conductor 260, the insulator 272, the insulator 273, the insulator 270, and the insulator 271 as masks. The plasma treatment is performed in, for example, an atmosphere containing the above-described element that forms an oxygen vacancy or the above-described element trapped by an oxygen vacancy. For example, the plasma treatment is performed using an argon gas and a nitrogen gas.

Subsequently, heat treatment can be performed. For the heat treatment, the conditions for the above-described heat treatment can be used. The heat treatment allows diffusion of the added dopant into the region 231 of the oxide 230, resulting in an increase in on-state current. Furthermore, the added dopant may be diffused into the region 232 by this heat treatment.

Through the above process, the transistor 200 can be formed. An insulator 280 may be formed over the insulator 274. The insulator 280 can be deposited by a sputtering method, a CVD method, an MBE method, a PLD method, an ALD method, or the like. Alternatively, a spin coating method, a dipping method, a droplet discharging method (such as an ink-jet method), a printing method (such as screen printing or offset printing), a doctor knife method, a roll coater method, a curtain coater method, or the like can be used. In this embodiment, silicon oxynitride is used for the insulator 280.

Note that the insulator 280 is preferably formed to have a planar top surface. For example, the insulator 280 may have a planar top surface at the point when the insulating film to be the insulator 280 is deposited. Alternatively, for example, the insulator 280 may have planarity by processing the top surface of the insulator and the like after the deposition so that the top surface becomes parallel to a reference surface such as a rear surface of the substrate. Such treatment is referred to as planarization treatment. Examples of the planarization treatment include CMP treatment and dry etching treatment. In this embodiment, CMP treatment is used as the planarization treatment. Note that the top surface of the insulator 280 does not necessarily have planarity.

Then, an opening reaching the region 231 of the oxide 230 is formed in the insulator 280 and the insulator 274, an opening reaching the conductor 260 is formed in the insulator 280, the insulator 274, the insulator 271, and the insulator 270, and an opening reaching the conductor 205 is formed in the insulator 280, the insulator 274, the insulator 222, and the insulator 220. The openings can be formed by a lithography method.

Note that in order that the conductor 252a and the conductor 252b are provided in contact with the side surface of the oxide 230, the opening reaching the oxide 230 is formed such that the side surface of the oxide 230 is exposed in the opening.

Next, the conductor 252 (the conductor 252a, the conductor 252b, the conductor 252c, and the conductor 252d) may be formed. A conductor electrically connected to the conductor 252 may be formed, as necessary.

### <Method 2 for Fabricating Semiconductor Device>

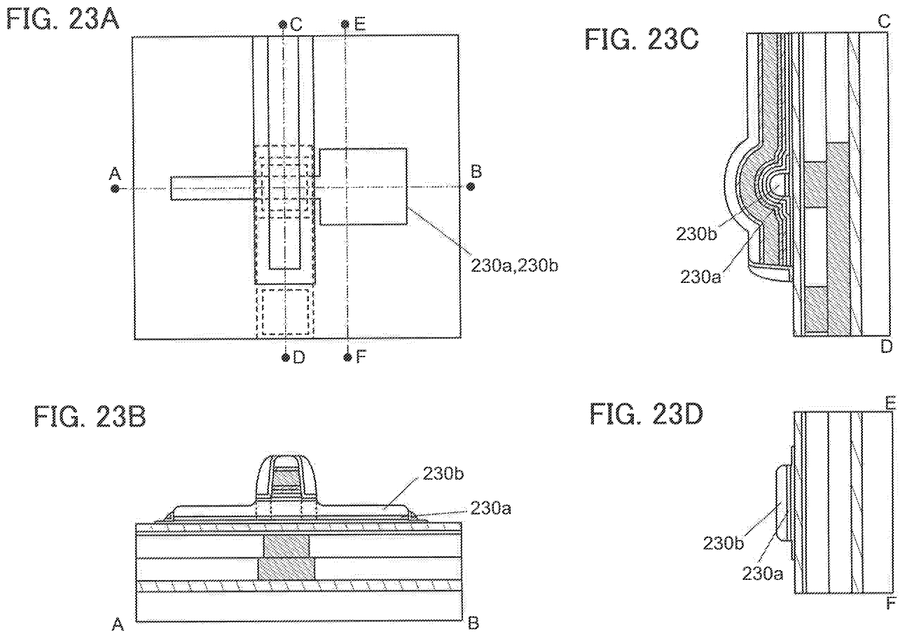

A method for fabricating a semiconductor device including the capacitor 100 in the same layer as the transistor 201 is described with reference to FIG. 23 to FIG. 25. In FIG. 23 to FIG. 25, (A) of each drawing is a top view. Moreover, (B) of each drawing is a cross-sectional view corresponding to a portion indicated by dashed-dotted line A-B in (A). Furthermore, (C) of each drawing is a cross-sectional view corresponding to a portion indicated by dashed-dotted line C-D in (A). Furthermore, (D) of each drawing is a cross-sectional view corresponding to a portion indicated by dashed-dotted line E-F in (A).

Note that since the method for forming the transistor 200 described in <Method 1 for fabricating semiconductor device> can be referred to for the method for forming the transistor 201, the description is omitted. In this fabricating method, the capacitance value of the capacitor 100 depends on the area of the oxide 230. This fabricating method shows an example in which the capacitance value of the capacitor 100 is increased by expanding part of the oxide 230 in the channel width direction (E-F direction).

First, in accordance with <Method 1 for fabricating semiconductor device>, the insulator 274 is deposited to cover the insulator 222, the oxide 230, the insulator 271, the insulator 272, and the insulator 273 to form the region 231 in the oxide 230, and then the insulator 274 is removed (see FIG. 23).

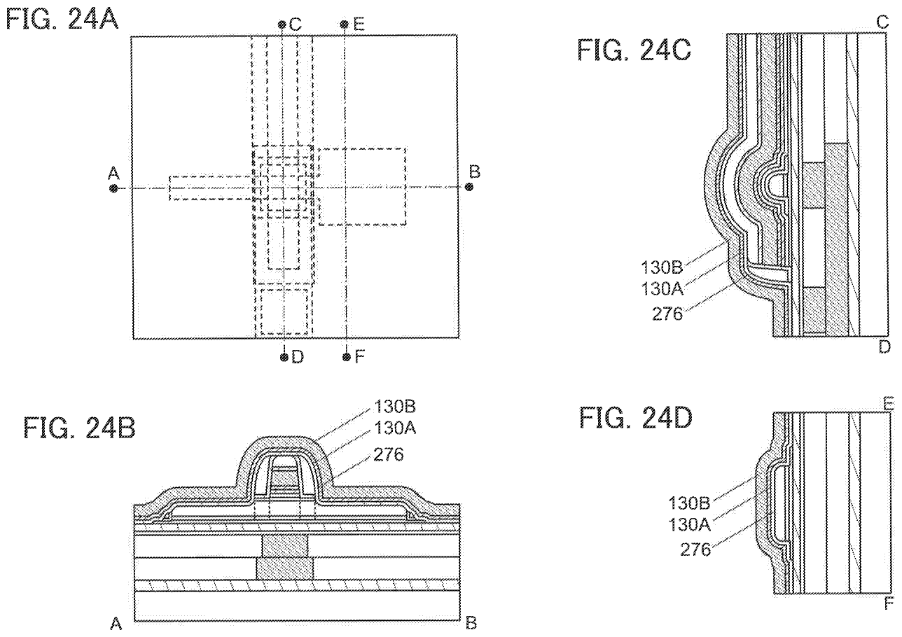

Next, the insulator 276 functioning as a dielectric of the capacitor 100 is formed (see FIG. 24). A material similar to that for the insulator 222 can be used for the insulator 276. An oxide insulator containing one or both of aluminum and hafnium is preferably used as the insulator 276. Aluminum oxide, hafnium oxide, an oxide containing aluminum and hafnium (hafnium aluminate), or the like is preferably used as the oxide insulator containing one or both of aluminum and hafnium. The thickness of the insulator 276 is greater than or equal to 1 nm and less than or equal to 10 nm, preferably greater than or equal to 1 nm and less than or equal to 5 nm.

The insulator 276 needs to be formed at a step portion formed by the oxide 230, the insulator 250, the conductor 260, the insulator 271, and the like. In order to form the insulator 276 having the above thickness at the step portion with a uniform thickness, an ALD method is preferably used.

The insulator 276 may have a stacked-layer structure. In the case where the insulator 276 has a stacked-layer structure, for example, a stacked-layer structure of hafnium oxide, aluminum oxide, and hafnium oxide is preferable. Alternatively, a stacked-layer structure of aluminum oxide, hafnium oxide, and aluminum oxide is preferable. Note that the insulator 276 of the present invention is not limited to the three-layer structure. The insulator 276 may have a single-layer structure, a two-layer structure, or a stacked-layer structure of four or more layers.

Each layer of the insulator 276 is preferably formed by an ALD method. In the case where the formation is performed by an ALD method, a multi-chamber ALD apparatus is preferably used as the apparatus for forming the insulator. With the use of a multi-chamber ALD apparatus, a substrate over which the insulator 276 is formed can be in a reduced-pressure atmosphere from the beginning of the formation of the insulator 276 to the end of the formation of each layer of the insulator 276; thus, the insulator 276 having a stacked-layer structure can be successively formed without being exposed to an air atmosphere. Each layer of the insulator 276 is successively formed, whereby contamination of interfaces between each layer of the insulator 276 can be prevented. A semiconductor device using such an insulator can have favorable characteristics and high reliability.

In the case where the insulator 276 has a stacked-layer structure, the thickness of each layer is greater than or equal to 0.5 nm and less than or equal to 5 nm, preferably greater than or equal to 1 nm and less than or equal to 3 nm. For example, a 1-nm-thick insulator including hafnium oxide, a 1-nm-thick insulator including aluminum oxide, and a 1-nm-thick insulator including hafnium oxide are successively deposited by an ALD method. In this case, the thickness of the insulator 276 is 3 nm. Note that the structure of the insulator 276 of the present invention is not limited thereto. The thicknesses of the layers of the insulator 276 having a stacked-layer structure may be the same or different from each other, or any one of the thicknesses may be different.

The insulator 276 is provided partly in contact with the region 231 having reduced resistance of the oxide 230. In the formation of the insulator 276, supply of oxygen to the region 231 or release of impurities such as hydrogen from the region 231 might increase the resistance value of the region 231. In order to reduce supply of oxygen to the region 231, it is preferable that the region 231 be not exposed to an oxygen atmosphere during the deposition. For example, in the formation of the insulator 276 by an ALD method, the deposition sequence in FIG. 5(C), in which the step of setting the inside of the chamber in an oxygen atmosphere (S104) is omitted, is preferably used. In the case where oxygen is contained in the second source gas, the pulse time (the ON time) is preferably as short as possible. In order to prevent release of impurities such as hydrogen from the region 231, the formation temperature of the insulator 276 is preferably set low, e.g., lower than or equal to 250° C., preferably lower than or equal to 200° C.

Furthermore, in the formation of the insulator 276, the insulator 276 is formed while the substrate is heated, so that heat treatment for the substrate that is necessary in a later step can be omitted. That is, the formation of the insulator 276 can also serve as heat treatment for the substrate.

Next, the conductive film 130A and a conductive film 130B are formed over the insulator 276 (see FIG. 24). The conductive film 130A and the conductive film 130B can be deposited by a sputtering method, a CVD method, an MBE method, a PLD method, an ALD method, or the like. In this embodiment, titanium nitride is formed by a sputtering method for the conductive film 130A, and tungsten is formed by a sputtering method for the conductive film 130B.

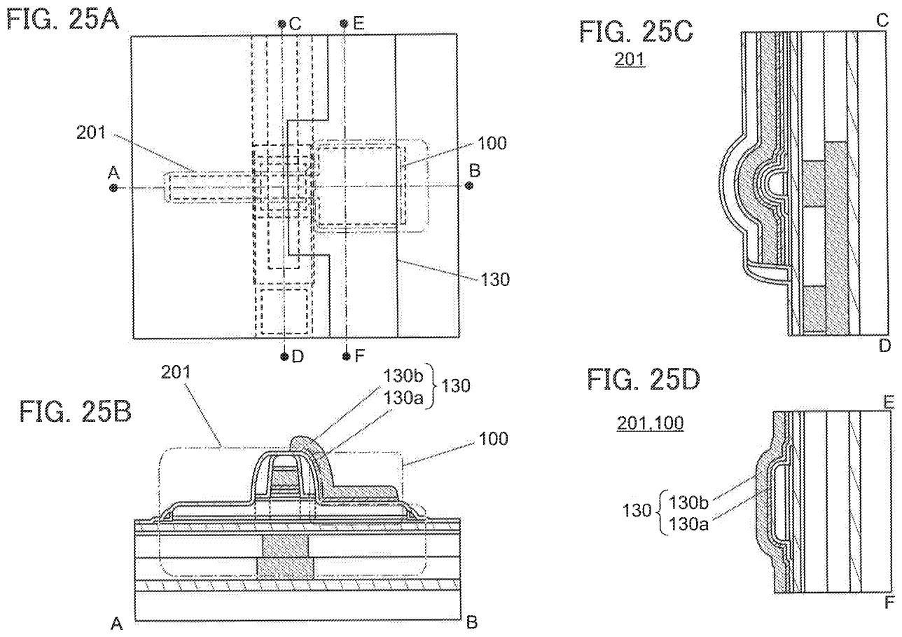

Next, the conductive film 130A and the conductive film 130B are processed by a lithography method to form the conductor 130 (the conductor 130a and the conductor 130b) (see FIG. 25). For the processing of the conductive film 130A and the conductive film 130B, a dry etching method, a wet etching method, or a combination of these methods can be used. A dry etching method in which anisotropic etching can be achieved is preferable because of its excellent microfabrication. In contrast, by using wet etching that allows isotropic etching, the conductive film 130A and the conductive film 130B on the side surface of the oxide 230, the side surface of the insulator 250, and side surface of the insulator 272 are easily removed. Thus, processing in which a dry etching method and a wet etching method are combined is preferable because the conductor 130 with favorable shape can be formed.

In this embodiment, as illustrated in FIG. 25(A) and FIG. 25(D), part of the conductor 130 provided over the oxide 230 is provided to extend outward from the oxide 230. Specifically, the conductor 130 is provided to extend beyond the oxide 230 to the E side and the F side in FIG. 25(D).

Such a shape is preferable because the capacitor 100 can form capacitance not only between the top surface of the oxide 230 and the conductor 130 but also between the side surface of the oxide 230 and the conductor 130. Therefore, in FIG. 25(B), the conductor 130 may be provided to extend beyond the oxide 230 to the B side. In contrast, when there is a limitation on the area occupied by the cell 600, the conductor 130 is formed so as to extend beyond the oxide 230 as little as possible; thus, the cell 600 can be miniaturized, so that higher integration of the semiconductor device can be achieved.

The conductor 130 may be formed to be connected to the conductor 130 of the adjacent capacitor 100.

Through the above process, the semiconductor device including the capacitor 100 in the same layer as the transistor 201 can be formed. An insulator 280 may be formed over the insulator 276 and the conductor 130. The insulator 280 can be deposited by a sputtering method, a CVD method, an MBE method, a PLD method, an ALD method, or the like. Alternatively, a spin coating method, a dipping method, a droplet discharging method (such as an ink-jet method), a printing method (such as screen printing or offset printing), a doctor knife method, a roll coater method, a curtain coater method, or the like can be used. In this embodiment, silicon oxynitride is used for the insulating film.

Note that the insulator 280 is preferably formed to have a planar top surface. For example, the insulator 280 may have a planar top surface at the point when the insulating film to be the insulator 280 is deposited. Alternatively, for example, the insulator 280 may have planarity by processing the top surface of the insulator and the like after the deposition so that the top surface becomes parallel to a reference surface such as a rear surface of the substrate. Such treatment is referred to as planarization treatment. Examples of the planarization treatment include CMP treatment and dry etching treatment. In this embodiment, CMP treatment is used as the planarization treatment. Note that the top surface of the insulator 280 does not necessarily have planarity.

Then, an opening reaching the region 231 of the oxide 230 is formed in the insulator 280 and the insulator 276, an opening reaching the conductor 130 is formed in the insulator 280, an opening reaching the conductor 260 is formed in the insulator 280, the insulator 276, the insulator 271, and the insulator 270, and an opening reaching the conductor 205 is formed in the insulator 280, the insulator 276, the insulator 222, and the insulator 220. The openings can be formed by a lithography method.

Note that in order that the conductor 252a is provided in contact with the side surface of the oxide 230, the opening reaching the oxide 230 is formed such that the side surface of the oxide 230 is exposed in the opening.

Next, the conductor 252 (the conductor 252a, the conductor 252b, the conductor 252c, and the conductor 252d) may be formed. A conductor electrically connected to the conductor 252 may be formed, as necessary.

According to one embodiment of the present invention, a semiconductor device that can be miniaturized or highly integrated can be provided. Alternatively, according to one embodiment of the present invention, a semiconductor device having favorable electrical characteristics can be provided. Alternatively, according to one embodiment of the present invention, a semiconductor device with low off-state current can be provided. Alternatively, according to one embodiment of the present invention, a transistor with high on-state current can be provided. Alternatively, according to one embodiment of the present invention, a highly reliable semiconductor device can be provided. Alternatively, according to one embodiment the present invention, a semiconductor device with reduced power consumption can be provided. Alternatively, according to one embodiment of the present invention, a semiconductor device with high productivity can be provided.

The structure, method, and the like described above in this embodiment can be used in an appropriate combination with the structures, methods, and the like described in the other embodiments.

### Embodiment 2

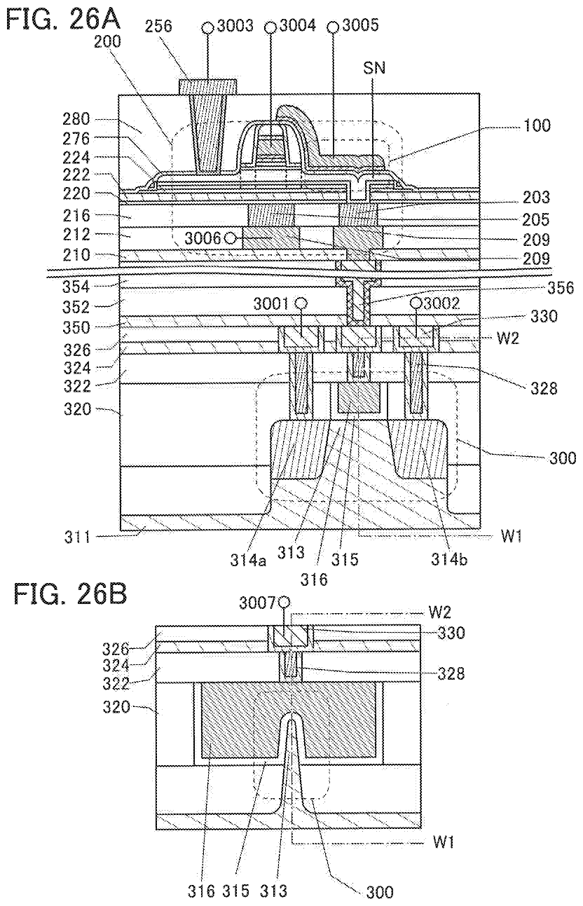

In this embodiment, embodiments of semiconductor devices will be described with reference to FIG. 26 to FIG. 29.

### [Memory Device 1]

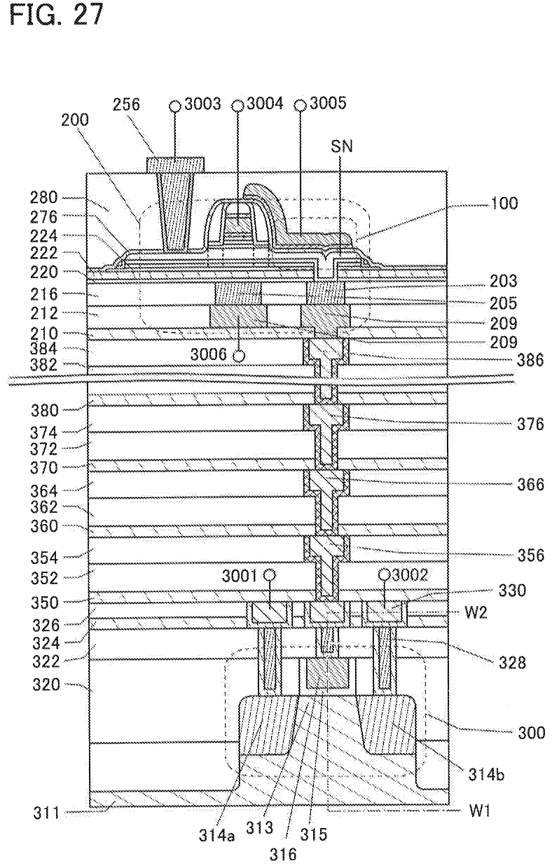

Memory devices illustrated in FIG. 26(A) and FIG. 27 each include the transistor 200, the capacitor 100, and the transistor 300.

The transistor 200 is a transistor in which a channel is formed in a semiconductor layer including an oxide semiconductor. Since the off-state current of the transistor 200 is small, a memory device using the transistor can retain stored contents for a long time. In other words, since refresh operation is not required or frequency of refresh operation is extremely low, the power consumption of the memory device can be sufficiently reduced.

The transistor 200 and the capacitor 100 illustrated in FIG. 26(A) and FIG. 27 have some components in common and thus have a small projected area, which enables miniaturization and high integration.

In the memory devices illustrated in FIG. 26(A) and FIG. 27, a wiring 3001 is electrically connected to a source of the transistor 300 and a wiring 3002 is electrically connected to a drain of the transistor 300. A wiring 3003 is electrically connected to one of the source and the drain of the transistor 200, a wiring 3004 is electrically connected to the first gate of the transistor 200, and a wiring 3006 is electrically connected to the second gate of the transistor 200. The other of the source and the drain of the transistor 200 functions as one electrode of the capacitor 100, and is electrically connected to the gate of the transistor 300 through an opening formed in the insulator 220, the insulator 222, the insulator 224, and the oxide 230a. A wiring 3005 is electrically connected to the other electrode of the capacitor 100.

The memory devices illustrated in FIG. 26(A) and FIG. 27 have a feature that the potential of the gate of the transistor 300 can be retained, and thus enable writing, retaining, and reading of data as described below.

Writing and retaining of data are described. First, the potential of the fourth wiring 3004 is set to a potential at which the transistor 200 is brought into a conduction state, so that the transistor 200 is brought into a conduction state. Accordingly, the potential of the third wiring 3003 is supplied to a node SN where the gate of the transistor 300 and one electrode of the capacitor 100 are electrically connected to each other. That is, a predetermined charge is supplied to the gate of the transistor 300 (writing). Here, one of charges providing two different potential levels (hereinafter referred to as a Low-level charge and a High-level charge) is supplied. After that, the potential of the fourth wiring 3004 is set to a potential at which the transistor 200 is brought into a non-conduction state, so that the transistor 200 is brought into a non-conduction state; thus, the charge is retained in the node SN (retaining).

In the case where the off-state current of the transistor 200 is low, the charge of the node SN is retained for a long time.

Next, reading of data is described. An appropriate potential (reading potential) is supplied to the fifth wiring 3005 in a state where a predetermined potential (constant potential) is supplied to the first wiring 3001, whereby the second wiring 3002 has a potential corresponding to the amount of charge retained in the node SN. This is because when the transistor 300 is of an n-channel type, an apparent threshold voltage V_{th_H} at the time when the High-level charge is supplied to the gate of the transistor 300 is lower than an apparent threshold voltage V_{th_L} at the time when the Low-level charge is supplied to the gate of the transistor 300. Here, an apparent threshold voltage refers to the potential of the fifth wiring 3005 which is needed to bring the transistor 300 into a “conduction state”. Thus, the potential of the fifth wiring 3005 is set to a potential V₀ which is between V_{th_H} and V_{th_L}, whereby the charge supplied to the node SN can be determined. For example, in the case where a High-level charge is supplied to the node SN in writing, when the potential of the fifth wiring 3005 is V₀ (>V_{th_H}), the transistor 300 is brought into a “conduction state”. Meanwhile, in the case where a Low-level charge is supplied to the node SN, the transistor 300 remains in a “non-conduction state” even when the potential of the fifth wiring 3005 is V₀ (<V_{th_L}). Thus, the data retained in the node SN can be read by determining the potential of the second wiring 3002.

### <Structure of Memory Device 1>

The memory device of one embodiment of the present invention includes the transistor 300, the transistor 200, and the capacitor 100 as illustrated in FIG. 26(A) and FIG. 27. The transistor 200 is provided above the transistor 300, and the capacitor 100 is provided in the same layer as the transistor 200.

The transistor 300 is provided over a substrate 311 and includes a conductor 316, an insulator 315, a semiconductor region 313 that is part of the substrate 311, and a low-resistance region 314a and a low-resistance region 314b functioning as a source region and a drain region.

The transistor 300 is of either a p-channel type or an n-channel type.

A region of the semiconductor region 313 where a channel is formed, a region in the vicinity thereof, the low-resistance region 314a and the low-resistance region 314b functioning as the source region and the drain region, and the like preferably contain a semiconductor such as a silicon-based semiconductor, and preferably contain single crystal silicon. Alternatively, the regions may be formed using a material containing Ge (germanium), SiGe (silicon germanium), GaAs (gallium arsenide), GaAlAs (gallium aluminum arsenide), or the like. A structure may be employed in which silicon whose effective mass is controlled by applying stress to the crystal lattice and thereby changing the lattice spacing is used. Alternatively, the transistor 300 may be a HEMT (High Electron Mobility Transistor) with the use of GaAs and GaAlAs, or the like.

The low-resistance region 314a and the low-resistance region 314b contain an element that imparts n-type conductivity, such as arsenic or phosphorus, or an element that imparts p-type conductivity, such as boron, in addition to a semiconductor material used for the semiconductor region 313.

The insulator 315 functions as a gate insulating film of the transistor 300.

For the conductor 316 functioning as a gate electrode, a semiconductor material such as silicon containing an element that imparts n-type conductivity, such as arsenic or phosphorus, or an element that imparts p-type conductivity, such as boron; or a conductive material such as a metal material, an alloy material, or a metal oxide material can be used.

Note that the work function is determined by a material for the conductor, whereby the threshold voltage can be adjusted by changing the material for the conductor. Specifically, it is preferable to use a material such as titanium nitride or tantalum nitride for the conductor. Moreover, in order to ensure both conductivity and embeddability, it is preferable to use a stacked layer of metal materials such as tungsten and aluminum as the conductor, and it is particularly preferable to use tungsten in terms of heat resistance.

Note that the transistor 300 illustrated in FIG. 26(A) and FIG. 27 is an example and the structure is not limited thereto; an appropriate transistor is used in accordance with a circuit configuration or a driving method.

Here, FIG. 26(B) shows a cross-sectional view of the transistor 300 in the W width direction indicated by W1-W2 in FIG. 26(A) and FIG. 27. As illustrated in FIG. 26(B), the transistor 300 has a convex shape in the semiconductor region 313 (part of the substrate 311) where a channel is formed. Furthermore, the conductor 316 is provided to cover the side surface and the top surface of the semiconductor region 313 with the insulator 315 therebetween. Note that for the conductor 316, a material that adjusts the work function may be used. Such a transistor 300 is also referred to as a FIN-type transistor because it utilizes a convex portion of the semiconductor substrate. Note that an insulator functioning as a mask for forming the convex portion may be included in contact with an upper portion of the convex portion. Furthermore, although the case where the convex portion is formed by processing part of the semiconductor substrate is described here, a semiconductor film having a convex shape may be formed by processing an SOI substrate.

An insulator 320, an insulator 322, an insulator 324, and an insulator 326 are provided to be stacked in this order to cover the transistor 300.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, or aluminum nitride is used, for example.

The insulator 322 may have a function of a planarization film for planarizing a level difference caused by the transistor 300 or the like provided thereunder. For example, the top surface of the insulator 322 may be planarized by planarization treatment using a chemical mechanical polishing (CMP) method or the like to improve planarity.

Furthermore, as the insulator 324, it is preferable to use a film having a barrier property that inhibits diffusion of hydrogen and impurities from the substrate 311, the transistor 300, or the like into a region where the transistor 200 is provided.

As an example of the film having a barrier property against hydrogen, silicon nitride formed by a CVD method can be used. Here, diffusion of hydrogen into a semiconductor element including an oxide semiconductor, such as the transistor 200, degrades the characteristics of the semiconductor element in some cases. Therefore, a film that inhibits diffusion of hydrogen is preferably used between the transistor 200 and the transistor 300. The film that inhibits diffusion of hydrogen is specifically a film from which a small amount of hydrogen is released.

The amount of released hydrogen can be analyzed by thermal desorption spectroscopy (TDS), for example. The amount of hydrogen released from the insulator 324 that is converted into hydrogen atoms per area of the insulator 324 is smaller than or equal to 10×10¹⁵ atoms/cm², preferably smaller than or equal to 5×10¹⁵ atoms/cm² in TDS analysis in a film-surface temperature range of 50° C. to 500° C., for example.

Note that the permittivity of the insulator 326 is preferably lower than that of the insulator 324. For example, the dielectric constant of the insulator 326 is preferably lower than 4, further preferably lower than 3. Furthermore, for example, the dielectric constant of the insulator 326 is preferably 0.7 times or less, further preferably 0.6 times or less the dielectric constant of the insulator 324. When a material with a low permittivity is used for an interlayer film, the parasitic capacitance generated between wirings can be reduced.

Furthermore, a conductor 328, a conductor 330, and the like that are electrically connected to the capacitor 100 or the transistor 200 are embedded in the insulator 320, the insulator 322, the insulator 324, and the insulator 326. Note that the conductor 328 and the conductor 330 function as plugs or wirings. In addition, a plurality of conductors functioning as plugs or wirings are collectively denoted by the same reference numeral in some cases. Furthermore, in this specification and the like, a wiring and a plug electrically connected to the wiring may be a single component. That is, there are a case where part of a conductor functions as a wiring and a case where part of a conductor functions as a plug.

As a material for each of plugs and wirings (the conductor 328, the conductor 330, and the like), a single layer or a stacked layer of a conductive material such as a metal material, an alloy material, a metal nitride material, or a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

The insulator 210, the insulator 212, and the insulator 216 are stacked in this order and provided above the insulator 354 and the conductor 356. A substance having a barrier property against oxygen and hydrogen is preferably used for one of the insulator 210, the insulator 212, and the insulator 216.

As the insulator 210, the insulator 212, and the insulator 216, for example, it is preferable to use a film having a barrier property that inhibits diffusion of hydrogen and impurities from the substrate 311 or a region where the transistor 300 is provided into the region where the transistor 200 is provided. Therefore, a material similar to that for the insulator 324 can be used.

Furthermore, as an example of the film having a barrier property against hydrogen, silicon nitride formed by a CVD method can be used. Here, diffusion of hydrogen into a semiconductor element including an oxide semiconductor, such as the transistor 200, degrades the characteristics of the semiconductor element in some cases. Therefore, a film that inhibits diffusion of hydrogen is preferably used between the transistor 200 and the transistor 300. The film that inhibits diffusion of hydrogen is specifically a film from which a small amount of hydrogen is released.

For the film having a barrier property against hydrogen used for the insulator 210, the insulator 212, and the insulator 216, a metal oxide such as aluminum oxide, hafnium oxide, or tantalum oxide is preferably used, for example.

In particular, aluminum oxide has an excellent blocking effect that inhibits the passage of both oxygen and impurities such as hydrogen and moisture which are factors of a change in electrical characteristics of the transistor. Accordingly, aluminum oxide can prevent entry of impurities such as hydrogen and moisture into the transistor 200 in a fabrication process and after the fabrication of the transistor. Furthermore, release of oxygen from the oxide included in the transistor 200 can be inhibited. Thus, aluminum oxide is suitably used as a protective film for the transistor 200.

Furthermore, for example, a material similar to that for the insulator 320 can be used for the insulator 212 and the insulator 216. Furthermore, when a material with a relatively low permittivity is used for an interlayer film, the parasitic capacitance generated between wirings can be reduced. As the insulator 212 and the insulator 216, a silicon oxide film or a silicon oxynitride film can be used, for example.

The conductor 209, the conductor 203, the conductor 205, and the like, which are conductors included in the transistor 200, are embedded in the insulator 210, the insulator 212, and the insulator 216. Note that the conductor 203 and the conductor 209 each have a function of a plug or a wiring that electrically connects the transistor 200 and the transistor 300. The conductor 209, the conductor 203, and the conductor 205 can be provided using a material similar to those for the conductor 328 and the conductor 330.

In particular, the conductor 209 in a region in contact with the insulator 210 and the insulator 212 is preferably a conductor having a barrier property against oxygen, hydrogen, and water. With this structure, the transistor 300 and the transistor 200 can be separated from each other by a layer having a barrier property against oxygen, hydrogen, and water, so that the diffusion of hydrogen from the transistor 300 into the transistor 200 can be inhibited.

The transistor 200 and the capacitor 100 are provided above the insulator 212. Note that the structures of the transistor 200 and the capacitor 100 described in the above embodiment can be used as the structures of the transistor 200 and the capacitor 100. The transistor 200 and the capacitor 100 illustrated in FIG. 26(A) are examples and the structures are not limited thereto; an appropriate transistor and capacitor are used in accordance with a circuit configuration and a driving method.

A wiring layer may be provided over the insulator 326 and the conductor 330. For example, in FIG. 27, an insulator 350, an insulator 352, and an insulator 354 are stacked in this order. Furthermore, a conductor 356 is formed in the insulator 350, the insulator 352, and the insulator 354. The conductor 356 functions as a plug or a wiring. Note that the conductor 356 can be provided using a material similar to those for the conductor 328 and the conductor 330.

Note that for example, as the insulator 350, an insulator having a barrier property against hydrogen is preferably used, as with the insulator 324. Furthermore, the conductor 356 preferably includes a conductor having a barrier property against hydrogen. Specifically, the conductor having a barrier property against hydrogen is formed in an opening portion included in the insulator 350 having a barrier property against hydrogen. With this structure, the transistor 300 and the transistor 200 can be separated from each other by a barrier layer, so that the diffusion of hydrogen from the transistor 300 into the transistor 200 can be inhibited.

Note that as the conductor having a barrier property against hydrogen, tantalum nitride is preferably used, for example. Furthermore, by stacking tantalum nitride and tungsten, which has high conductivity, the diffusion of hydrogen from the transistor 300 can be inhibited while the conductivity as a wiring is kept. In this case, a structure in which a tantalum nitride layer having a barrier property against hydrogen is in contact with the insulator 350 having a barrier property against hydrogen is preferable.

A wiring layer may be provided over the insulator 354 and the conductor 356. For example, in FIG. 27, an insulator 360, an insulator 362, and an insulator 364 are stacked in this order. Furthermore, a conductor 366 is formed in the insulator 360, the insulator 362, and the insulator 364. The conductor 366 functions as a plug or a wiring. Note that the conductor 366 can be provided using a material similar to those for the conductor 328 and the conductor 330.

Note that for example, as the insulator 360, an insulator having a barrier property against hydrogen is preferably used, as with the insulator 324. Furthermore, the conductor 366 preferably includes a conductor having a barrier property against hydrogen. Specifically, the conductor having a barrier property against hydrogen is formed in an opening portion included in the insulator 360 having a barrier property against hydrogen. With this structure, the transistor 300 and the transistor 200 can be separated from each other by a barrier layer, so that the diffusion of hydrogen from the transistor 300 into the transistor 200 can be inhibited.

A wiring layer may be provided over the insulator 364 and the conductor 366. For example, in FIG. 27, an insulator 370, an insulator 372, and an insulator 374 are stacked in this order. Furthermore, a conductor 376 is formed in the insulator 370, the insulator 372, and the insulator 374. The conductor 376 functions as a plug or a wiring. Note that the conductor 376 can be provided using a material similar to those for the conductor 328 and the conductor 330.

Note that for example, as the insulator 370, an insulator having a barrier property against hydrogen is preferably used, as with the insulator 324. Furthermore, the conductor 376 preferably includes a conductor having a barrier property against hydrogen. Specifically, the conductor having a barrier property against hydrogen is formed in an opening portion included in the insulator 370 having a barrier property against hydrogen. With this structure, the transistor 300 and the transistor 200 can be separated from each other by a barrier layer, so that the diffusion of hydrogen from the transistor 300 into the transistor 200 can be inhibited.

A wiring layer may be provided over the insulator 374 and the conductor 376. For example, in FIG. 27, an insulator 380, an insulator 382, and an insulator 384 are stacked in this order. Furthermore, a conductor 386 is formed in the insulator 380, the insulator 382, and the insulator 384. The conductor 386 functions as a plug or a wiring. Note that the conductor 386 can be provided using a material similar to those for the conductor 328 and the conductor 330.

Note that for example, as the insulator 380, an insulator having a barrier property against hydrogen is preferably used, as with the insulator 324. Furthermore, the conductor 386 preferably includes a conductor having a barrier property against hydrogen. Specifically, the conductor having a barrier property against hydrogen is formed in an opening portion included in the insulator 380 having a barrier property against hydrogen. With this structure, the transistor 300 and the transistor 200 can be separated from each other by a barrier layer, so that the diffusion of hydrogen from the transistor 300 into the transistor 200 can be inhibited.

The insulator 210, the insulator 212, and the insulator 216 are stacked in this order and provided over the insulator 384 and the conductor 386. A substance having a barrier property against oxygen and hydrogen is preferably used for one of the insulator 210, the insulator 212, and the insulator 216.

As the insulator 210, the insulator 212, and the insulator 216, for example, it is preferable to use a film having a barrier property that inhibits diffusion of hydrogen and impurities from the substrate 311 or a region where the transistor 300 is provided into the region where the transistor 200 is provided. Therefore, a material similar to that for the insulator 324 can be used.

As an example of the film having a barrier property against hydrogen, silicon nitride formed by a sputtering method or a CVD method can be used. Here, diffusion of hydrogen into a semiconductor element including an oxide semiconductor, such as the transistor 200, degrades the characteristics of the semiconductor element in some cases. Therefore, a film that inhibits diffusion of hydrogen is preferably used between the transistor 200 and the transistor 300. The film that inhibits diffusion of hydrogen is specifically a film from which a small amount of hydrogen is released.

For the film having a barrier property against hydrogen used for the insulator 210, the insulator 212, and the insulator 216, a metal oxide such as aluminum oxide, hafnium oxide, or tantalum oxide is preferably used, for example.

In particular, aluminum oxide has an excellent blocking effect that inhibits the passage of both oxygen and impurities such as hydrogen and moisture which are factors of a change in electrical characteristics of the transistor. Accordingly, aluminum oxide can prevent entry of impurities such as hydrogen and moisture into the transistor 200 in a fabrication process and after the fabrication of the transistor. Furthermore, release of oxygen from the oxide included in the transistor 200 can be inhibited. Thus, aluminum oxide is suitably used as a protective film for the transistor 200.

Furthermore, for example, a material similar to that for the insulator 320 can be used for the insulator 212 and the insulator 216. Furthermore, when a material with a relatively low permittivity is used for an interlayer film, the parasitic capacitance generated between wirings can be reduced. As the insulator 212 and the insulator 216, a silicon oxide film or a silicon oxynitride film can be used, for example.

The conductor 209, the conductor 203, the conductor 205, and the like, which are conductors included in the transistor 200, are embedded in the insulator 210, the insulator 212, and the insulator 216. Note that the conductor 203 and the conductor 209 each have a function of a plug or a wiring that electrically connects the transistor 200 and the transistor 300. The conductor 209, the conductor 203, and the conductor 205 can be provided using a material similar to those for the conductor 328 and the conductor 330.

In particular, the conductor 209 in a region in contact with the insulator 210 and the insulator 212 is preferably a conductor having a barrier property against oxygen, hydrogen, and water. With this structure, the transistor 300 and the transistor 200 can be separated from each other by a layer having a barrier property against oxygen, hydrogen, and water, so that the diffusion of hydrogen from the transistor 300 into the transistor 200 can be inhibited.

The transistor 200 and the capacitor 100 are provided above the insulator 212. Note that the structures of the transistor 200 and the capacitor 100 described in the above embodiment can be used as the structures of the transistor 200 and the capacitor 100. The transistor 200 and the capacitor 100 illustrated in FIG. 27 are examples and the structures are not limited thereto; an appropriate transistor and capacitor are used in accordance with a circuit configuration and a driving method.

Here, FIG. 27 illustrates an example in which the gate of the transistor 300 and the other of the source and the drain of the transistor 200 are electrically connected to each other through the four conductors: the conductor 356, the conductor 366, the conductor 376, and the conductor 386; however, this embodiment is not limited thereto. A conductor provided between the gate of the transistor 300 and the other of the source and the drain of the transistor 200 may be only the conductor 356, or two, three, or five or more conductors may be provided. Alternatively, the conductor 330 electrically connected to the gate of the transistor 300 and the conductor 209 electrically connected to the other of the source and the drain of the transistor 200 may be directly connected to each other.

The above is the description of the structure example. With the use of this structure, a change in electrical characteristics can be reduced and reliability can be improved in a semiconductor device using a transistor including an oxide semiconductor. Alternatively, a transistor including an oxide semiconductor and having a large on-state current can be provided. Alternatively, a transistor including an oxide semiconductor and having a small off-state current can be provided. Alternatively, a semiconductor device with reduced power consumption can be provided.

### Modification Example 1 of Memory Device 1

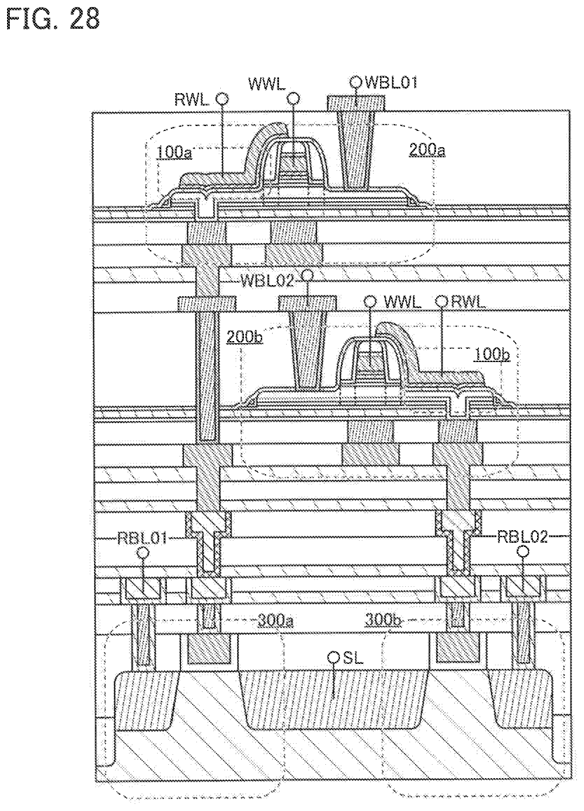

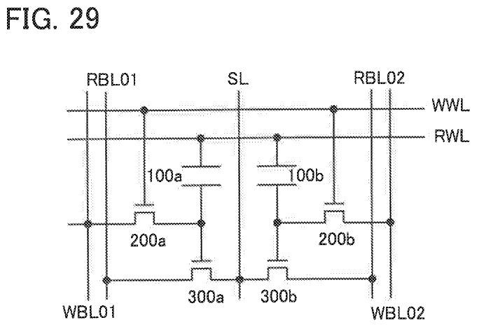

A modification example of this embodiment is illustrated in FIG. 28 and FIG. 29

When the memory devices illustrated in FIG. 28 are integrated as memory cells, a memory cell array can be formed. For example, in a circuit diagram shown in FIG. 29, a plurality of memory devices are provided so that memory cells are arranged in a matrix. FIG. 28 is an example of a cross-sectional view of the memory cell array in the case where the transistors 200 are integrated in the memory device illustrated in FIG. 26.

FIG. 28 and FIG. 29 each illustrate a memory cell array that includes a memory device including a transistor 300a, a transistor 200a, and a capacitor 100a, and a memory device including a transistor 300b, a transistor 200b, and a capacitor 100b.

For example, as illustrated in FIG. 26, the transistor 200a and the transistor 200b can be provided to overlap with each other. In addition, an SL line shared by the transistor 300a and the transistor 300b can be provided. For example, when the low-resistance region 314a is provided as the SL line shared by the transistor 300a and the transistor 300b, a wiring and a plug need not to be formed, so that the process can be shortened. Furthermore, this structure enables a reduction in area, higher integration, and miniaturization of the semiconductor device.

The structure, method, and the like described above in this embodiment can be used in an appropriate combination with the structures, methods, and the like described in the other embodiments.

### Embodiment 3

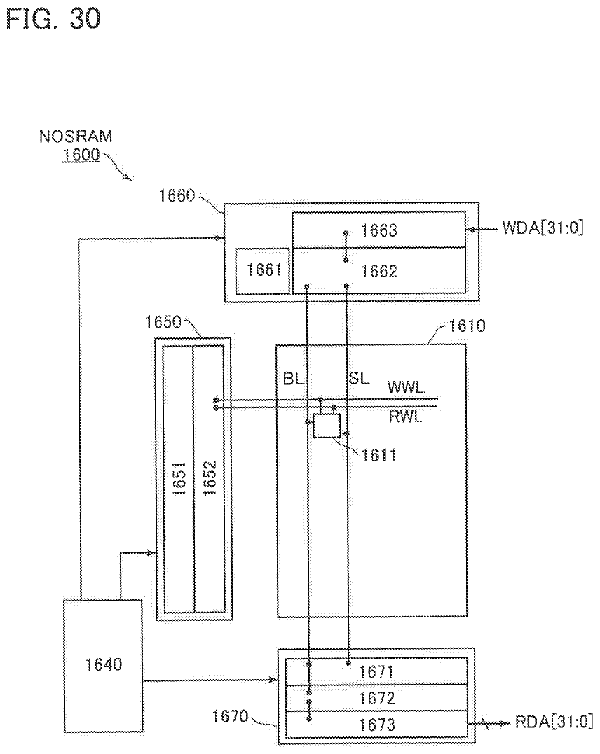

In this embodiment, a NOSRAM is described as an example of a memory device of one embodiment of the present invention, which includes a capacitor and a transistor using an oxide as a semiconductor (hereinafter referred to as an OS transistor) with reference to FIG. 30 to FIG. 33. A NOSRAM (registered trademark) is an abbreviation of “Nonvolatile Oxide Semiconductor RAM”, which indicates RAM including a gain cell (2T or 3T) memory cell. Note that hereinafter, a memory device using an OS transistor, such as the NOSRAM, is referred to as an OS memory in some cases.

A memory device in which OS transistors are used in memory cells (hereinafter referred to as an “OS memory”) is used in a NOSRAM. The OS memory is a memory including at least a capacitor and an OS transistor that controls charging and discharging of the capacitor. Since the OS transistor is a transistor with an extremely low off-state current, the OS memory has excellent retention characteristics and thus can function as a nonvolatile memory.

### <<NOSRAM>>

FIG. 30 illustrates a structure example of a NOSRAM. A NOSRAM 1600 illustrated in FIG. 30 includes a memory cell array 1610, a controller 1640, a row driver 1650, a column driver 1660, and an output driver 1670. Note that the NOSRAM 1600 is a multilevel NOSRAM in which one memory cell stores multilevel data.

The memory cell array 1610 includes a plurality of memory cells 1611, a plurality of word lines WWL and RWL, bit lines BL, and source lines SL. The word lines WWL are write word lines and the word lines RWL are read word lines. In the NOSRAM 1600, one memory cell 1611 stores 3-bit (8-level) data.

The controller 1640 controls the entire NOSRAM 1600 as a whole, and writes data WDA[31:0] and reads out data RDA[31:0]. The controller 1640 processes command signals from the outside (e.g., a chip enable signal and a write enable signal) to generate control signals for the row driver 1650, the column driver 1660, and the output driver 1670.

The row driver 1650 has a function of selecting a row to be accessed. The row driver 1650 includes a row decoder 1651 and a word line driver 1652.

The column driver 1660 drives the source lines SL and the bit lines BL. The column driver 1660 includes a column decoder 1661, a write driver 1662, and a DAC (digital-analog converter circuit) 1663.

The DAC 1663 converts 3-bit digital data into an analog voltage. The DAC 1663 converts 32-bit data WDA[31:0] into an analog voltage per 3 bits.

The write driver 1662 has a function of precharging the source lines SL, a function of bringing the source lines SL into an electrically floating state, a function of selecting a source line SL, a function of inputting a writing voltage generated by the DAC 1663 to the selected source line SL, a function of precharging the bit line BL, a function of bringing the bit lines BL into an electrically floating state, and the like.

The output driver 1670 includes a selector 1671, an ADC (analog-digital converter circuit) 1672, and an output buffer 1673. The selector 1671 selects a source line SL to be accessed and transmits the voltage of the selected source line SL to the ADC 1672. The ADC 1672 has a function of converting an analog voltage into 3-bit digital data. The voltage of the source line SL is converted into 3-bit data in the ADC 1672, and the output buffer 1673 retains data output from the ADC 1672.

Note that the configuration of the row driver 1650, the column driver 1660, and the output driver 1670 described in this embodiment is not limited to the above. The arrangement of those drivers and wirings connected to the drivers may be changed or the functions of the drivers and the wirings connected to the drivers may be changed or added, depending on the configuration, driving method, or the like of the memory cell array 1610. For example, a configuration may be employed in which the bit lines BL have part of the function of the source lines SL.

Although the amount of data retained in each of the memory cells 1611 is 3 bits in the above description, the structure of the memory device of this embodiment is not limited thereto. The amount of data retained in each of the memory cells 1611 may be 2 bits or less or 4 bits or more. In the case where the amount of data retained in each of the memory cells 1611 is one bit, for example, a structure may be employed in which the DAC 1663 and the ADC 1672 are not provided.

### <Memory Cell>

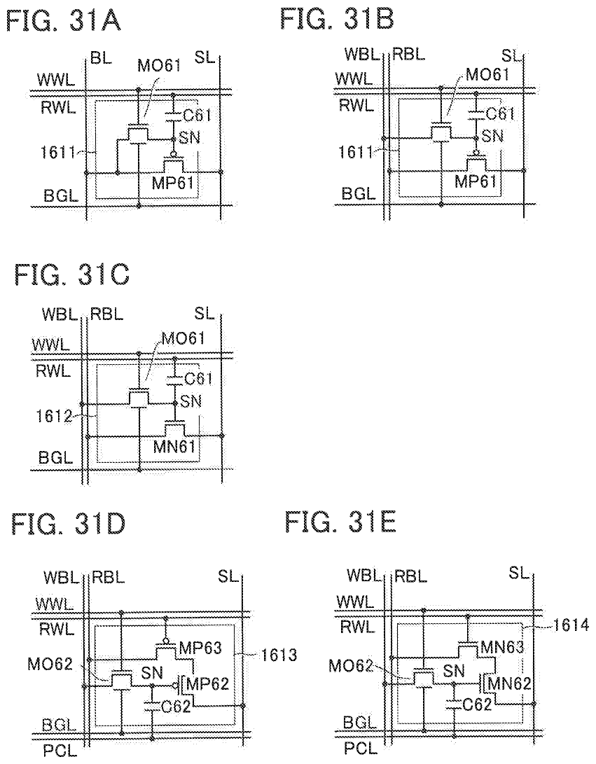

FIG. 31(A) is a circuit diagram showing a structure example of the memory cell 1611. The memory cell 1611 is a 2T gain cell, and the memory cell 1611 is electrically connected to the word lines WWL and RWL, the bit line BL, the source line SL, and a wiring BGL. The memory cell 1611 includes a node SN, an OS transistor MO61, a transistor MP61, and a capacitor C61. The OS transistor MO61 is a write transistor. The transistor MP61 is a read transistor and is formed using a p-channel Si transistor, for example. The capacitor C61 is a storage capacitor for retaining the voltage of the node SN. The node SN is a data storage node and corresponds to a gate of the transistor MP61 here.

The write transistor of the memory cell 1611 is formed using the OS transistor MO61; thus, the NOSRAM 1600 can retain data for a long time.

In the example of FIG. 31(A), the bit line BL is a common bit line for writing and reading; however, as illustrated in FIG. 31(B), a bit line WBL functioning as a write bit line and a bit line RBL functioning as a read bit line may be provided.

FIG. 31(C) to FIG. 31(E) illustrate other structure examples of the memory cell. FIG. 31(C) to FIG. 31(E) illustrate examples where the bit line WBL for writing and the bit line RBL for reading are provided; however, as in FIG. 31(A), a bit line shared in writing and reading may be provided.

A memory cell 1612 illustrated in FIG. 31(C) is a modification example of the memory cell 1611 where the read transistor is changed into an n-channel transistor (MN61). The transistor MN61 may be an OS transistor or a Si transistor.

In the memory cell 1611 and the memory cell 1612, the OS transistor MO61 may be an OS transistor with no back gate.

A memory cell 1613 illustrated in FIG. 31(D) is a 3T gain cell and is electrically connected to the word lines WWL and RWL, the bit lines WBL and RBL, the source line SL, and wirings BGL and PCL. The memory cell 1613 includes the node SN, an OS transistor MO62, a transistor MP62, a transistor MP63, and a capacitor C62. The OS transistor MO62 is a write transistor. The transistor MP62 is a read transistor and the transistor MP63 is a selection transistor.

A memory cell 1614 illustrated in FIG. 31(E) is a modification example of the memory cell 1613 where the read transistor and the selection transistor are changed into n-channel transistors (MN62 and MN63). The transistors MN62 and MN63 may be OS transistors or Si transistors.

The OS transistors MO62 in the memory cell 1613 and the memory cell 1614 may each be an OS transistor with no back gate.

The transistor MP61, the transistor MN61, the transistor MP62, the transistor MP63, the transistor MN62, and the transistor MN63 provided in the memory cell 1611 to the memory cell 1614 may be transistors with no back gates or transistors with back gates.

What is called a NOR memory device in which the memory cells 1611 or the like are connected in parallel is described above, but the memory device of this embodiment is not limited thereto. For example, what is called a NAND memory device in which memory cells 1615 described below are connected in series may be provided.

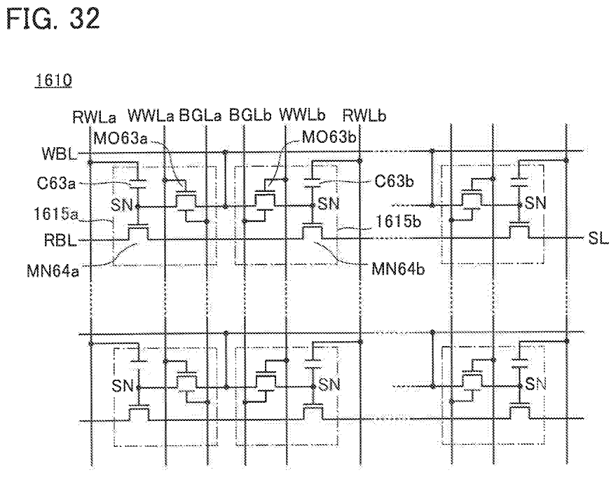

FIG. 32 is a circuit diagram showing a structure example of the NAND memory cell array 1610. The memory cell array 1610 illustrated in FIG. 32 includes the source line SL, the bit line RBL, the bit line WBL, the word line WWL, the word line RWL, the wiring BGL, and the memory cell 1615. The memory cell 1615 includes the node SN, an OS transistor MO63, a transistor MN64, and a capacitor C63. Here, the transistor MN64 is formed of an n-channel Si transistor, for example. The transistor MN64 is not limited thereto and may be a p-channel Si transistor or an OS transistor.

A memory cell 1615a and a memory cell 1615b illustrated in FIG. 32 are described below as examples. Here, the character “a” or “b” is added to the reference numerals of wirings and circuit elements connected to either the memory cell 1615a or the memory cell 1615b.

In the memory cell 1615a, a gate of a transistor MN64a, one of a source and a drain of a transistor MO63a, and one electrode of a capacitor C63a are electrically connected to one another. The bit line WBL and the other of the source and the drain of the transistor MO63a are electrically connected to each other. A word line WWLa and a gate of the transistor MO63a are electrically connected to each other. A wiring BGLa and a back gate of the transistor MO63a are electrically connected to each other. A word line RWLa and the other electrode of the capacitor C63a are electrically connected to each other.

The memory cell 1615b can be provided symmetric to the memory cell 1615a with a contact portion with the bit line WBL as a symmetric axis. Therefore, circuit elements included in the memory cell 1615b are connected to wirings as in the memory cell 1615a.

A source of the transistor MN64a included in the memory cell 1615a is electrically connected to a drain of a transistor MN64b of the memory cell 1615b. A drain of the transistor MN64a included in the memory cell 1615a is electrically connected to the bit line RBL. A source of the transistor MN64b included in the memory cell 1615b is electrically connected to the source line SL through the transistors MN64 included in the plurality of memory cells 1615. As described here, a plurality of transistors MN64 are connected in series between the bit line RBL and the source line SL in the NAND memory cell array 1610.

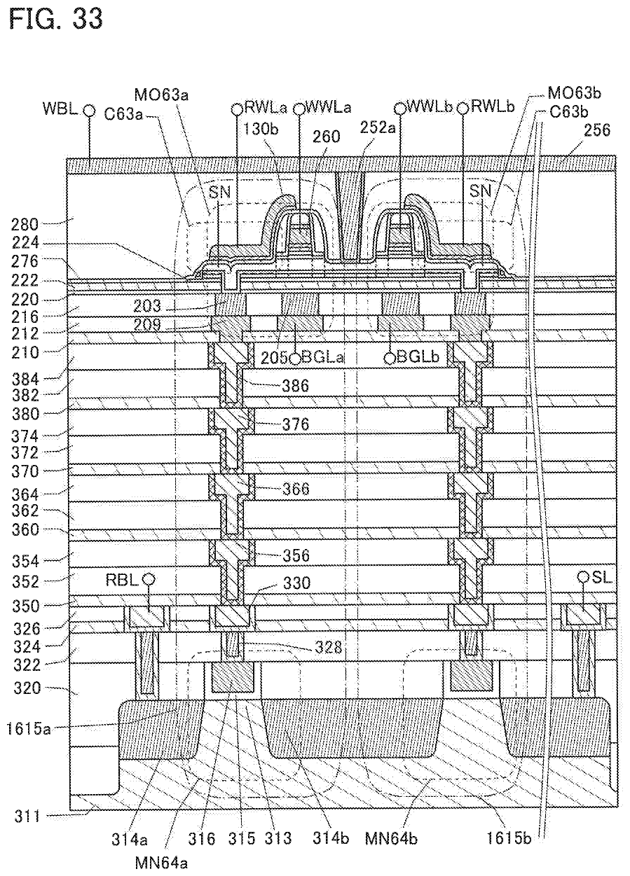

FIG. 33 illustrates a cross-sectional view corresponding to the memory cell 1615a and the memory cell 1615b. The memory cell 1615a and the memory cell 1615b have a structure similar to that of the memory device illustrated in FIG. 26. That is, the capacitor C63a and a capacitor C63b have structures similar to those of the capacitors 100, the OS transistor MO63a and an OS transistor MO63b have structures similar to those of the transistors 200, and the transistor MN64a and the transistor MN64b have structures similar to those of the transistors 300. Note that for components illustrated in FIG. 33 that are denoted by the same reference numerals as the components illustrated in FIG. 26, refer to the corresponding description.

In the memory cell 1615a, the conductor 130b is provided to extend and functions as the word line RWLa, the conductor 260 is provided to extend and functions as the word line WWLa, and a conductor 209 in contact with a bottom surface of the conductor 205 is provided to extend and functions as the wiring BGLa. A word line RWLb, a word line WWLb, and a wiring BGLb are provided similarly in the memory cell 1615b.

The low-resistance region 314b illustrated in FIG. 33 functions as the source of the transistor MN64a and the drain of the transistor MN64b. The low-resistance region 314a functioning as the drain of the transistor MN64a is electrically connected to the bit line RBL through the conductor 328 and the conductor 330. The source of the transistor MN64b is electrically connected to the source line SL through the transistors MN64 included in the plurality of memory cells 1615, the conductor 328, and the conductor 330.

A conductor 256 is provided to extend and functions as the bit line WBL. The conductor 252a functions as the contact portion with the word line WBL and is shared by the transistor MO63a and the transistor MO63b. When the contact portion with the bit line WBL is shared by the memory cell 1615a and the memory cell 1615b as described above, the number of contact portions with the bit line WBL can be reduced and the area occupied by the memory cell 1615 in the top view can be reduced. Accordingly, the memory device of this embodiment can be further highly integrated and the storage capacity per unit area can be increased.

In a memory device including the memory cell array 1610 illustrated in FIG. 32, writing operation and reading operation are performed for each group of memory cells (hereinafter referred to as a memory cell column) connected to the same word line WWL (or the word line RWL). For example, the writing operation can be performed as follows. A potential at which the transistor MO63 is brought into an on state is applied to the word line WWL connected to a memory cell column on which writing is performed so that the transistors MO63 in the memory cell column on which writing is performed are brought into an on state. Accordingly, the potential of the bit line WBL is applied to the gates of the transistors MN64 and one electrodes of the capacitors C63 in the specified memory cell column, whereby a predetermined charge is applied to the gates. Thus, data can be written to the memory cells 1615 in the specified memory cell column.

For example, the reading operation can be performed as follows. First, a potential at which the transistor MN64 is brought into an on state is applied to the word lines RWL not connected to a memory cell column on which reading is performed regardless of a charge applied to the gates of the transistors MN64, so that the transistors MN64 not in the memory cell column on which reading is performed are brought into an on state. Then, a potential (reading potential) at which an on state or an off state of the transistor MN64 is selected is applied to the word line RWL connected to the memory cell column on which reading is performed in accordance with a charge of the gates of the transistors MN64. Then, a fixed potential is applied to the source line SL and a reading circuit connected to the bit line RBL is brought into an operation state. Here, a plurality of transistors MN64 between the source line SL and the bit line RBL are in an on state except the transistor in the memory cell column on which reading is performed; therefore, the conductance between the source line SL and the bit line RBL depends on the state (an on state or an off state) of the transistor MN64 in the memory cell column on which reading is performed. Since the conductance of the transistor varies depending on the charge of the gate of the transistor MN64 in the memory cell column on which reading is performed, the potential of the bit line RBL varies accordingly. By reading the potential of the bit line RBL with the reading circuit, data can be read from the memory cell 1615 in the specified memory cell column.

There is no limitation on the number of rewriting operations of the NOSRAM 1600 in principle because data is rewritten by charging and discharging of the capacitor C61, the capacitor C62, or the capacitor C63, and data can be written and read with low energy. Furthermore, since data can be retained for a long time, the refresh rate can be reduced.

In the case where the semiconductor device described in the above embodiment is used for the memory cells 1611, 1612, 1613, 1614, and 1615, the transistors 200 can be used as the OS transistors MO61, MO62, and MO63, the capacitors 100 can be used as the capacitors C61, C62, and C63, and the transistors 300 can be used as the transistors MP61, MP62, MP63, MN61, MN62, MN63, and MN64. Accordingly, the area occupied by one set consisting of a transistor and a capacitor in the top view can be reduced, so that the memory device of this embodiment can be further highly integrated. Thus, storage capacity per unit area of the memory device of this embodiment can be increased.

The structures described in this embodiment can be used in an appropriate combination with the structures described in the other embodiments.

### Embodiment 4

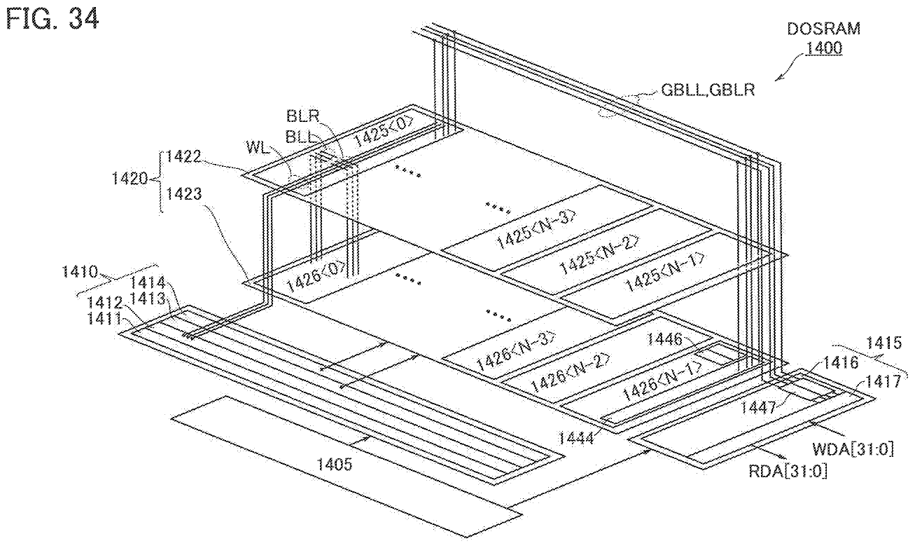

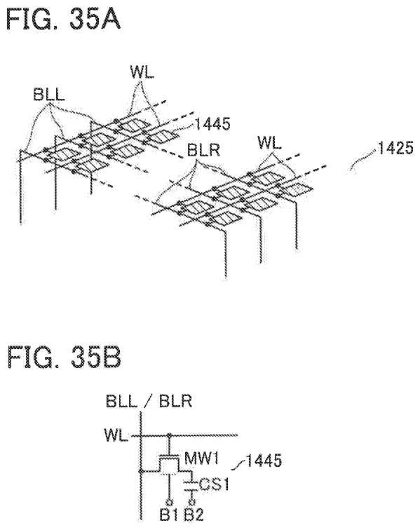

In this embodiment, a DOSRAM will be described as an example of the memory device of one embodiment of the present invention that includes an OS transistor and a capacitor, with reference to FIG. 34 and FIG. 35. A DOSRAM (registered trademark) is an abbreviation of “Dynamic Oxide Semiconductor RAM,” which is a RAM including a IT (transistor) 1C (capacitor) memory cell. As in the NOSRAM, an OS memory is used in the DOSRAM.

### <<DOSRAM 1400>>

FIG. 34 shows a configuration example of the DOSRAM. As shown in FIG. 34, a DOSRAM 1400 includes a controller 1405, a row circuit 1410, a column circuit 1415, and a memory cell and sense amplifier array 1420 (hereinafter referred to as an “MC-SA array 1420”).

The row circuit 1410 includes a decoder 1411, a word line driver circuit 1412, a column selector 1413, and a sense amplifier driver circuit 1414. The column circuit 1415 includes a global sense amplifier array 1416 and an input/output circuit 1417. The global sense amplifier array 1416 includes a plurality of global sense amplifiers 1447. The MC-SA array 1420 includes a memory cell array 1422, a sense amplifier array 1423, and global bit lines GBLL and GBLR.

### (MC-SA Array 1420)

The MC-SA array 1420 has a stacked-layer structure where the memory cell array 1422 is stacked over the sense amplifier array 1423. The global bit lines GBLL and GBLR are stacked over the memory cell array 1422. The DOSRAM 1400 adopts, as the bit-line structure, a hierarchical bit line structure hierarchized with local bit lines and global bit lines.

The memory cell array 1422 includes N local memory cell arrays 1425<0> to 1425<N−1>, where N is an integer greater than or equal to 2. FIG. 35(A) illustrates a configuration example of the local memory cell array 1425. The local memory cell array 1425 includes a plurality of memory cells 1445, a plurality of word lines WL, and a plurality of bit lines BLL and BLR. In the example of FIG. 35(A), the local memory cell array 1425 has an open bit-line architecture but may have a folded bit-line architecture.

FIG. 35(B) shows a circuit configuration example of the memory cell 1445. The memory cell 1445 includes a transistor MW1, a capacitor CS1, and terminals B1 and B2. The transistor MW1 has a function of controlling charging and discharging of the capacitor CS1. A gate of the transistor MW1 is electrically connected to the word line WL, a first terminal of the transistor MW1 is electrically connected to the bit line (BLL or BLR), and a second terminal of the transistor MW1 is electrically connected to a first terminal of the capacitor CS1. A second terminal of the capacitor CS1 is electrically connected to the terminal B2. A constant voltage (e.g., a low power supply voltage) is input to the terminal B2.

In the case where the semiconductor device described in any of the above embodiments is used in the memory cell 1445, the transistor 200 can be used as the transistor MW1, and the capacitor 100 can be used as the capacitor CS1. Thus, the area occupied by each set consisting of one transistor and one capacitor in the top view can be reduced, so that the memory device of this embodiment can be highly integrated. As a result, storage capacity per unit area of the memory device of this embodiment can be increased.

The transistor MW1 includes a back gate, and the back gate is electrically connected to the terminal B1. This makes it possible to change the threshold voltage of the transistor MW1 with a voltage of the terminal B1. For example, the voltage of the terminal B1 is a fixed voltage (e.g., a negative constant voltage); alternatively, the voltage of the terminal B1 may be changed in response to the operation of the DOSRAM 1400.

The back gate of the transistor MW1 may be electrically connected to the gate, the source, or the drain of the transistor MW1. Alternatively, the back gate is not necessarily provided in the transistor MW1.

The sense amplifier array 1423 includes N local sense amplifier arrays 1426<0> to 1426<N−1>. The local sense amplifier array 1426 includes one switch array 1444 and a plurality of sense amplifiers 1446. A bit line pair is electrically connected to the sense amplifier 1446. The sense amplifier 1446 has a function of precharging the bit line pair, a function of amplifying a voltage difference between the bit line pair, and a function of retaining the voltage difference. The switch array 1444 has a function of selecting a bit line pair and bringing the selected bit line pair and a global bit line pair into a conduction state.

Here, a bit line pair refers to two bit lines which are compared by a sense amplifier at the same time. A global bit line pair refers to two global bit lines which are compared by a global sense amplifier at the same time. The bit line pair can be referred to as a pair of bit lines, and the global bit line pair can be referred to as a pair of global bit lines. Here, the bit line BLL and the bit line BLR form one bit line pair. The global bit line GBLL and the global bit line GBLR form one global bit line pair. In the following description, the expressions “bit line pair (BLL, BLR)” and “global bit line pair (GBLL, GBLR)” are also used.

### (Controller 1405)

The controller 1405 has a function of controlling the overall operation of the DOSRAM 1400. The controller 1405 has a function of performing logic operation on a command signal that is input from the outside and determining an operation mode, a function of generating control signals for the row circuit 1410 and the column circuit 1415 so that the determined operation mode is executed, a function of retaining an address signal that is input from the outside, and a function of generating an internal address signal.

### (Row Circuit 1410)

The row circuit 1410 has a function of driving the MC-SA array 1420. The decoder 1411 has a function of decoding an address signal. The word line driver circuit 1412 generates a selection signal for selecting the word line WL of a row that is to be accessed. The column selector 1413 and the sense amplifier driver circuit 1414 are circuits for driving the sense amplifier array 1423. The column selector 1413 has a function of generating a selection signal for selecting the bit line of a column that is to be accessed. With the selection signal from the column selector 1413, the switch array 1444 of each local sense amplifier array 1426 is controlled. With the control signal from the sense amplifier driver circuit 1414, the plurality of local sense amplifier arrays 1426 are independently driven.

### (Column Circuit 1415)

The column circuit 1415 has a function of controlling the input of data signals WDA[31:0], and a function of controlling the output of data signals RDA[31:0]. The data signals WDA[31:0] are write data signals, and the data signals RDA[31:0] are read data signals.

The global sense amplifier 1447 is electrically connected to the global bit line pair (GBLL, GBLR). The global sense amplifier 1447 has a function of amplifying a voltage difference between the global bit line pair (GBLL, GBLR), and a function of retaining the voltage difference. Data is written to and read from the global bit line pair (GBLL, GBLR) by the input/output circuit 1417.

The write operation of the DOSRAM 1400 is briefly described. Data is written to the global bit line pair by the input/output circuit 1417. The data of the global bit line pair is retained by the global sense amplifier array 1416. By the switch array 1444 of the local sense amplifier array 1426 specified by an address, the data of the global bit line pair is written to the bit line pair of a target column. The local sense amplifier array 1426 amplifies the written data, and retains the amplified data. In the specified local memory cell array 1425, the word line WL of a target row is selected by the row circuit 1410, and the data retained at the local sense amplifier array 1426 is written to the memory cell 1445 of the selected row.

The read operation of the DOSRAM 1400 is briefly described. One row of the local memory cell array 1425 is specified by an address signal. In the specified local memory cell array 1425, the word line WL of a target row is in a selected state, and data of the memory cell 1445 is written to the bit line. The local sense amplifier array 1426 detects a voltage difference between the bit line pair of each column as data, and retains the data. Among the data retained at the local sense amplifier array 1426, the data of a column specified by the address is written to the global bit line pair by the switch array 1444. The global sense amplifier array 1416 determines and retains the data of the global bit line pair. The data retained in the global sense amplifier array 1416 is output to the input/output circuit 1417. Thus, the data reading operation is completed.

There is theoretically no limitation on the number of rewriting operations of the DOSRAM 1400 because data is rewritten by charging and discharging of the capacitor CS1; and data can be written and read with low energy. In addition, the memory cell 1445 has a simple circuit configuration, and thus the capacity can be easily increased.

The transistor MW1 is an OS transistor. The extremely low off-state current of the OS transistor can inhibit charge leakage from the capacitor CS1. Therefore, the retention time of the DOSRAM 1400 is much longer than that of a DRAM. This allows less frequent refresh, which can reduce the power needed for refresh operations. Thus, the DOSRAM 1400 is suitable for a memory device that rewrites a large volume of data with a high frequency, for example, a frame memory used for image processing.

Since the MC-SA array 1420 has a stacked-layer structure, the bit line can be shortened to a length that is close to the length of the local sense amplifier array 1426. A shorter bit line results in smaller bit line capacitance, which can reduce the storage capacitance of the memory cell 1445. In addition, providing the switch array 1444 in the local sense amplifier array 1426 can reduce the number of long bit lines. For the reasons described above, a driving load during access to the DOSRAM 1400 is reduced, enabling a reduction in power consumption.

The structure described in this embodiment can be used in an appropriate combination with the structures described in the other embodiments.

### Embodiment 5

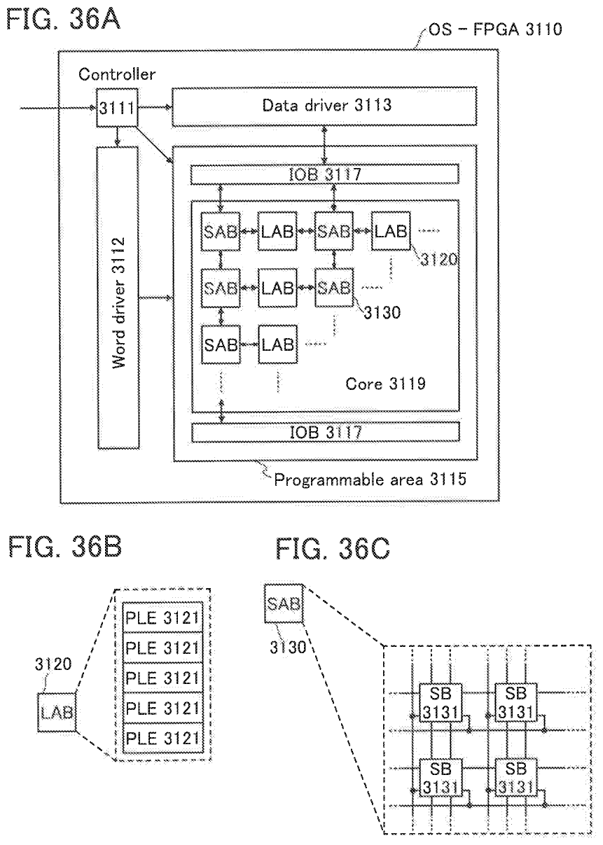

In this embodiment, an FPGA (field programmable gate array) is described as an example of a semiconductor device of one embodiment of the present invention in which an OS transistor and a capacitor are used, with reference to FIG. 36 to FIG. 39. In the FPGA of this embodiment, an OS memory is used for a configuration memory and a register. Here, such an FPGA is referred to as an “OS-FPGA”.

### <<OS-FPGA>>

FIG. 36(A) illustrates a configuration example of an OS-FPGA. An OS-FPGA 3110 illustrated in FIG. 36(A) is capable of context switching by a multi-context configuration, fine-grained power gating, and NOFF (normally-off) computing. The OS-FPGA 3110 includes a controller 3111, a word driver 3112, a data driver 3113, and a programmable area 3115.

The programmable area 3115 includes two input/output blocks (IOBs) 3117 and a core 3119. The IOB 3117 includes a plurality of programmable input/output circuits. The core 3119 includes a plurality of logic array blocks (LABs) 3120 and a plurality of switch array blocks (SABs) 3130. The LAB 3120 includes a plurality of PLEs 3121. FIG. 36(B) illustrates an example in which the LAB 3120 includes five PLEs 3121. As illustrated in FIG. 36(C), the SAB 3130 includes a plurality of switch blocks (SBs) 3131 arranged in an array. The LAB 3120 is connected to the LABs 3120 in four directions (on the left, right, top, and bottom sides) through its input terminals and the SABs 3130.

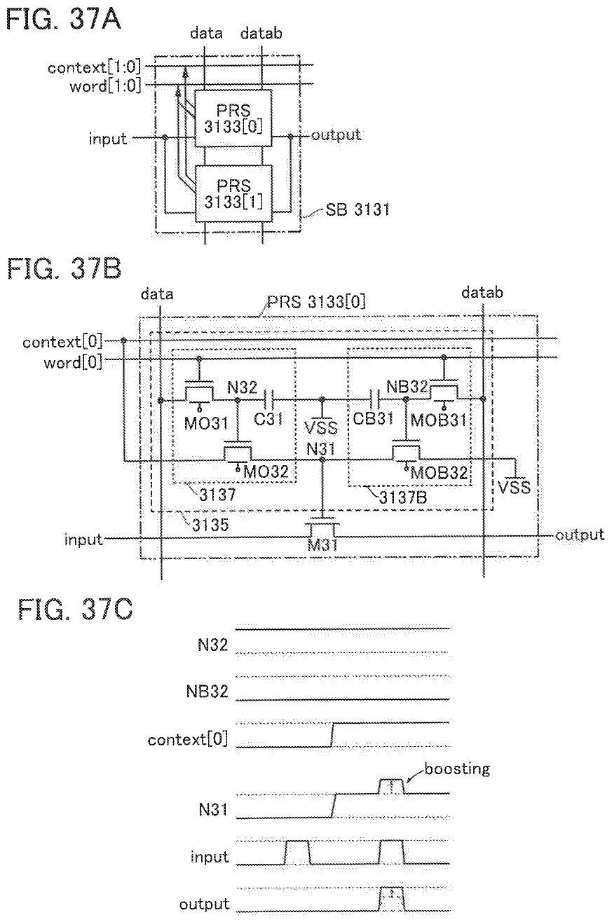

The SB 3131 is described with reference to FIG. 37(A) to FIG. 37(C). To the SB 3131 illustrated in FIG. 37(A), data, datab, and signals context[1:0] and word[1:0] are input. The data and the datab are configuration data, and the logics of the data and the datab have a complementary relationship. The number of contexts in the OS-FPGA 3110 is two, and the signals context[1:0] are context selection signals. The signals word[1:0] are word line selection signals, and wirings to which the signals word[1:0] are input are each a word line.

The SB 3131 includes PRSs (programmable routing switches) 3133[0] and 3133[1]. The PRSs 3133[0] and 3133[1] each include a configuration memory (CM) that can store complementary data. Note that in the case where the PRS 3133[0] and the PRS 3133[1] are not distinguished from each other, they are each referred to as a PRS 3133. The same applies to other elements.

FIG. 37(B) illustrates a circuit configuration example of the PRS 3133[0]. The PRS 3133[0] and the PRS 3133[1] have the same circuit configuration. The PRS 3133[0] and the PRS 3133[1] are different from each other in a context selection signal and a word line selection signal that are input. The signals context[0] and word[0] are input to the PRS 3133[0], and the signals context[1] and word[1] are input to the PRS 3133[1]. For example, in the SB 3131, when the signal context[0] is set to “H”, the PRS 3133[0] is activated.

The PRS 3133[0] includes a CM 3135 and a Si transistor M31. The Si transistor M31 is a pass transistor that is controlled by the CM 3135. The CM 3135 includes memory circuits 3137 and 3137B. The memory circuits 3137 and 3137B have the same circuit configuration. The memory circuit 3137 includes a capacitor C31 and OS transistors MO31 and MO32. The memory circuit 3137B includes a capacitor CB31 and OS transistors MOB31 and MOB32.

In the case where the semiconductor device described in any of the above embodiments is used in the SAB 3130, the transistor 200 can be used as the OS transistors MO31 and MOB31, and the capacitor 100 can be used as the capacitors C31 and CB31. Thus, the area occupied by each set consisting of one transistor and one capacitor in the top view can be reduced, so that the memory device of this embodiment can be highly integrated.

The OS transistors MO31, MO32, MOB31, and MOB32 each include a back gate, and each of these back gates are electrically connected to a power supply line that supplies a fixed voltage.

A gate of the Si transistor M31, a gate of the OS transistor MO32, and a gate of the OS transistor MOB32 correspond to a node N31, a node N32, and a node NB32, respectively. The node N32 and the node NB32 are each a charge retention node of the CM 3135. The OS transistor MO32 controls the conduction state between the node N31 and a signal line for the signal context[0]. The OS transistor MOB32 controls the conduction state between the node N31 and a low-potential power supply line VSS.

Data retained in the memory circuits 3137 and 3137B have a complementary relationship. Thus, either the OS transistor MO32 or the OS transistor MOB32 is turned on.

The operation example of the PRS 3133[0] is described with reference to FIG. 37(C). In the PRS 3133[0], to which configuration data has already been written, the node N32 is at “H”, whereas the node NB32 is at “L”.

The PRS 3133[0] is inactive while the signal context[0] is at “L”. During this period, even when an input terminal of the PRS 3133[0] is transferred to “H”, the gate of the Si transistor M31 is kept at “L” and an output terminal of the PRS 3133[0] is also kept at “L”.

The PRS 3133[0] is active while the signal context[0] is at “H”. When the signal context[0] is transferred to “H”, the gate of the Si transistor M31 is transferred to “H” by the configuration data stored in the CM 3135.

When the input terminal is transferred to “H” during a period in which the PRS 3133[0] is active, the gate voltage of the Si transistor M31 is increased by boosting because the OS transistor MO32 of the memory circuit 3137 is a source follower. As a result, the OS transistor MO32 of the memory circuit 3137 loses the driving capability, and the gate of the Si transistor M31 is brought into a floating state.

In the PRS 3133 with a multi-context function, the CM 3135 also has a function of a multiplexer.

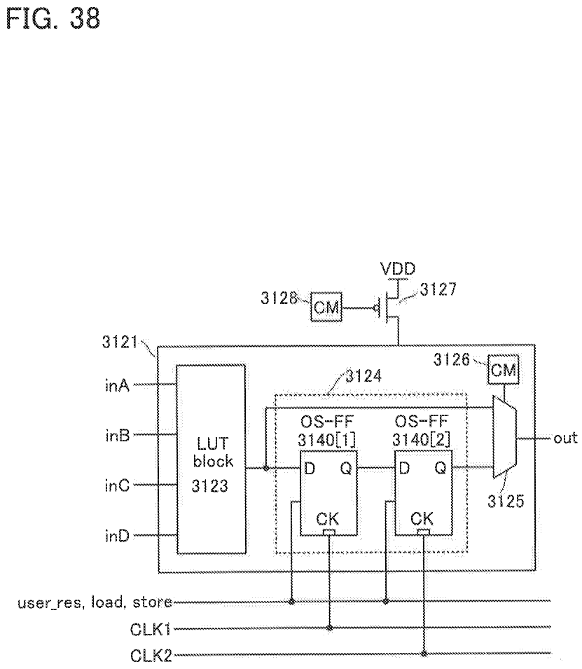

FIG. 38 illustrates a configuration example of the PLE 3121. The PLE 3121 includes an LUT (lookup table) block 3123, a register block 3124, a selector 3125, and a CM 3126. The LUT block 3123 is configured to multiplex an output of a pair of 16-bit CMs therein in accordance with inputs inA to inD. The selector 3125 selects an output of the LUT block 3123 or an output of the register block 3124 in accordance with the configuration stored in the CM 3126.

The PLE 3121 is electrically connected to a power supply line for a voltage VDD through a power switch 3127. Whether the power switch 3127 is turned on or off is determined in accordance with configuration data stored in a CM 3128. Providing the power switch 3127 for each PLE 3121 enables fine-grained power gating. The PLE 3121 that is not used after context switching can be power gated owing to the fine-grained power gating function; thus, standby power can be effectively reduced.

The register block 3124 is formed by nonvolatile registers to achieve NOFF computing. The nonvolatile registers in the PLE 3121 are each a flip-flop provided with an OS memory (hereinafter referred to as [OS-FF]).

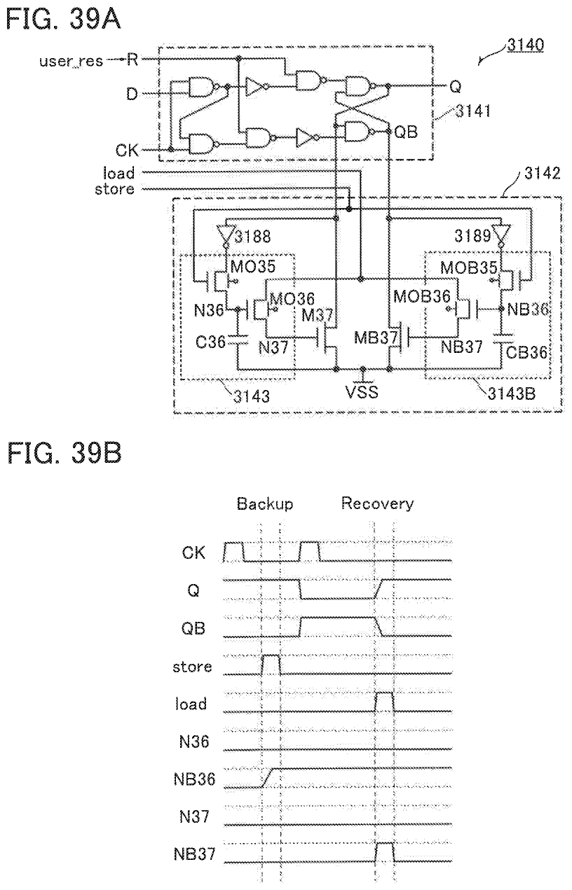

The register block 3124 includes OS-FFs 3140[1] and 3140[2]. Signals user_res, load, and store are input to the OS-FFs 3140[1] and 3140[2]. A clock signal CLK1 is input to the OS-FF 3140[1] and a clock signal CLK2 is input to the OS-FF 3140[2]. FIG. 39(A) illustrates a configuration example of the OS-FF 3140.

The OS-FF 3140 includes an FF 3141 and a shadow register 3142. The FF 3141 includes nodes CK, R, D, Q, and QB. A clock signal is input to the node CK. The signal user_res is input to the node R. The signal user_res is a reset signal. The node D is a data input node, and the node Q is a data output node. The logics of the node Q and the node QB have a complementary relationship.

The shadow register 3142 functions as a backup circuit of the FF 3141. The shadow register 3142 backs up data of the nodes Q and QB in response to the signal store and writes back the backed up data to the nodes Q and QB in response to the signal load.

The shadow register 3142 includes inverter circuits 3188 and 3189, Si transistors M37 and MB37, and memory circuits 3143 and 3143B. The memory circuits 3143 and 3143B each have the same circuit configuration as the memory circuit 3137 of the PRS 3133. The memory circuit 3143 includes a capacitor C36 and OS transistors MO35 and MO36. The memory circuit 3143B includes a capacitor CB36, an OS transistor MOB35, and an OS transistor MOB36. A node N36 and a node NB36 correspond to a gate of the OS transistor MO36 and a gate of the OS transistor MOB36, respectively, and are each a charge retention node. A node N37 and a node NB37 correspond to a gate of the Si transistor M37 and a gate of the Si transistor MB37, respectively.

In the case where the semiconductor device described in any of the above embodiments is used in the LAB 3120, the transistor 200 can be used as the OS transistors MO35 and MOB35, and the capacitor 100 can be used as the capacitors C36 and CB36. Thus, the area occupied by each set consisting of one transistor and one capacitor in the top view can be reduced, so that the memory device of this embodiment can be highly integrated.

The OS transistors MO35, MO36, MOB35, and MOB36 each include a back gate, and each of these back gates are electrically connected to a power supply line that supplies a fixed voltage.

An example of an operation method of the OS-FF 3140 is described with reference to FIG. 39(B).

### (Backup)

When the signal store at “H” is input to the OS-FF 3140, the shadow register 3142 backs up data of the FF 3141. The node N36 becomes “L” when the data of the node Q is written thereto, and the node NB36 becomes “H” when the data of the node QB is written thereto. After that, power gating is performed and the power switch 3127 is turned off. Although the data of the nodes Q and QB of the FF 3141 are lost, the shadow register 3142 retains the backed up data even when power supply is stopped.

### (Recovery)

The power switch 3127 is turned on to supply power to the PLE 3121. After that, when the signal load at “H” is input to the OS-FF 3140, the shadow register 3142 writes back the backed up data to the FF 3141. The node N37 is kept at “L” because the node N36 is at “L”, and the node NB37 becomes “H” because the node NB36 is at “H”. Thus, the node Q becomes “H” and the node QB becomes “L”. That is, the OS-FF 3140 is recovered to a state at the backup operation.

A combination of the fine-grained power gating and backup/recovery operation of the OS-FF 3140 allows power consumption of the OS-FPGA 3110 to be effectively reduced.

As an error that might occur in a memory circuit, a soft error due to the entry of radiation is given. The soft error is a phenomenon in which a malfunction such as inversion of data stored in a memory is caused by electron-hole pair generation when a transistor is irradiated with a rays emitted from a material of a memory or a package or the like, secondary cosmic ray neutrons generated by nuclear reaction of primary cosmic rays entering the Earth's atmosphere from outer space with nuclei of atoms existing in the atmosphere, or the like. An OS memory using an OS transistor has a high soft-error tolerance. Therefore, the OS-FPGA 3110 with high reliability can be provided when an OS memory is included therein.

The structure described in this embodiment can be used in an appropriate combination with the structures described in the other embodiments.

### Embodiment 6

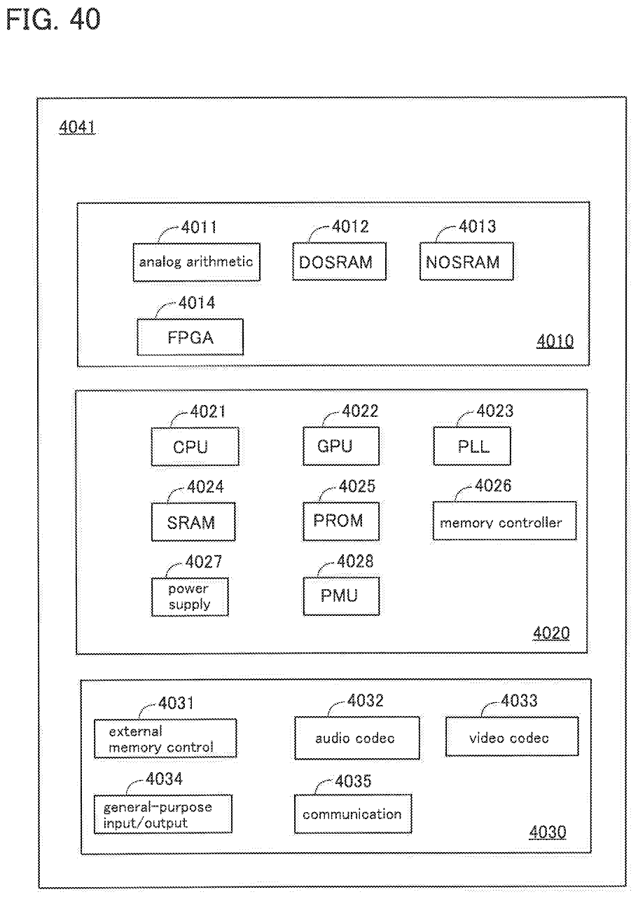

In this embodiment, an AI system in which the semiconductor device of any of the above embodiments is used is described with reference to FIG. 40.

FIG. 40 is a block diagram illustrating a structure example of an AI system 4041. The AI system 4041 includes an arithmetic portion 4010, a control portion 4020, and an input/output portion 4030.

The arithmetic portion 4010 includes an analog arithmetic circuit 4011, a DOSRAM 4012, a NOSRAM 4013, and an FPGA 4014. The DOSRAM 1400, the NOSRAM 1600, and the OS-FPGA 3110 described in the above embodiments can be used as the DOSRAM 4012, the NOSRAM 4013, and the FPGA 4014, respectively.

The control portion 4020 includes a CPU (Central Processing Unit) 4021, a GPU (Graphics Processing Unit) 4022, a PLL (Phase Locked Loop) 4023, an SRAM (Static Random Access Memory) 4024, a PROM (Programmable Read Only Memory) 4025, a memory controller 4026, a power supply circuit 4027, and a PMU (Power Management Unit) 4028.

The input/output portion 4030 includes an external memory control circuit 4031, an audio codec 4032, a video codec 4033, a general-purpose input/output module 4034, and a communication module 4035.

The arithmetic portion 4010 can execute learning or inference by a neural network.

The analog arithmetic circuit 4011 includes an A/D (analog/digital) converter circuit, a D/A (digital/analog) converter circuit, and a product-sum operation circuit.

The analog arithmetic circuit 4011 is preferably formed using an OS transistor. The analog arithmetic circuit 4011 using an OS transistor includes an analog memory and can execute a product-sum operation necessary for the learning or inference with low power consumption.

The DOSRAM 4012 is a DRAM formed using an OS transistor, and the DOSRAM 4012 is a memory that temporarily stores digital data sent from the CPU 4021. The DOSRAM 4012 includes a memory cell including an OS transistor and a read circuit portion including a Si transistor. Because the memory cell and the read circuit portion can be provided in different layers that are stacked, the entire circuit area of the DOSRAM 4012 can be small.

In the calculation with the neural network, the number of input data exceeds 1000 in some cases. In the case where the input data are stored in an SRAM, the input data have to be stored piece by piece because of the circuit area limitation and small storage capacity of the SRAM. The DOSRAM 4012 has a larger storage capacity than an SRAM because the memory cells can be highly integrated even in a limited circuit area. Therefore, the DOSRAM 4012 can efficiently store the input data.

The NOSRAM 4013 is a nonvolatile memory using an OS transistor. The NOSRAM 4013 consumes less power in writing data than the other nonvolatile memories such as a flash memory, a ReRAM (Resistive Random Access Memory), and an MRAM (Magnetoresistive Random Access Memory). Furthermore, unlike a flash memory and a ReRAM in which elements deteriorate by data writing, the NOSRAM has no limitation on the number of times of data writing.

Furthermore, the NOSRAM 4013 can store multilevel data of two or more bits as well as one-bit binary data. The multilevel data storage in the NOSRAM 4013 leads to a reduction in the memory cell area per bit.

Furthermore, the NOSRAM 4013 can store analog data as well as digital data. Thus, the analog arithmetic circuit 4011 can use the NOSRAM 4013 as an analog memory. The NOSRAM 4013 can store analog data as it is, and thus a D/A converter circuit and an A/D converter circuit are unnecessary. Therefore, with the use of the NOSRAM 4013, the area of the peripheral circuit can be reduced. In this specification, analog data refers to data having a resolution of three bits (eight levels) or more. The above-described multilevel data is included in the analog data in some cases.

Data and parameters used in the neural network calculation can be once stored in the NOSRAM 4013. The data and parameters may be stored in a memory provided outside the AI system 4041 via the CPU 4021; however, the NOSRAM 4013 provided inside the AI system 4041 can store the data and parameters more quickly with lower power consumption. Furthermore, the NOSRAM 4013 enables a longer bit line than the DOSRAM 4012 and thus can have an increased storage capacity.

The FPGA 4014 is an FPGA using an OS transistor. With the use of the FPGA 4014, the AI system 4041 can establish a connection of a neural network such as a deep neural network (DNN), a convolutional neural network (CNN), a recurrent neural network (RNN), an autoencoder, a deep Boltzmann machine (DBM), or a deep belief network (DBN) described later, with a hardware. Establishing the connection of the neural network with a hardware enables higher speed performance.

The FPGA 4014 is an FPGA including an OS transistor. An OS-FPGA can have a smaller memory area than an FPGA including an SRAM. Thus, addition of a context switching function only causes a small increase in area. Moreover, an OS-FPGA can transmit data and parameters at high speed by boosting.

In the AI system 4041, the analog arithmetic circuit 4011, the DOSRAM 4012, the NOSRAM 4013, and the FPGA 4014 can be provided on one die (chip). Thus, the AI system 4041 can execute calculation of the neural network quickly with low power consumption. In addition, the analog arithmetic circuit 4011, the DOSRAM 4012, the NOSRAM 4013, and the FPGA 4014 can be fabricated through the same manufacturing process. Therefore, the AI system 4041 can be fabricated at low cost.

Note that the arithmetic portion 4010 does not necessarily include all of the following: the DOSRAM 4012, the NOSRAM 4013, and the FPGA 4014. One or more memories selected from the DOSRAM 4012, the NOSRAM 4013, and the FPGA 4014 are provided in accordance with a problem that is desired to be solved by the AI system 4041.

The AI system 4041 can execute a method such as a deep neural network (DNN), a convolutional neural network (CNN), a recurrent neural network (RNN), an autoencoder, a deep Boltzmann machine (DBM), or a deep belief network (DBN) in accordance with the problem that is desired to be solved. The PROM 4025 can store a program for executing at least one of these methods. Furthermore, part or the whole of the program may be stored in the NOSRAM 4013.

Most of the existing programs used as libraries are premised on processing with a GPU. Therefore, the AI system 4041 preferably includes the GPU 4022. The AI system 4041 can execute the bottleneck product-sum operation among all the product-sum operations used for learning and inference in the arithmetic portion 4010, and execute the other product-sum operations in the GPU 4022. In this manner, the learning and inference can be executed at high speed.

The power supply circuit 4027 generates not only a low power supply potential for a logic circuit but also a potential for an analog operation. The power supply circuit 4027 may use an OS memory. When a reference potential is stored in the OS memory, the power consumption of the power supply circuit 4027 can be reduced.

The PMU 4028 has a function of temporarily stopping the power supply to the AI system 4041.

The CPU 4021 and the GPU 4022 preferably include OS memories as registers. By including the OS memories, the CPU 4021 and the GPU 4022 can retain data (logic values) in the OS memories even when power supply is stopped. As a result, the AI system 4041 can save the power.

The PLL 4023 has a function of generating a clock. The AI system 4041 performs an operation on the basis of the clock generated by the PLL 4023. The PLL 4023 preferably includes an OS memory. By including the OS memory, the PLL 4023 can retain an analog potential with which the clock oscillation frequency is controlled.

The AI system 4041 may store data in an external memory such as a DRAM. For this reason, the AI system 4041 preferably includes the memory controller 4026 functioning as an interface with the external DRAM. Furthermore, the memory controller 4026 is preferably positioned near the CPU 4021 or the GPU 4022. Thus, data transmission can be performed at high speed.

Some or all of the circuits illustrated in the control portion 4020 can be formed on the same die as the arithmetic portion 4010. Thus, the AI system 4041 can execute the neural network calculation at high speed with low power consumption.

Data used for the neural network calculation is stored in an external storage device (such as an HDD (Hard Disk Drive) or an SSD (Solid State Drive)) in many cases. Therefore, the AI system 4041 preferably includes the external memory control circuit 4031 functioning as an interface with the external storage device.

Because the neural network often deals with audio and video for learning and inference, the AI system 4041 includes the audio codec 4032 and the video codec 4033. The audio codec 4032 encodes and decodes audio data, and the video codec 4033 encodes and decodes video data.

The AI system 4041 can perform learning or inference using data obtained from an external sensor. For this reason, the AI system 4041 includes the general-purpose input/output module 4034. The general-purpose input/output module 4034 includes a USB (Universal Serial Bus) or an I2C (Inter-Integrated Circuit), for example.

The AI system 4041 can perform learning or inference using data obtained via the Internet. For this reason, the AI system 4041 preferably includes the communication module 4035.

The analog arithmetic circuit 4011 may use a multi-level flash memory as an analog memory. However, the flash memory has a limitation on the number of rewriting times. In addition, it is extremely difficult to embed the multi-level flash memory (to form the arithmetic circuit and the memory on the same die).

Alternatively, the analog arithmetic circuit 4011 may use a ReRAM as an analog memory. However, the ReRAM has a limitation on the number of rewriting times and also has a problem in storage accuracy. Moreover, the ReRAM is a two-terminal element, and thus has a complicated circuit design for separating data writing and data reading.

Further alternatively, the analog arithmetic circuit 4011 may use an MRAM as an analog memory. However, the MRAM has a problem in storage accuracy because of its low magnetoresistive ratio.

In consideration of the above, the analog arithmetic circuit 4011 preferably uses an OS memory as an analog memory.

The structure described in this embodiment can be used in appropriate combination with the structure described in the other embodiments.

### Embodiment 7

### Application Example of AI System

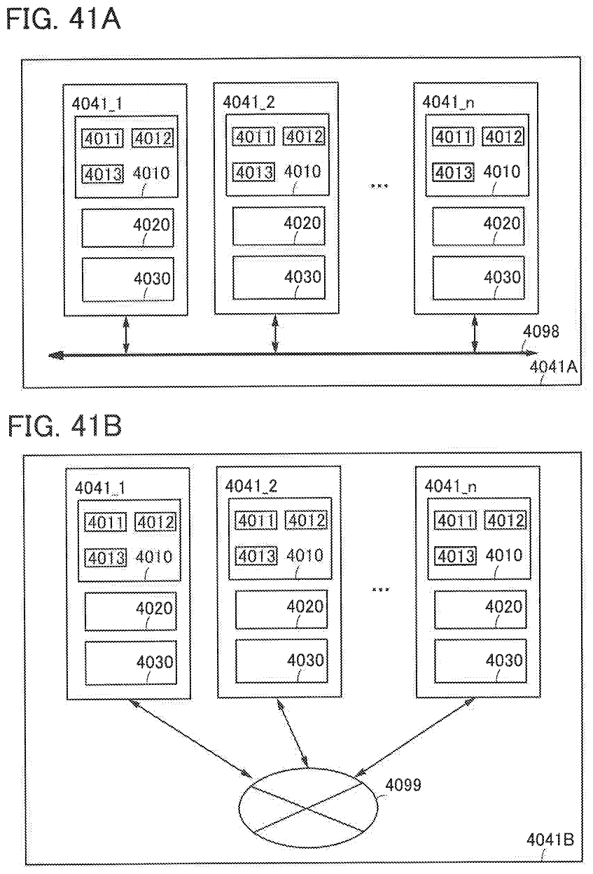

In this embodiment, application examples of the AI system described in the above embodiment will be described with reference to FIG. 41.

FIG. 41(A) illustrates an AI system 4041A in which the AI systems 4041 described with FIG. 40 are arranged in parallel and a signal can be transmitted between the systems via a bus line.

The AI system 4041A illustrated in FIG. 41(A) includes a plurality of AI systems 4041_1 to 4041_n (n is a natural number). The AI system 4041_1 to the AI system 4041_n are connected to each other via a bus line 4098.

FIG. 41(B) illustrates an AI system 4041B in which the AI systems 4041 described with FIG. 40 are arranged in parallel as in FIG. 41(A) and a signal can be transmitted between the systems via a network.

The AI system 4041B illustrated in FIG. 41(B) includes the plurality of AI systems 4041_1 to 4041_n. The AI system 4041_1 to the AI system 4041_n are connected to each other via a network 4099.

A communication module is provided in each of the AI system 4041_1 to the AI system 4041_n; such a configuration enables wireless or wired communication via the network 4099. A communication module can communicate via an antenna. Communication can be performed when an electronic device is connected to a computer network such as the Internet (infrastructure of the World Wide Web, WWW), an intranet, an extranet, a personal area network (PAN), a local area network (LAN), a campus area network (CAN), a metropolitan area network (MAN), a wide area network (WAN), or a global area network (GAN), for example. In the case of performing wireless communication, it is possible to use, as a communication protocol or a communication technology, a communications standard such as Long-Term Evolution (LTE), Global System for Mobile Communication (GSM: registered trademark), Enhanced Data Rates for GSM Evolution (EDGE), Code Division Multiple Access 2000 (CDMA2000), or W-CDMA (registered trademark), or a communications standard developed by IEEE such as Wi-Fi (registered trademark), Bluetooth (registered trademark), or ZigBee (registered trademark).

With the configuration illustrated in FIG. 41(A) or 41(B), analog signals obtained with external sensors or the like can be processed by different AI systems. For example, analog signals containing biological information such as brain waves, a pulse, blood pressure, and body temperature obtained with a variety of sensors such as a brain wave sensor, a pulse wave sensor, a blood pressure sensor, and a temperature sensor can be processed by different AI systems. Since each of the AI systems performs signal processing or learning, the amount of information processed by each AI system can be reduced. Accordingly, the signal processing or learning requires a smaller amount of arithmetic processing. As a result, recognition accuracy can be increased. With the use of data obtained with each AI system, biological information that irregularly changes should be able to be collectively grasped instantly.

The structure described in this embodiment can be used in appropriate combination with any of the other structures described in the other embodiments.

### Embodiment 8

In this embodiment, an example of an IC into which the AI system described in the above embodiment is incorporated is described.

In the AI system described in the above embodiment, a digital processing circuit such as a CPU that includes a Si transistor, an analog arithmetic circuit that uses an OS transistor, an OS-FPGA, and an OS memory such as a DOSRAM or a NOSRAM can be integrated into one die.

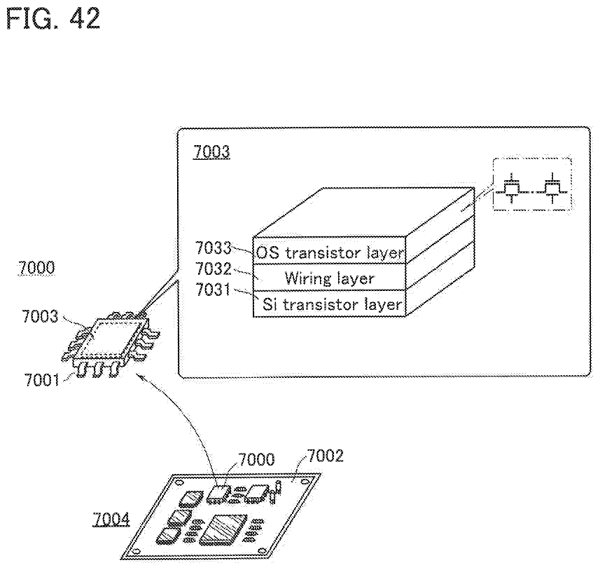

FIG. 42 illustrates the example of the IC into which the AI system is incorporated. An AI system IC 7000 illustrated in FIG. 42 includes a lead 7001 and a circuit portion 7003. The AI system IC 7000 is mounted on a printed circuit board 7002, for example. A plurality of such IC chips are combined and electrically connected to each other on the printed circuit board 7002; thus, a board on which electronic components are mounted (a circuit board 7004) is completed. In the circuit portion 7003, the various circuits described in the above embodiment are provided on one die. The circuit portion 7003 has a stacked-layer structure, which is broadly divided into a Si transistor layer 7031, a wiring layer 7032, and an OS transistor layer 7033. Since the OS transistor layer 7033 can be provided to be stacked over the Si transistor layer 7031, the size of the AI system IC 7000 can be easily reduced.

Although a QFP (Quad Flat Package) is used as a package of the AI system IC 7000 in FIG. 42, the embodiment of the package is not limited thereto.

The digital processing circuit such as a CPU, the analog arithmetic circuit that uses an OS transistor, the OS-FPGA, and the OS memory such as a DOSRAM or a NOSRAM can all be formed in the Si transistor layer 7031, the wiring layer 7032, and the OS transistor layer 7033. In other words, elements included in the AI system can be formed through the same manufacturing process. Thus, the number of steps in the manufacturing process of the IC described in this embodiment does not need to be increased even when the number of elements is increased, and accordingly the AI system can be incorporated into the IC at low cost.

The structure described in this embodiment can be used in an appropriate combination with the structures described in the other embodiments.

### Embodiment 9

### <Electronic Device>

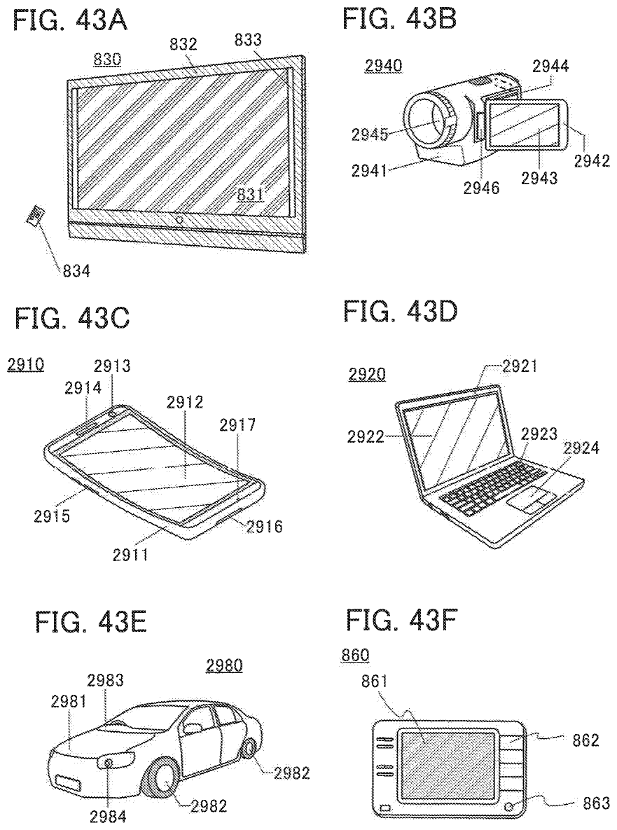

A semiconductor device of one embodiment of the present invention can be used for a variety of electronic devices. FIG. 43 illustrates specific examples of the electronic devices using the semiconductor device of one embodiment of the present invention.

FIG. 43(A) illustrates a monitor 830. The monitor 830 includes a display portion 831, a housing 832, a speaker 833, and the like. Furthermore, an LED lamp, operation keys (including a power switch or an operation switch), a connection terminal, a variety of sensors, a microphone, and the like can be included. The monitor 830 can be controlled with a remote controller 834.

The monitor 830 can function as a television device by receiving airwaves.

Examples of the airwaves the monitor 830 can receive include ground waves and waves transmitted from a satellite. The example of the airwaves also include analog broadcasting, digital broadcasting, image-sound-only broadcasting, and sound-only broadcasting. For example, airwaves transmitted in a certain frequency band in a UHF band (higher than or equal to 300 MHz and lower than or equal to 3 GHz) or a VHF band (higher than or equal to 30 MHz and lower than or equal to 300 MHz) can be received. When a plurality of pieces of data received in a plurality of frequency bands is used, the transfer rate can be increased and more information can be obtained. Accordingly, the display portion 831 can display an image with a resolution exceeding the full high definition. An image with a resolution of, for example, 4K2K, 8K4K, 16K8K, or more can be displayed.

A structure may be employed in which an image to be displayed on the display portion 831 is generated using broadcasting data transmitted with a technology for transmitting data via a computer network such as the Internet, a LAN (Local Area Network), or Wi-Fi (registered trademark). In this case, the monitor 830 does not need to include a tuner.

The monitor 830 can be used as a computer monitor when connected to a computer. Several people can see the monitor 830 connected to a computer at the same time; thus, the monitor 830 can be used for a conference system. The monitor 830 can also be used for a videoconference system by display of data in a computer via a network or connection of the monitor 830 itself to a network.

The monitor 830 can also be used as a digital signage.

The semiconductor device of one embodiment of the present invention can be used for, for example, a driver circuit or an image processing portion of the display portion. When the semiconductor device of one embodiment of the present invention is used for the driver circuit or the image processing portion of the display portion, high-speed operation or signal processing can be achieved with low power consumption.

When an AI system using the semiconductor device of one embodiment of the present invention is used for the image processing portion of the monitor 830, image processing such as noise removal processing, grayscale conversion processing, color tone correction processing, or luminance correction processing can be performed. Furthermore, pixel interpolation processing due to resolution up-conversion, frame interpolation processing due to frame frequency up-conversion, or the like can be performed. In the grayscale conversion processing, not only the number of grayscale levels of an image can be changed, but also interpolation of the gray value in the case of increasing the number of grayscale levels can be performed. In addition, high-dynamic range (HDR) processing for increasing a dynamic range is also included in the grayscale conversion processing.

A video camera 2940 illustrated in FIG. 43(B) includes a housing 2941, a housing 2942, a display portion 2943, operation switches 2944, a lens 2945, a joint 2946, and the like. The operation switches 2944 and the lens 2945 are provided on the housing 2941, and the display portion 2943 is provided on the housing 2942. The video camera 2940 also includes an antenna, a battery, and the like inside the housing 2941. A structure is employed in which the housing 2941 and the housing 2942 are connected to each other with the joint 2946, and the angle between the housing 2941 and the housing 2942 can be changed with the joint 2946. The orientation of an image displayed on the display portion 2943 may be changed and display and non-display of an image can be switched depending on the angle between the housing 2941 and the housing 2942.

The semiconductor device of one embodiment of the present invention can be used for, for example, a driver circuit or an image processing portion of the display portion. When the semiconductor device of one embodiment of the present invention is used for the driver circuit or the image processing portion of the display portion, high-speed operation or signal processing can be achieved with low power consumption.

When an AI system using the semiconductor device of one embodiment of the present invention is used for the image processing portion of the video camera 2940, imaging appropriate for the surroundings of the video camera 2940 can be achieved. Specifically, imaging can be performed with optimal exposure for the surrounding brightness. In the case of performing imaging with backlighting or imaging under different brightness conditions such as indoors and outdoors at the same time, high-dynamic-range (HDR) imaging can be performed.

Furthermore, the AI system can learn the user's habit and assist in performing imaging. Specifically, the AI system can learn the user's camera shaking habit and correct the camera shaking during imaging, so that blurring of the obtained image associated with camera shaking can be reduced as much as possible. In the case of using a zoom function during imaging, the orientation of the lens or the like can be controlled such that a subject is positioned at the center of an image all the time.

An information terminal 2910 illustrated in FIG. 43(C) includes a housing 2911, a display portion 2912, a microphone 2917, a speaker portion 2914, a camera 2913, an external connection portion 2916, operation switches 2915, and the like. A display panel and a touch screen that use a flexible substrate are provided in the display portion 2912. The information terminal 2910 also includes an antenna, a battery, and the like inside the housing 2911. The information terminal 2910 can be used as, for example, a smartphone, a mobile phone, a tablet information terminal, a tablet personal computer, or an e-book reader.

For example, a memory device using the semiconductor device of one embodiment of the present invention can retain control data, a control program, or the like of the information terminal 2910 for a long time.

When an AI system using the semiconductor device of one embodiment of the present invention is used for an image processing portion of the information terminal 2910, image processing such as noise removal processing, grayscale conversion processing, color tone correction processing, or luminance correction processing can be performed. Furthermore, pixel interpolation processing due to resolution up-conversion, frame interpolation processing due to frame frequency up-conversion, or the like can be performed. In the grayscale conversion processing, not only the number of grayscale levels of an image can be changed, but also interpolation of the gray value in the case of increasing the number of grayscale levels can be performed. In addition, high-dynamic range (HDR) processing for increasing a dynamic range is also included in the grayscale conversion processing.

Furthermore, the AI system can learn the user's habit and assist in operating the information terminal 2910. The information terminal 2910 into which the AI system is incorporated can predict touch input from the motion of the user's fingers, eyes, or the like.

A laptop personal computer 2920 illustrated in FIG. 43(D) includes a housing 2921, a display portion 2922, a keyboard 2923, a pointing device 2924, and the like. The laptop personal computer 2920 also includes an antenna, a battery, and the like inside the housing 2921.

For example, a memory device using the semiconductor device of one embodiment of the present invention can retain control data, a control program, or the like of the laptop personal computer 2920 for a long time.

When an AI system using the semiconductor device of one embodiment of the present invention is used for an image processing portion of the laptop personal computer 2920, image processing such as noise removal processing, grayscale conversion processing, color tone correction processing, or luminance correction processing can be performed. Furthermore, pixel interpolation processing due to resolution up-conversion, frame interpolation processing due to frame frequency up-conversion, or the like can be performed. In the grayscale conversion processing, not only the number of grayscale levels of an image can be changed, but also interpolation of the gray value in the case of increasing the number of grayscale levels can be performed. In addition, high-dynamic range (HDR) processing for increasing a dynamic range is also included in the grayscale conversion processing.

Furthermore, the AI system can learn the user's habit and assist in operating the laptop personal computer 2920. The laptop personal computer 2920 into which the AI system is incorporated can predict touch input to the display portion 2922, from the motion of the user's fingers, eyes, or the like. In inputting text, the AI system predicts input from the past input text data or a text or a diagram such as a photograph around the text, to assist conversion. Accordingly, input mistakes and conversion mistakes can be reduced as much as possible.

FIG. 43(E) is an external view illustrating an example of an automobile, and FIG. 43(F) illustrates a navigation device 860. An automobile 2980 includes a car body 2981, wheels 2982, a dashboard 2983, lights 2984, and the like. The automobile 2980 also includes an antenna, a battery, and the like. The navigation device 860 includes a display portion 861, operation buttons 862, and an external input terminal 863. The automobile 2980 and the navigation device 860 can be independent of each other; however, it is preferable that a structure be employed in which the navigation device 860 is incorporated into and liked to the automobile 2980.

For example, a memory device using the semiconductor device of one embodiment of the present invention can retain control data, a control program, or the like of the automobile 2980 or the navigation device 860 for a long time. When an AI system using the semiconductor device of one embodiment of the present invention is used for a control device or the like of the automobile 2980, the AI system can learn driver's driving skill and habit and assist in safe driving or driving involving efficient use of gasoline or a battery. To assist in safe driving, the AI system learns not only driver's driving skill and habit, but also learns the behavior of the automobile such as the speed and movement of the automobile 2980, road information saved in the navigation device 860, and the like complexly; thus, driving lane departure can be prevented and collision with other automobiles, pedestrians, objects, and the like can be prevented. Specifically, when there is a sharp curve in the traveling direction, the navigation device 860 transmits the road information to the automobile 2980 so that the speed of the automobile 2980 can be controlled and steering can be assisted.

This embodiment can be implemented in an appropriate combination with the structures described in the other embodiments, example, and the like.

### Example 1

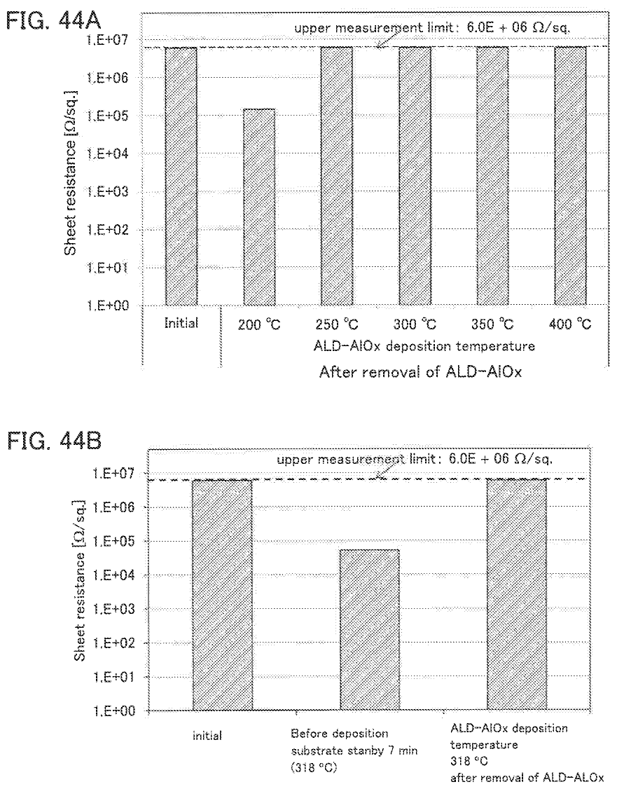

The insulating film or the insulator described in Embodiment 1 was deposited over an oxide by an ALD method, and a change in the sheet resistance of the oxide was evaluated. FIG. 44 shows the evaluation results.

By a sputtering method, a first oxide film with a thickness of 5 nm was formed over a quartz substrate using a target with In:Ga:Zn=1:3:4 [atomic ratio], and a second oxide film with a thickness of 15 nm was formed using a target with In:Ga:Zn=4:2:4.1 [atomic ratio]. Next, the formed oxide films were subjected to heat treatment at 400° C. in a nitrogen atmosphere for one hour and then successively subjected to another heat treatment at 400° C. in an oxygen atmosphere for one hour. After the heat treatment, a third oxide film with a thickness of 5 nm was formed over the second oxide film using a target with In:Ga:Zn=1:3:4 [atomic ratio]. In the above manner, an oxide including the first oxide film, the second oxide film, and the third oxide film was obtained.

The sheet resistance of the obtained oxide was measured. A sheet resistance measurer with a measurement upper limit of 6×10⁶ Ω/sq. was used. The measurement results exceeded the range, which showed that the sheet resistance of the oxide was higher than or equal to 6×10⁶ Ω/sq.

Next, aluminum oxide (AlOx) was formed over the oxide by an ALD method. For the deposition of the aluminum oxide, trimethylaluminum (TMA) was used as the first source gas. In addition, nitrogen was used as a carrier gas for the first source gas, and the flow rate thereof was 200 sccm. As the second source gas, ozone (O₃) and oxygen (O₂) were used. In addition, nitrogen was used as a carrier gas for the second source gas, and the flow rate thereof was 150 sccm. The introduction time (pulse) of the first source gas was 0.1 s, the purge time of the first source gas was 3 s, the introduction time (pulse) of the second source gas was 15 s, and the purge time of the second source gas was 3 s. At this time, the aluminum oxide was formed under five temperature conditions: 200° C. (the first condition), 250° C. (the second condition), 300° C. (the third condition), 350° C. (the fourth condition), and 400° C. (the fifth condition).

After the aluminum oxide was formed under the above five conditions, the aluminum oxide was removed by wet etching, and then the sheet resistance of the oxide was measured again. Under the condition where aluminum oxide was formed at 200° C., the sheet resistance of the oxide after the aluminum oxide was removed was 1.43×10⁵ Ω/sq., which showed that the sheet resistance of the oxide was reduced through the deposition of the aluminum oxide. In contrast, under the second condition to the fifth condition in which the aluminum oxide was formed at higher than or equal to 250° C., the sheet resistance of the oxide after the aluminum oxide was removed exceeded the range, which showed that the sheet resistance of the oxide was higher than or equal to 6×10⁶ Ω/sq. (see FIG. 44(A)).

Possible reasons for the reduction in the sheet resistance of the oxide by the formation of the aluminum oxide at 200° C. are as follows: hydrogen entered the oxide during the standby time from setting of a substrate in the deposition chamber to the deposition; oxygen was released from the oxide, which generated an oxygen vacancy; hydrogen entered the oxide during the deposition; or oxygen was not sufficiently added to the oxide during the deposition.

In contrast, the sheet resistance of the oxide remained over the measurement upper limit even when the aluminum oxide was formed at higher than or equal to 250° C.; this is probably because hydrogen in the oxide was released during the standby time from setting of the substrate in the deposition chamber to the deposition, or oxygen was sufficiently supplied to the oxide during the deposition.

FIG. 44(B) shows the measurement results of the sheet resistance of the oxide obtained in the following manner: at the deposition temperature of 318° C., the substrate was on standby from being set in the deposition chamber to just before the deposition, and then the substrate was taken out from the deposition chamber without performing deposition. The standby time of the substrate in the deposition chamber was approximately 7 min. The sheet resistance of the oxide at this time was 5.18×10⁴ Ω/sq. On the other hand, the substrate was on standby in the deposition chamber under a similar condition for 7 min, aluminum oxide was formed, and then the sheet resistance of the oxide was measured after the aluminum oxide was removed; thus, the sheet resistance of the oxide exceeded the range, higher than or equal to 6×10⁶ Ω/sq.

From the above, it was found that the resistance value of the oxide was reduced in the deposition chamber once, and then increased again through the deposition. As the reason for the temporal reduction in the resistance value of the oxide, one or both of the following can be considered: release of oxygen from the oxide to the air in the deposition chamber, which forms an oxygen vacancy, and entry of hydrogen to the oxide. As the reason for the increase in the resistance value of the oxide after the formation of the aluminum oxide, addition of oxygen to the oxide during the deposition can be considered. One or both of compensation for the oxygen vacancy in the oxide by the addition of oxygen and release of hydrogen from the oxide can be considered. Hydrogen in the oxide reacts with oxygen that is added during the deposition and is released from the oxide as water (H₂O) in some cases.

In the case where a film is formed over an oxide by an ALD method, the property of the oxide was found to be changed depending on the conditions. In particular, the sheet resistance of the oxide changes depending on the deposition temperature. For example, in the case where the region 231 or the region 232 to be a low-resistance region is formed in the oxide 230, deposition is performed under the first condition with a low deposition temperature, which is described in this example. For example, in the case where the resistance of part of the oxide 230 is reduced by the formation of the insulating film 272A to be the insulator 272, the first condition is preferably employed. In contrast, in the case where the resistance of the oxide 230 is not reduced by the formation of the insulating film 272A but the resistance of part of the oxide 230 is reduced by the formation of the insulator 274, the insulating film 272A is preferably formed under any of the second condition to the fifth condition with a high deposition temperature. In formation of the insulating film or the insulator that can be used for the present invention, the deposition conditions can be appropriately selected in accordance with requirement for a device or process.

### Example 2

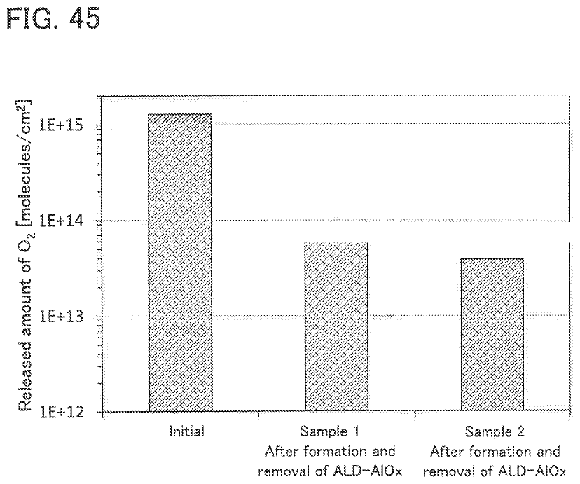

Next, the oxygen barrier property of the insulator formed by an ALD method, which was described in Embodiment 1, was evaluated. FIG. 45 shows the evaluation results.

An oxide film with a thickness of 5 nm was formed over a silicon substrate by a sputtering method using a target with In:Ga:Zn=1:3:4 [atomic ratio], and a silicon oxynitride film with a thickness of 10 nm was formed thereover by a CVD method. In order to supply oxygen to the silicon oxynitride film, aluminum oxide with a thickness of 5 nm was formed by a sputtering method using a target of Al₂O₃.

Next, the aluminum oxide formed by a sputtering method was removed by wet etching to expose the silicon oxynitride film, and then the amount of oxygen contained in the silicon oxynitride film was measured. The amount of oxygen was measured by TDS (Thermal Desorption Spectroscopy) analysis, and the amount of oxygen released from the silicon oxynitride film was measured. The amount of oxygen released from the silicon oxynitride film at this time was 1.28×10¹⁵ molecules/cm².

Next, an evaluation sample was formed and the oxygen barrier property of the insulator formed by an ALD method was evaluated. In a similar manner to the above, as Sample 1, an oxide film with a thickness of 5 nm was formed over a silicon substrate by a sputtering method using a target with In:Ga:Zn=1:3:4 [atomic ratio], and a silicon oxynitride film with a thickness of 10 nm was formed thereover by a CVD method. In order to supply oxygen to the silicon oxynitride film, aluminum oxide with a thickness of 5 nm was formed by a sputtering method using a target of Al₂O₃.

Next, the aluminum oxide formed by a sputtering method was removed by wet etching to expose the silicon oxynitride film. Another aluminum oxide was formed over the exposed silicon oxynitride film by an ALD method. As an apparatus for forming the aluminum oxide, an ALD deposition apparatus including a carrying-in/out chamber and a transfer chamber in addition to a deposition chamber was used. The carrying-in/out chamber and the transfer chamber of the ALD deposition apparatus are filled with an inert gas such as nitrogen, and can maintain a reduced-pressure atmosphere. For the deposition of the aluminum oxide, trimethylaluminum (TMA) was used as the first source gas. In addition, nitrogen was used as a carrier gas for the first source gas, and the flow rate thereof was 200 sccm. As the second source gas, ozone (O₃) and oxygen (O₂) were used. In addition, nitrogen was used as a carrier gas for the second source gas, and the flow rate thereof was 150 sccm. The introduction time (pulse) of the first source gas was 0.1 s, the purge time of the first source gas was 3 s, the introduction time (pulse) of the second source gas was 15 s, and the purge time of the second source gas was 3 s. At this time, the formation temperature of the aluminum oxide was 201° C.

In a manner similar to the above, the aluminum oxide formed by an ALD method was removed by wet etching to expose the silicon oxynitride film, and then the amount of oxygen contained in the silicon oxynitride film was measured by TDS analysis. The amount of oxygen released from the silicon oxynitride film at this time was 5.89×10¹³ molecules/cm².

Next, an insulator was formed as Sample 2 with an ALD deposition apparatus that does not include a carrying-in/out chamber and a transfer chamber, and the oxygen barrier property thereof was evaluated. The deposition chamber was opened to the air, and a substrate was directly set in the deposition chamber. After the substrate was set in the deposition chamber, the deposition chamber was vacuum-evacuated, and a heater was set to 250° C. After the heater reached 250° C., the substrate was held so that the substrate temperature became uniform in the substrate surface. After that, ozone (O₃) and oxygen (O₂) were introduced into the deposition chamber, so that the deposition chamber was in an oxygen atmosphere. In addition, nitrogen was used as a carrier gas and the flow rate thereof was 20 sccm. Ozone, oxygen, and the carrier gas were introduced in a pulsed form. For the deposition of the insulating film, trimethylaluminum (TMA) was used as the first source gas. In addition, nitrogen was used as a carrier gas for the first source gas, and the flow rate thereof was 20 sccm. As the second source gas, ozone (O₃) and oxygen (O₂) were used. In addition, nitrogen was used as a carrier gas for the second source gas, and the flow rate thereof was 20 sccm. The introduction time (pulse) of the first source gas was 0.03 s, the purge time of the first source gas was 15 s, the introduction time (pulse) of the second source gas was 0.10 s, and the purge time of the second source gas was 20 s.

In a manner similar to the above, the formed aluminum oxide was removed by wet etching to expose the silicon oxynitride film, and then the amount of oxygen contained in the silicon oxynitride film was measured by TDS analysis. The amount of oxygen released from the silicon oxynitride film at this time was 3.88×10¹³ molecules/cm². Thus, it was found that an insulator formed with an ALD deposition apparatus that includes a carrying-in/out chamber and a transfer chamber had higher oxygen barrier property.

### Example 3

A transistor was fabricated by an ALD method described in this embodiment and evaluated. The transistor used for the evaluation is different from the transistor 200 illustrated in FIG. 1 in that the conductor 209 and the insulator 273 are not provided.

The conductor 205 was formed by a damascene method to have a stacked-layer structure of tantalum nitride, titanium nitride, and tungsten. As the insulator 220, silicon oxynitride with a thickness of 10 nm was formed by a CVD method. As the insulator 222, hafnium oxide with a thickness of 20 nm was formed by an ALD method. As the insulator 224, silicon oxynitride with a thickness of 30 nm was formed by a CVD method. As the oxide 230a, an oxide with a thickness of 5 nm was formed by a sputtering method using a target with In:Ga:Zn=1:3:4 [atomic ratio]. As the oxide 230b, an oxide with a thickness of 15 nm was formed by a sputtering method using a target with In:Ga:Zn=4:2:4.1 [atomic ratio]. As the oxide 230c, an oxide with a thickness of 5 nm was formed by a sputtering method using a target with In:Ga:Zn=1:3:4 [atomic ratio]. As the insulator 250a, silicon oxynitride with a thickness of 10 nm was formed by a CVD method. As the insulator 250b, aluminum oxide with a thickness of 5 nm was formed by a sputtering method. As the conductor 260, titanium nitride with a thickness of 10 nm and tungsten with a thickness of 30 nm were successively formed by a sputtering method. As the insulator 270, aluminum oxide with a thickness of 7 nm was formed by an ALD method. As the insulator 271, silicon oxynitride was formed by a CVD method. As the insulator 272, aluminum oxide with a thickness of 5 nm was formed by an ALD method. As the insulator 274, silicon nitride with a thickness of 20 nm was formed by a CVD method.

For the deposition of the aluminum oxide used as the insulator 272, trimethylaluminum (TMA) was used as the first source gas. In addition, nitrogen was used as a carrier gas for the first source gas, and the flow rate thereof was 200 sccm. As the second source gas, ozone (O₃) and oxygen (O₂) were used. In addition, nitrogen was used as a carrier gas for the second source gas, and the flow rate thereof was 150 sccm. The introduction time (pulse) of the first source gas was 0.1 s, the purge time of the first source gas was 3 s, the introduction time (pulse) of the second source gas was 15 s, and the purge time of the second source gas was 3 s. At this time, the formation temperature of the aluminum oxide was 201° C.

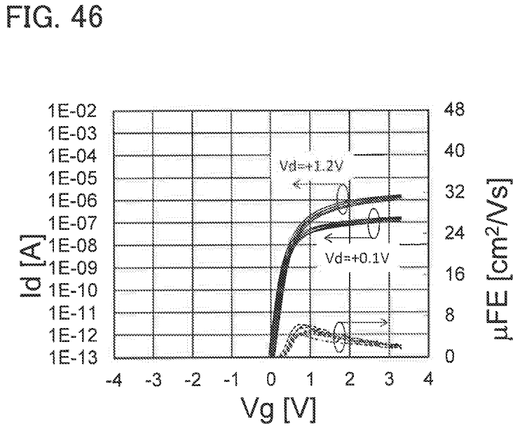

As the electrical characteristics of the transistor fabricated in the above manner, FIG. 46 shows the I_{d}−V_{g} characteristics. The channel length (L) of the transistor whose electrical characteristics were measured was 0.33 μm, the channel width (W) was 0.16 μm, and the density that can be obtained from the number of transistors provided per unit area was 0.23/μm². A transistor with favorable characteristics in which on/off was switched at V_{g} of around 0 V was obtained.

### REFERENCE NUMERALS

100 capacitor
100a capacitor
100b capacitor
130 conductor
130a conductor
130A conductive film
130b conductor
130B conductive film
200 transistor
200a transistor
200b transistor
201 transistor
203 conductor
205 conductor
207 conductor
208 insulator
209 conductor
210 insulator
212 insulator
214 insulator
216 insulator
220 insulator
222 insulator
222a insulator
222b insulator
222c insulator
224 insulator
230 oxide
230a oxide
230A oxide film
230b oxide
230B oxide film
230c oxide
230C oxide film
230d oxide
231 region
231a region
231b region
232 region
232a region
232b region
234 region
239 region
250 insulator
250a insulator
250A insulating film
250b insulator
250B insulating film
252 conductor
252a conductor
252b conductor
252c conductor
252d conductor
256 conductor
260 conductor
260a conductor
260A conductive film
260b conductor
260B conductive film
270 insulator
270A insulating film
271 insulator
271A insulating film
272 insulator
272A insulating film
273 insulator
273A insulating film
274 insulator
276 insulator
276a insulator
276b insulator
276c insulator
280 insulator
300 transistor
300a transistor
300b transistor
311 substrate
313 semiconductor region
314a low-resistance region
314b low-resistance region
315 insulator
316 conductor
320 insulator
322 insulator
324 insulator
326 insulator
328 conductor
330 conductor
350 insulator
352 insulator
354 insulator
356 conductor
360 insulator
362 insulator
364 insulator
366 conductor
370 insulator
372 insulator
374 insulator
376 conductor
380 insulator
382 insulator
384 insulator
386 conductor
400 transistor
403 conductor
405 conductor
409 conductor
430 oxide
430a oxide
430b oxide
430c oxide
430d oxide
450 insulator
450a insulator
450b insulator
452a conductor
452b conductor
460 conductor
460a conductor
460b conductor
470 insulator
471 insulator
472 insulator
473 insulator
600 cell
600a cell
600b cell
620 circuit
640 circuit
830 monitor
831 display portion
832 housing
833 speaker
834 remote controller
860 navigation device
861 display portion
862 operation button
863 external input terminal
1000 deposition apparatus
1002 carrying-in/out chamber
1004 carrying-in/out chamber
1006 transfer chamber
1008 deposition chamber
1009 deposition chamber
1010 deposition chamber
1014 transfer arm
1020 chamber
1021a source material supply portion
1021b source material supply portion
1022a high-speed valve
1022b high-speed valve
1023a source material introduction port
1023b source material introduction port
1024 source material exhaust port
1025 evacuation unit
1026 substrate holder
1027 heater
1028 plasma generation apparatus
1029 coil
1030 substrate
1400 DOSRAM
1405 controller
1410 row circuit
1411 decoder
1412 word line driver circuit
1413 column selector
1414 sense amplifier driver circuit
1415 column circuit
1416 global sense amplifier array
1417 input/output circuit
1420 sense amplifier array
1422 memory cell array
1423 sense amplifier array
1425 local memory cell array
1426 local sense amplifier array
1444 switch array
1445 memory cell
1446 sense amplifier
1447 global sense amplifier
1600 NOSRAM
1610 memory cell array
1611 memory cell
1612 memory cell
1613 memory cell
1614 memory cell
1615 memory cell
1615a memory cell
1615b memory cell
1640 controller
1650 row driver
1651 row decoder
1652 word line driver
1660 column driver
1661 column decoder
1662 driver
1663 DAC
1670 output driver
1671 selector
1672 ADC
1673 output buffer
2000 CDMA
2910 information terminal
2911 housing
2912 display portion
2913 camera
2914 speaker portion
2915 operation switch
2916 external connection portion
2917 microphone
2920 laptop personal computer
2921 housing
2922 display portion
2923 keyboard
2924 pointing device
2940 video camera
2941 housing
2942 housing
2943 display portion
2944 operation switch
2945 lens
2946 joint
2980 automobile
2981 car body
2982 wheel
2983 dashboard
2984 light
3001 wiring
3002 wiring
3003 wiring
3004 wiring
3005 wiring
3006 wiring
3110 OS-FPGA
3111 controller
3112 word driver
3113 data driver
3115 programmable area
3117 IOB
3119 core
3120 LAB
3121 PLE
3123 LUT block
3124 register block
3125 selector
3126 CM
3127 power switch
3128 CM
3130 SAB
3131 SB
3133 PRS
3135 CM
3137 memory circuit
3137B memory circuit
3140 OS-FF
3141 FF
3142 shadow register
3143 memory circuit
3143B memory circuit
3188 inverter circuit
3189 inverter circuit
4010 arithmetic portion
4011 analog arithmetic circuit
4012 DOSRAM
4013 NOSRAM
4014 FPGA
4020 control circuit
4021 CPU
4022 GPU
4023 PLL
4025 PROM
4026 memory controller
4027 power supply circuit
4028 PMU
4030 input/output portion
4031 external memory control circuit
4032 audio codec
4033 video codec
4034 general-purpose input/output module
4035 communication module
4041 AI system
4041_n AI system
4041_1 AI system
4041A AI system
4041B AI system
4098 bus line
4099 network
7000 AI system IC
7001 lead
7003 circuit portion
7031 Si transistor layer
7032 wiring layer
7033 OS transistor layer

1. A method for fabricating a semiconductor device comprising the steps of:
setting a substrate over which an oxide is provided in a deposition chamber;
introducing an oxidizer into the deposition chamber in a pulsed form a plurality of times;
forming an insulating film over the oxide after the introduction of the oxidizer,
wherein one or both of addition of oxygen to the oxide and release of hydrogen or water from the oxide are performed by the introduction of the oxidizer.

2. The method for fabricating the semiconductor device according to claim 1, wherein the insulating film is formed by an ALD method.

3. The method for fabricating the semiconductor device according to claim 1, wherein the insulating film is an oxide comprising one or both of aluminum and hafnium.

4. A method for fabricating a semiconductor device comprising the steps of:
forming a first insulating film over an oxide;
forming a second insulating film over the first insulating film;
forming a conductive film over the second insulating film;
processing the conductive film, the second insulating film, and the first insulating film to expose part of a top surface of the oxide so as to form a first insulator over the oxide, a second insulator over the first insulator, and a conductor over the second insulator; and
forming a third insulating film that is in contact with the top surface of the oxide exposed by the processing, a side surface of the first insulator, a side surface of the second insulator, and a side surface of the conductor,
wherein the first insulating film and the second insulating film are successively formed in a reduced-pressure atmosphere.

5. The method for fabricating the semiconductor device according to claim 4, wherein the first insulating film and the second insulating film are formed by an ALD method.

6. The method for fabricating the semiconductor device according to claim 4, wherein the third insulating film is formed by an ALD method.

7. The method for fabricating the semiconductor device according to claim 4, wherein the second insulating film is an oxide comprising one or both of aluminum and hafnium.

8. The method for fabricating the semiconductor device according to claim 4, wherein the third insulating film is an oxide comprising one or both of aluminum and hafnium.

9. The method for fabricating the semiconductor device according to claim 4, wherein at least the top surface of the oxide exposed by the processing and the side surface of the first insulator are exposed to an oxidizer before the third insulating film is formed.

10. A method for fabricating a semiconductor device comprising the steps of:
forming a first insulator over a first conductor;
forming a second insulator over the first insulator;
forming a third insulator over the second insulator;
forming a fourth insulator over the third insulator;
forming a fifth insulator over the fourth insulator; and
forming an oxide over the fifth insulator,
wherein the second insulator, the third insulator, and the fourth insulator are successively formed in a reduced-pressure atmosphere.

11. The method for fabricating the semiconductor device according to claim 10, wherein the second insulator, the third insulator, and the fourth insulator are formed by an ALD method.

12. The method for fabricating the semiconductor device according to claim 10,
wherein the second insulator and the fourth insulator are each an oxide comprising one of hafnium and aluminum, and
wherein the third insulator is an oxide comprising the other of hafnium and aluminum.

13. The method for fabricating the semiconductor device according to claim 2, wherein the insulating film is an oxide comprising one or both of aluminum and hafnium.

14. The method for fabricating the semiconductor device according to claim 5, wherein the third insulating film is formed by an ALD method.

15. The method for fabricating the semiconductor device according to claim 5, wherein the second insulating film is an oxide comprising one or both of aluminum and hafnium.

16. The method for fabricating the semiconductor device according to claim 5, wherein the third insulating film is an oxide comprising one or both of aluminum and hafnium.

17. The method for fabricating the semiconductor device according to claim 5, wherein at least the top surface of the oxide exposed by the processing and the side surface of the first insulator are exposed to an oxidizer before the third insulating film is formed.
